(19) United States
(12) Patent Application Publication
(10) Pub. No.: US 2007/0046369 A1
(43) Pub. Date: Mar. 1, 2007

(54) High Sensitivity RFID TAG Integrated Circuits

(76) Inventors: Robert C. Schober, Huntington Beach, CA (US); Ion Opris, San Jose, CA (US); Francois Krummenacher, Lausanne (CH)

Correspondence Address: CHRISTIE, PARKER & HALE, LLP, PO BOX 7068, PASADENA, CA, 91109-7068, US

(21) Appl. No.: 11/459,339

(22) Filed: Jul. 22, 2006

Related U.S. Application Data
(60) Provisional application No. 60/701,692, filed on Jul. 22, 2005.

(51) Int. Cl. H03F 21/00

(52) U.S. Cl. 330/7; 340/572.1

(57) ABSTRACT

A method and apparatus for an ultra-high sensitivity, low cost, passive (no battery) low-power energy harvesting data transmitting circuit energy, such as a RFID (Radio Frequency IDentification) tag integrated circuit “chip.” By using combinations of special purpose design enhancements, the low-power energy harvesting passive data transmitting circuit, such as the RFID tag chip, operates in the sub-microwatt power range. The chip power should be derived from a low-microwatt per square centimeter RF field radiated to the RFID tag antenna from the tag reader (interrogator) or derived from a suitable low signal source, such as a sonic transducer (e.g., a piezoelectric transducer or a low level DC source, such as a bimetallic or chemical source).

### CROSS-REFERENCE TO RELATED APPLICATION

This application claims priority to and the benefit of U.S. Provisional Application No. 60/701,692, filed on Jul. 22, 2005, the entire content of which is incorporated herein by reference.

### FIELD OF THE INVENTION

This disclosure pertains to the field of a low-power energy harvesting passive data transmitting circuit and/or Radio Frequency IDentification (RFID). More particularly, the disclosure relates to the ability to increase the assuredness of picking up every RFID tagged item in the prescribed range. Normally, a disproportionate number of RFID tagged items are missed when being interrogated. This is due to widely varying RF field, which is caused by absorption and multi-path reflection of the tag reader's radiated energy field, which is imposed on the RFID tags for tag powering and command transmissions. This is similar to reception of a radio in a weak reception, area where more sensitive radios are capable of reliable reception. A tag including a low-power energy harvesting passive data transmitting circuit that requires much less energy to operate than other tags, will be readable when located within much lower energy points in the reader RF field.

### BACKGROUND OF THE INVENTION

Bar code labels are in full use for identification of items and entering data into tracking, sales, and the like systems. Radio Frequency IDentification (RFID) will displace the existing bar code system in the near future. To do this, the tags should be reliably read at significant distances and within shipping and packaging containers regardless of the surrounding items.

In RFID systems, there are:

A. passive tags, which derive their operating power from the reader RF field imposed on the tag,

B. active tags that are powered from a battery in the tag, and

C. battery assisted or semi-active tags that use a battery to start the tag, but these tags derive their operating power from the RF reader field like the passive tags.

The passive tags receive commands by alternating the radiated energy that powers them between two levels, and these tags return data, such as product codes and serial numbers, to the reader by alternating between two antenna impedances. Normally the reader output power is 100 percent and about 70 percent for logical ZERO and logical ONE. The reader can also transmit phase modulation keying, or some other scheme, instead of amplitude modulation in an attempt to keep the transmitted power at a maximum for powering the tag. When the reader wants to see the information output from the tag, the reader holds its output level at 100 percent and detects modulation in the backscatter from the tags in its RF field of view much as passive eavesdropping devices have employed some time ago. In order to have universal communication, the information and control signals between the reader and tag are transmitted in accordance with one or more of the several established RFID communication protocols. These are various protocol sequences that singulate and identify the tags in the reader field of view. On these identified tags, the reader can store small amount of data in the tag which can be retrieved later by the reader. The minimum data stored in the tag should be its serial number. This retrieved serial number can be used to access a database for retrieving additional information on the tagged item. This process of querying the item database can be reduced by including additional information on the tag such as product code, manufacturing date, and other item specific information. This is at a cost of tag complexity, cost, and sensitivity.

The active tags are battery powered and communicate with the reader by transmitting an RF signal in response to the reader commands. Since these tags are battery powered, they should have an ultra-low standby power drain. The tag transmitter should also consume minimal power. For these reasons, the practical read range is relatively short. The battery life is defined as the product shelf life.

The semi-active or battery assisted tags contain an extremely small printed battery which is used to assist RFID tag startup at the beginning of a reader interrogation. After startup, the tag is powered from the RF field imposed on it by the reader. During the rest of the tag's active cycle, the tag operates like the passive tag.

### SUMMARY OF THE INVENTION

A first aspect of the present invention is to provide a low-power energy harvesting passive data transmitting circuit, e.g., to power the RFID tag from the tag reader RF field with the smallest amount of energy density at the tag antenna. A second aspect of the present invention is to provide a manufactured data transmitting circuit and/or tag at a cost that approaches that of the printed bar code that it is displacing. These aspects are followed by the tag reader design. Lower power, more sensitive, RFID tags enable lower cost readers. As previously learned in the case of bar code acceptance, very low cost readers are key to triggering wide acceptance of the technology. Although the RFID reader is a difficult design, it does not fundamentally violate technology limits like that of powering the tag integrated circuit from only the received RF field. In order to reach this efficient low cost RFID tag system, a series of creative design approaches should be profoundly used:

1. More Reliable Reads in the Real World:

The RFID tag's sensitivity should be maximized in order to achieve a long read range. This long read range provides a process of identifying or locating a non-visible item in its existing location and thus eliminates the physical requirement of visually observing a tagged item or moving the item through a read area. This would enable instantaneous warehouse inventory monitoring, tabulation, and tracking. With an array of readers, the product's location can be localized and missing products found. For this, readers, which are under system control, can pinpoint RFID tags within the interrogation region. The readers can coarsely derive sector, direction, and range of the RFID tagged items. The reader beam width can be computer controlled, and through an array of readers, triangulate each item's position. The ability of a reader to interrogate weakly powered tags in fringe regions is limited by the legal limit for tag reader power output. This high reader output mode is initially used to determine if the product is present and return which readers see the queried product. At this high reader output power setting, the RF attenuation and shielding effects that limit RFID tag reading have a minimum effect. The high reader gain is then reduced to provide a first cut at the range and region of the RFID tag, and determine any movement. A narrower beam can further derive the tag's location. Handheld readers can be used also in narrowing down a tag's position. By using multiple reader antennas, the limitation of not knowing that a weak tag is a result of distance or presence of attenuating media intervening between the reader and the tag is minimized.

2. Smaller RFID Tag Footprint:

Higher tag integrated circuit sensitivity enables construction of smaller tags with reasonable read range. Thus reducing power requirements of the tag, sensitivity can be traded off with a decrease in tag antenna inlay size. Smaller tag antenna footprints reduce cost and widen RFID application space. An example is attaching smaller tags on the ends of products rather than the lager areas which, when stacked on top of each other, cause ghosting or difficulties in determining products, e.g., compact disks (CD).

3. Singulation of Individual RFID Tags:

Each RFID tag should be individually readable in a field of thousands of tags in varying proximity to each other from populations of closely overlapped groupings to single tags. Singulated tags should be able to remember that they have been singulated for a short period of time when the reader RF energy drops below tag operating level and not down to near zero after a read session. This is performed in accordance with the RFID tag's protocol standard and the use of sticky latches.

4. RFID Tag Manufacturing Cost Should be Minimized:

In order for an RFID tag to achieve market penetration, its manufacturing cost should be extremely low. Low cost tags will increase tag production volume, resulting in a further decrease in tag cost. This lower tag cost will economically allow its use on increasingly lower cost products. Thus, the RFID tag cost will enjoy the benefits of the highest volume production in a decreasing cost spiral. This commodity effect has an avalanche point that is not achievable with current costs. The creative approaches in this disclosure will significantly help enable reaching this goal. The tag cost should be low enough for it to be covered by decreased product distribution related cost and efficiencies, as well as new forms of market data collection.

5. Energy Collection—Complex Impedance Matching:

The RFID tag antenna gathers and applies energy from the reader differentially across the chip input bonding pads. With this are several impedance mismatches existing in the RF path. In air, the transmission impedance is on the order of 377 ohms, the antenna output to chip is inherently in the order of 50 to 75 ohms, and the integrated circuit is physically around 2,000 ohms due to integrated circuit intrinsic resistances. The reactive parts of the complex impedance further complicate the impedance mismatches. These impedance mismatches reflect energy back to the reader, which could be going into powering the tag. Partial control of these reflections are necessary in order for the reader to sense the tag's return signal through backscatter. The integrated circuit keys its input impedance between two states to transmit backscattered return signals to the reader. When the RFID tag is placed too close to the reader, the mismatch of the chip impedance to the antenna is used to reflect dangerous levels of excess energy off the chip back through the antenna instead of having the integrated circuit absorb it.

The limiting sensitivity factor in the RFID reader is when the tag system is just barely able to power the tag. Higher range capability enables positioning the RFID tag location in equivalently low fields that occur when items, which attenuate and reflect signals, are in the transmission paths. With this out-of-sight items inside containers or deep within warehouse storage can be located and identified. Ultra-high sensitivity enables reading tags even when the tagged items are located within RF absorbing material such as moisture, or placed in close proximity to metal surfaces.

6. Resonator Between the Antenna and Charge Pump:

An on-chip resonator is used to transform an ultra-low voltage at the antenna-chip input for assisting the power supply rectifier/charge pump. This resonator transitions between the linear antenna input to the higher voltage switching circuitry. The resonator uses special techniques, which shield it and reduce its coil resistance in order to maximize its quality factor. The resonator also uses the capacitive input of the charge pump as a reactive element. The antenna can also drive the charge pump differentially. Two antennas can be used additively to take advantage of directional RF fields from the reader. Each antenna has its own charge pump and modulator here.

7. Antenna Impedance Modulator:

The antenna impedance should be modulated as the preferred RFID tag data to reader signal path technique. When the impedance is lowered, the energy is stolen from the charge pump/rectifier input to the tag power supply. To minimize this loss, the impedance may be modulated in the complex plane instead of just attenuated in the real plane.

8. Efficiency:

Efficiency in the transfer and use of the energy from the reader to the RFID tag electronics is a prime subject of this disclosure. The power from the antenna is passed from the antenna to the integrated circuit power extraction circuit as well as around it through parasitic capacitance on the chip input bonding pads and related circuitry. For this reason, it is highly desirable to minimize the non-power extraction capacitance at the chip input. For this, the bonding pads are kept small or replaced by edge bonding techniques.

9. Low Voltage Charge Pump/Rectifier Operation:

Additional efficiency is obtained by maintaining low voltage swings at the chip input where the naturally low antenna impedance dominates. The lower the impedance at the antenna input pads, the lower the voltage swing there. Unfortunately, the impedance mismatch limits the RF energy transfer from the antenna to the integrated circuit. Lower voltage swings limit the power lost in the parasitic capacitance. This power savings is a squared function of the voltage swing (P˜CV²). Unfortunately, the power extraction circuitry should rectify the RF input power, which is a switching function that uses some form of semiconductor diodes that require a threshold voltage difference to turn them ON and OFF. An integrated resonator is used to convert from the lower antenna impedance at the pads to the higher impedance of the integrated circuit. This converts the current mode antenna signal to the voltage mode which is needed for the switching integrated circuit rectifier/charge pump. This solves the contradiction of needing voltage swing to operate a switching circuit when only having near-zero voltage swings into the semiconductor diodes that require half-volt thresholds to switch.

The semiconductor rectifier threshold voltage is lowered to near zero or as low as zero volts with native transistors. In lowering this threshold voltage, the rectifier transistors do not turn OFF very well. The characteristic shape of the diode curve does not change significantly as the threshold voltage is reduced, but is merely shifted down in voltage. This means that although the diodes turn ON at low voltage, they do not turn OFF well when the input swing is reversed. In an RFID tag application, it is more important to lower the turn ON voltage than it is to turn the diode OFF well. For normal diodes at low voltages, no input power rectification activity occurs if the two switching states are both well in the OFF region of operation. Because of the high OFF leakage of zero or ultra low threshold voltage transistors, the result is a functional but low efficiency rectifier that operates at near zero input voltage swing—a very non-intuitive approach. This ON to less-ON (=OFF state here) switching impedance ratio is enhanced by using the body to assist through back-gating the transistor by means of what is called well-snatchers. Since individual transistor wells can be biased individually, the wells are taken to the voltage that assists the transistor's operation best, or prevent latch-up as the case may be. For the transistors that are not in wells, they can have an equivalent body-snatcher effect applied over a small voltage between the source and body in one direction limited with forward biasing this junction, but not for the other polarity. The body-snatcher is a circuit that takes the transistor body to the most advantageous voltage which is often a voltage outside its transistor source voltage. It normally grabs the well and brings it to the highest voltage. This can prevent forward biasing of the body to source/drain nodes, or it can enhance the transistor conduction, or cutoff leakage, through the back-gate transistor biasing. The poly gate can be assisted by the body gate effect, which has a lower channel conduction control. Body-snatcher is the more general term for well-snatcher. The well is the body connection for one of the transistor types. A special transistor structure that enhances this ON to OFF switching ratio is disclosed.

10. Low Voltage Oscillator:

RFID tags need an oscillator to decode commands, operate the tag protocol logic, and transmit information back to the reader. Reliable reads are dependent on moderately accurate timing periods. Ultra-low power is not consistent with accurate oscillators. A current-fed ring oscillator that is well suited for RFID tags is disclosed. This oscillator can be calibrated at manufacture by programming a word in memory, which controls the current source. During RFID tag operation, the oscillator operates at a much higher frequency than the RFID protocol timing. The protocol starts with a pulse width, which is used to prescale the master timing of the RFID tag. This prescale divisor is latched in a register at the beginning of tag communications, and thus the tag automatically is adjusted to differences in reader timing, modes of operation, and tag native oscillator frequencies. A special Resettable dynamic frequency divider is disclosed for this prescalar. This prescalar enables the use of a higher frequency oscillator for finer time resolution while using less power than a lower frequency oscillator.

11. Low Voltage Supply Derivation and Regulation:

The current-fed ring oscillator provides a minimum voltage-delay relationship that is used to regulate the power supply throughout the RFID tag integrated circuit logic. This is a semiconductor parameter tracking circuit that auto adapts to its integrated circuit process and environmental conditions providing a stable minimum operating conditions for the entire RFID tag electronics. This guarantees operation at the lowest power independent of conditions. This oscillator system also provides logic signals that indicate that there is sufficient tag power supply voltage to proceed with the protocol state machine or that the tag should go into a state preservation state due to lack of sufficient power.

12. Low Voltage Circuit Operation:

The dominant mandate for the rest of the tag integrated circuit design is to satisfy the needed functionality with the least amount of power. Logic that behaves well and minimizes power while operating in extreme-weak inversion MOS mode is disclosed. Ultra-low voltage logic that is applicable to RFID tag usage is disclosed. Since this logic operates down around 200 millivolts, the transistor switches are not capable of turning OFF or ON well, leaving an OFF to ON ratio in the order of 100 for operation. The enhancement is not only from the voltage squared advantage, but in that the tag circuit does not require the higher voltage output from the charge pump or rectifier. In addition, the use of clockless logic for an RFID tag is disclosed.

13. Logic Implementation for Minimizing Peak Power Loading:

Logic design is similar to that of Grey-Code counters is employed. This is primarily to limit the peak current drain on the logic power supply during RFID tag operation.

14. CMOS Device Structures:

Special CMOS device techniques to increase gain in the weak-inversion mode of operation and reduce off current leakage. A special series MOS device is disclosed that employs some of the band-gap technology to self-bias itself. Also, some very-short channels are used where they do not have to hold off any drain voltage, particularly in native transistor applications.

15. Low Voltage Memory:

Writable memory is used for storing a unique serial number and other programmable data such as product code and tracking information such as date and check points. Normally this memory is write once and read many (WORM). The charge that is accumulated on floating gates during semiconductor fabrication may be used as an initial zero in the memory cell. This is the charge that is to be avoided on larger floating wires during processing which is known from its integrated circuit antenna design rules. The use of this charge to flip a differential cell upon ultra-low voltage power up requires a careful differential cell layout design. The cell should be exactly differential in order to flip upon power up, but it should absorb more charge on a larger metal node to come up as the initial zero. To make the cells operate at essentially zero input voltage, native or near zero threshold transistors are employed. The leakage current can be cut back as the voltage is increased through a power cutoff transistor. Here the data is latched in a higher voltage latch, as the initial memory latch power is cutoff. Thus, there is a staged power up sequence. Native transistors latch the information near zero volts during startup, and normal transistors may grab the latched data if the native devices are turned off as much as possible.

Since in most cases, memory does not need to be rewritten often if at all, simpler memory can be used for these applications. Where a few rewrites are needed, an extended part of memory can be used. Here, for rewriting, the initial word is written to all ones thus signifying that it has been rewritten at a prescribed upper location in memory, or just erased.

Memory structure can use one of several processes where an offset charge is stored around the channel or device. The process takes advantage of the ultra-thin gate oxide of the deep submicron processes. In this, it is not necessary to develop a special ROM integrated circuit process such as dual poly. Instead ordinary gates are floated and their charge controlled through various accumulation and tunneling methods.

16. Low Voltage Passive Sensors:

Sensors can be incorporated into RFID tags. Consistent with low RFID tag costs, the sensors are moderate to low accuracy in most cases. In order to operate these sensors with ultra low power and voltage, and still have the capability of digitizing their output, differential sensors are employed. Here two nearly identical sensors are run in parallel. Their difference id designed in to be sensitive to the parameter being measured. These sensors are used to feed a current into identical oscillators. The oscillators run counters up. The first counter stops the count, and the difference is the digital word out. Calibration memory words are read from the tag static memory and used to calculate out errors externally.

17. Partial List of Significant Design Considerations:

In order to maximize the ability of powering the RFID tag, many significant design techniques should be creatively employed and combined in a consistent manner. The critical design parameters include, but are not limited to the following list:
1) Antenna design to maximize energy transfer independent of orientation.
2) Antenna to chip complex impedance matching.
3) Minimization of parasitic RF losses to and on chip.
4) Differential charge-pump/active rectifier to match differential antenna input.
5) Millivolt startup circuitry to bias the rectifier/charge pump.
6) Low-level (low millivolt) operation of the rectifier/charge pump.
7) Use native transistors (near zero threshold voltage) at selected places.
8) Use ultra-short channel length native transistors where there is low voltage.
9) Compound transistors to decrease OFF leakage and increase low voltage gain.
10) Resonator on-chip tuned to UHF or operating frequency.
11) Means of reflecting excessive antenna overdrive energy back off antenna.
12) Means of limiting excessive charge pump output voltage to safe level.
13) Minimal parasitic integrated circuit input protection.
14) Combine multiple charge pump outputs to the highest output voltage.
15) Process/performance sensitive power supply voltage reference generator.
16) Startup control for multiple circuit wake-up sequencing.
17) Lowest voltage power supply regulation.
18) Integrated energy storage.
19) Data demodulator consistent with active rectifier/charge pump.
20) Data modulator which keys output impedance without loading input significantly.
21) Ultra low power current-fed ring oscillator.
22) Oscillator with logic element delay to logic voltage relationship.
23) Processing parameter/environment cancellation to guarantee operation at minimum.
24) Rough calibration scheme for oscillator current source.
25) Ultra-low power dynamic prescalar to set timing via reader calibration pulse-width.
26) Prescalar phase selector to reduce the required frequency for time resolution.
27) Grey-code like logic design to eliminate peak current demands on power supply.
28) Self-timed Clockless logic design.
29) Ultra-low voltage logic which employs ultra-low threshold transistors.
30) Logic cells optimized to reliability operate at ultra-low voltage.
31) Ultra-low profile logic cells down to a height of 5 and 6 metal-2 pitch.
32) Dual rail logic power for well/substrate isolation.

A more complete understanding of the low-power energy harvesting passive data transmitting circuit and/or Radio Frequency IDentification (RFID) will be afforded to those skilled in the art and by a consideration of the following detailed description. Reference will be made to the appended sheets of drawings which will first be described briefly.

### BRIEF DESCRIPTION OF THE DRAWINGS

The accompanying drawings, together with the specification, illustrate exemplary embodiments of the present invention, and, together with the description, serve to explain the principles of the present invention.

FIG. 1 illustrates a resonator model of series resonant circuit with shunt capacitance (C₀).

FIG. 1A illustrates an operational standard series resonant circuit model to represent a RLC circuit elements with its parasitic bypass capacitance (C₀) that makes up the low-Q tank circuit including an external antenna connected between node (A1) and node (GND), a resonator (COIL), and a charge pump (CP).

FIG. 2 is a schematic of an active rectifier.

FIG. 3 is a schematic of an active rectifier with polarity reversed.

FIG. 4 is a schematic of a cascode circuit.

FIG. 5 is a schematic of a BgSCFET circuit.

FIG. 6 illustrates simulated output resistance of p-BgSCFET (normalized to the output resistance of a p-FET of same dimensions) vs. the ratio between the main transistor length (Lm) to cascode transistor length (Lc).

FIG. 7 illustrates measured I-V characteristics of a p-BgSCFET and a p-FET of same dimensions (W/L ratio of 3/10).

FIG. 8 illustrates CMOS Drain to Source “OFF” Leakage Current Reduction for Series-Coupled Bandgap Compound Transistor Configuration.

FIG. 9 illustrates reduction of “ON” Resistance of CMOS Transmission Gate for Series-Coupled Bandgap Compound Transistor Configuration.

FIG. 10 is a charge pump block level Top Block Interconnect schematic.

FIG. 10A illustrates a primary first stage part of the charge pump schematic of FIG. 10 in principle functionality using switches.

FIG. 10B illustrates the same part shown in FIG. 10A using diodes.

FIG. 10C illustrates a complementary configuration of the primary first stage part of the charge pump schematic of FIG. 10 using diodes of the opposite polarity.

FIG. 10D illustrates interconnections between the parts shown in FIGS. 10B and 10C to construct a dual polarity (or input) charge pump.

FIG. 10E illustrates drain-to-source current (Ids) vs. gate-to-source voltage (Vgs) comparison of a native MOS transistor, a regular MOS transistor, and a Schottky diode of equivalent current carrying capacity.

FIG. 10F illustrates a more detail view in the operating region of the Schottky diode shown in FIG. 10E.

FIG. 10G illustrates a more detail view in the operating region of the native MOS transistor shown in FIG. 10E.

FIG. 11 is a three stage charge pump transistor level schematic.

FIG. 11A is a more detail view of a main charge portion of the three stage charge pump transistor level schematic of FIG. 11 showing capacitors formed using native MOS transistors (NA).

FIG. 12 is a Data Detector transistor level schematic.

FIG. 13 is a Power Good Detector transistor level schematic.

FIG. 14 is a simulation test transistor level schematic.

FIG. 15 illustrates simulation test plots of voltages (or signals) at nodes data_h, data_i, and vdd of the circuit of FIG. 14 with Fast parameters at 00 C, and 300 mV.

FIG. 16 illustrates simulation test plots of voltages (or signals) at nodes data_h, data_i, and vdd of the circuit of FIG. 14 with Fast parameters at 700 C, and 300 mV.

FIG. 17 illustrates simulation test plots of voltages (or signals) at nodes data_h, data_i, and vdd of the circuit of FIG. 14 with Slow parameters at 00 C, and 346 mV.

FIG. 18 illustrates simulation test plots of voltages (or signals) at nodes data_h, data_i, and vdd of the circuit of FIG. 14 with Slow parameters at 700 C, and 300 mV.

FIG. 19 illustrates simulation test plots of voltages (or signals) at nodes data_h, data_i, and vdd of the circuit of FIG. 14 with Typical parameters at 00 C, and 300 mV.

FIG. 20 illustrates simulation test plots of voltages (or signals) at nodes data_h, data_i, and vdd of the circuit of FIG. 14 with Typical parameters at 700 C, and 300 mV.

FIG. 21 illustrates simulation test plots of voltages (or signals) at nodes data_h, data_i, and vdd of the circuit of FIG. 14 with Typical parameters.

FIG. 22 illustrates simulation test plots of voltages (or signals) at nodes data_h, data_i, and vdd of the circuit of FIG. 14 with high input signal limit and with Fast parameters at 700 C, and 7.75V.

FIG. 23 illustrates simulation test plots voltages (or signals) at nodes data_h, data_i, and vdd of the circuit of FIG. 14 with high input signal limit and with Fast parameters at 00 C, and 7.75V.

FIG. 24 illustrates simulation test plots of voltages (or signals) at nodes data_h, data_i, and vdd of the circuit of FIG. 14 with high input signal limit and with Slow parameters at 700 C, and 7.75V.

FIG. 25 illustrates simulation test plots of voltages (or signals) at nodes data_h, data_i, and vdd of the circuit of FIG. 14 with high input signal limit and with Slow parameters at 00 C, and 7.75V.

FIG. 26 illustrates simulation test plots of voltages (or signals) at nodes data_h, data_i, and vdd of the circuit of FIG. 14 with high input signal limit and with Typical parameters at 700 C, and 7.75V.

FIG. 27 illustrates simulation test plots of voltages (or signals) at nodes data_h, data_i, and vdd of the circuit of FIG. 14 with high input signal limit and with Typical parameters at 00 C, and 7.75V.

FIG. 28 is a charge pump 2 block level Top Schematic Block Interconnect schematic.

FIG. 29 is a charge pump 3 block level Top Schematic Block Interconnect schematic.

FIG. 30 is a charge pump 4 block level Top Schematic Block Interconnect schematic diagram.

FIG. 31 is another three stage charge pump transistor level schematic with different design parameters.

FIG. 32 is yet another three stage charge pump transistor level schematic with different design parameters.

FIG. 33 is a four stage charge pump transistor level schematic.

FIG. 34 is a Data Detector B transistor level schematic.

FIG. 35 is a Power Good Detector B transistor level schematic.

FIG. 36 is a simulation test B transistor level schematic.

FIG. 37 illustrates simulation test B plots of voltages (or signals) at nodes vdd, pg, data_out of the circuit of FIG. 36 with Slow parameters at 00 C, and 210 mV.

FIG. 38 illustrates simulation test B plots of voltages (or signals) at nodes vdd, pg, data_out of the circuit of FIG. 36 with Slow parameters at 700 C, and 175 mV.

FIG. 39 illustrates simulation test B plots of voltages (or signals) at nodes vdd, pg, data_out of the circuit of FIG. 36 with Fast parameters at 700 C, and 200 mV.

FIG. 40 illustrates simulation test B plots of voltages (or signals) at nodes vdd, pg, data_out of the circuit of FIG. 36 with Fast parameters at 00 C, and 175 mV.

FIG. 41 illustrates simulation test B plots of voltages (or signals) at nodes vdd, pg, data_out of the circuit of FIG. 36 with Typical parameters at 250 C, and 175 mV.

FIG. 42 illustrates simulation test B plots of voltages (or signals) at nodes vdd, pg, data_out of the circuit of FIG. 36 with Fast parameters at 00 C, and 175 mV.

FIG. 43 illustrates simulation test B plots of voltages (or signals) at nodes vdd, pg, data_out of the circuit of FIG. 36 with Fast parameters at 700 C, and 175 mV.

FIG. 44 illustrates simulation test B plots of voltages (or signals) at nodes vdd, pg, data_out of the circuit of FIG. 36 with maximum input and with Typical parameters at 250 C, and 7.75V.

FIG. 45 illustrates simulation test B plots of voltages (or signals) at nodes vdd, pg, data_out of the circuit of FIG. 36 with maximum input and with Slow parameters at 00 C, and 7.75V.

FIG. 46 illustrates simulation test B plots of voltages (or signals) at nodes vdd, pg, data_out of the circuit of FIG. 36 with maximum input and with Fast parameters at 00 C, and 7.75V.

FIG. 47 illustrates simulation test B2 plots of voltages (or signals) at nodes vdd, pg, data_out of the circuit of FIG. 36 with maximum input and with Slow parameters at 700 C, and 7.75V.

FIG. 48 illustrates simulation test B2 plots of voltages (or signals) at nodes vdd, pg, data_out of the circuit of FIG. 36 with maximum input and with Fast parameters at 700 C, and 7.75V.

FIG. 49 illustrates simulation test B2 plots of voltages (or signals) at nodes vdd, pg, data_out of the circuit of FIG. 36 with maximum input and with Fast parameters at 00 C, and 7.75V.

FIG. 50 illustrates a simulation test B3 transistor level schematic.

FIG. 51 illustrates simulation test B3 plots of voltages (or signals) at nodes vdd, pg, data_out of the circuit of FIG. 50 with worst-case condition Slow parameters at 00 C, and 200 mV.

FIG. 52 illustrates a simulation test B4 transistor level schematic.

FIG. 53 illustrates a simulation test B4 plots of voltages (or signals) at nodes vdd, pg, data_out of the circuit of FIG. 36 with worst-case condition Slow parameters at 00 C, and 200 mV.

FIG. 54 illustrates Arrayed Layout of RFID tag dual charge-pump/resonator test chips.

FIG. 55 illustrates Layout 3 of RFID tag dual charge-pump/resonator.

FIG. 56 illustrates Layout 3-s of RFID tag dual charge-pump/resonator.

FIG. 57 illustrates Layout 31 of RFID tag dual charge-pump/resonator.

FIG. 58 illustrates Layout 31-s of RFID tag dual charge-pump/resonator.

FIG. 59 illustrates layout 32 of RFID tag dual charge-pump/resonator.

FIG. 60 illustrates Layout 32-s of RFID tag dual charge-pump/resonator.

FIG. 61 illustrates Layout 4 of RFID tag dual charge-pump/resonator.

FIG. 62 illustrates Layout 4-s of RFID tag dual charge-pump/resonator.

FIG. 63 illustrates Layout 41 of RFID tag dual charge-pump/resonator.

FIG. 64 illustrates Layout 41-s of RFID tag dual charge-pump/resonator.

FIG. 65 illustrates Layout 42 of RFID tag dual charge-pump/resonator.

FIG. 66 illustrates Layout 42-s of RFID tag dual charge-pump/resonator.

FIG. 67 illustrates Layout A of RFID tag dual charge-pump/resonator.

FIG. 68 illustrates Layout A-s of RFID tag dual charge-pump/resonator.

FIG. 69 illustrates Layout A1 of RFID tag dual charge-pump/resonator.

FIG. 70 illustrates Layout A1-s of RFID tag dual charge-pump/resonator.

FIG. 71 illustrates Layout A2 of RFID tag dual charge-pump/resonator.

FIG. 72 illustrates Layout A2-s of RFID tag dual charge-pump/resonator.

FIG. 73 illustrates Layout B of RFID tag dual charge-pump/resonator.

FIG. 74 illustrates Layout B-s of RFID tag dual charge-pump/resonator.

FIG. 75 illustrates Layout B1 of RFID tag dual charge-pump/resonator.

FIG. 76 illustrates Layout B1-s of RFID tag dual charge-pump/resonator.

FIG. 77 illustrates Layout B2 of RFID tag dual charge-pump/resonator.

FIG. 78 illustrates Layout B2-s of RFID tag dual charge-pump/resonator.

FIG. 79 is circuit block diagram of a Trimmable RC Oscillator.

FIG. 80 illustrates Oscillator circuit principle of a Trimmable RC Oscillator.

FIG. 81 is a Top Level Block Interconnect schematic of a Trimmable RC Oscillator.

FIG. 82 is a Ring Oscillator Block Interconnect schematic of a Trimmable RC Oscillator.

FIG. 83 is a Ring Oscillator Inverter schematic of a Trimmable RC Oscillator.

FIG. 84 is an RC Oscillator Loop Amplifier schematic of a Trimmable RC Oscillator.

FIG. 85 is a Programmable Current Mirror schematic of a Trimmable RC Oscillator.

FIG. 86 is a Programmable Current Mirror Single-Pole-Double-Throw Switch schematic of a Trimmable RC Oscillator.

FIG. 87 is a Trimmable Resistor schematic of a Trimmable RC Oscillator.

FIG. 88 is a Digital Supply Buffer schematic of a Trimmable RC Oscillator.

FIG. 89 is a Ring Oscillator Buffer Inverter schematic of a Trimmable RC Oscillator.

FIG. 90 is a Dynamic Divide-By-2 schematic of a Trimmable RC Oscillator.

FIG. 91 is a Current Reference schematic of a Trimmable RC Oscillator.

FIG. 92 is an Oscillator Status Monitor schematic of a Trimmable RC Oscillator.

FIG. 93 illustrates schematics and stick diagrams of C²L Dynamic Divide by 2 (lower left stick), and an output buffer (lower right stick).

FIG. 94 illustrates Layout of C²L Dynamic Divide by 2.

FIG. 95 illustrates Layout of C²L Dynamic Divide by 2 including an output buffer.

FIG. 96 illustrates Voltage limiting performance, using normal threshold voltages, of C²L Dynamic Divide by 2 logic cell.

FIG. 97 is schematics and stick diagrams of C²L Dynamic Divide by 2 with static reset (lower left stick), and including an output buffer (lower right stick).

FIG. 98 illustrates Layout of C²L Dynamic Divide by 2 with static reset.

FIG. 99 illustrates Layout of C²L Dynamic Divide by 2 with static reset including an output buffer.

FIG. 100 is schematics and stick diagrams of C²L Dynamic Divide by 3 with static reset (lower left stick), and including an output buffer (center right stick).

FIG. 101 illustrates Layout of C²L Dynamic Divide by 3 with static reset.

FIG. 102 illustrates Layout of C²L Dynamic Divide by 3 with static reset including an output buffer.

FIG. 103 illustrates Voltage limiting performance, using normal threshold voltages, of C²L Dynamic Divide by 3 logic cell.

FIG. 104 is a Top Level block diagram of a RFID tag Digital Controller.

FIG. 105 is a System Timing Control schematic of a RFID tag Digital Controller.

FIG. 106 is a System Timing logic schematic of a RFID tag Digital Controller.

FIG. 107 is a Clock to Data Synchronizer logic diagram of a RFID tag Digital Controller.

FIG. 108 is a Clock Synchronizer logic diagram of a RFID tag Digital Controller.

FIG. 109 is a Timer Counter Register logic diagram of a RFID tag Digital Controller.

FIG. 110 is an Oscillator Calibration logic diagram of a RFID tag Digital Controller.

FIG. 111 is an Oscillator Calibration Register logic diagram of a RFID tag Digital Controller.

FIG. 112 is a DownLink Symbol Detector logic diagram of a RFID tag Digital Controller.

FIG. 113 is a Command Operation logic diagram of a RFID tag Digital Controller.

FIG. 114 is a Dual antenna/charge pump tag floorplan.

FIG. 115 is a Dual antenna/charge pump tag floorplan with side-mounted antennas.

FIG. 116 is a Dual antenna/charge pump tag floorplan with vertical-mounted antennas.

FIG. 117 illustrates Top level chip floorplan for single antenna minimal die size RFID chip.

FIG. 118 is an Example drawing for small die size mounting configurations.

FIG. 119 is a single antenna chip mount to RFID tag inlay for 2, 3 and 4 pads.

FIG. 120 illustrates a floating node including gates of the programming devices, gates of a sensing circuit, and with no diffusion (i.e., only gates).

### DETAILED DESCRIPTION

In the following detailed description, only certain exemplary embodiments of the present invention are shown and described, by way of illustration. As those skilled in the art would recognize, the described exemplary embodiments may be modified in various ways, all without departing from the spirit or scope of the present invention. Accordingly, the drawings and description are to be regarded as illustrative in nature, and not restrictive. There may be parts shown in the drawings, or parts not shown in the drawings, that are not discussed in the specification as they are not essential to a complete understanding of the invention.

A. RFID Tag Sensitivity

The RFID tag sensitivity is delineated by the minimum level of energy applied to the tag antenna, which powers the RFID tag's integrated circuit electronics. At this minimum input power, the entire RFID tag system should function properly. The first element to drop out prevents the entire tag system from being functional. Ideally, for the most sensitive tag as voltage is decreased, everything would drop out at the same time. Reduction of the highest dropout voltage element directly enhances the entire RFID tag's system sensitivity. Any other circuit element over-design tends to load the circuit and thus reduces the overall sensitivity of the entire RFID tag. This defines the RFID tag's design operational balance point between each circuit element. Integrated circuit process parameter variations as well as their worst-case limits should be taken into account in order for this maximum sensitivity RFID tag and be producible in large quantities at the lowest manufacturing cost. To address and minimize this balance point impact, the electronic circuitry is uniquely designed to use the integrated circuit process parameters to establish the bias and calibration points. This cost that should be minimized is that of the entire tag. Thus, the cost and performance of the tag integrated circuit should be balanced with the total manufactured RFID tag cost.

B. Antenna Interface

The UHF antenna interface to the chip is an extremely important design challenge in that a maximum portion of UHF input energy has to be directed into the chip power system in order to provide enough circuit power to make the RFID tag operational. This has to function at very low input power levels (for example 10 to 50 microwatts). This same input also has to be able to hold off very high power levels (for example a potential 6 volts) indefinitely when the tag is placed in close contact with the reader. Not only does the tag need to survive this maximum field, but also it should operate properly at this maximum power input creating a very wide dynamic range of operation.

The antenna interface is bi-directional in that the antenna impedance is modulated to create the backscatter used to communicate data back to the reader. Modulated backscatter, similar to that which was used for eavesdropping bugs in the past, is a very tag power efficient method of communication from the tag to the reader while using a sustained RF field from the reader to power and communicate to the tag. The parasitic loading of the antenna modulation devices creates parasitic loading that shunts energy away form the power subsystem. Creative techniques are employed to reduce this loading.

For maximum energy transfer from the antenna to the RFID tag integrated circuit, the complex impedance of the antenna is matched as closely as practical to the complex impedance of the integrated circuit input. Here the normally lower impedance of the antenna is raised and the normally higher integrated circuit impedance is lowered to approach a common value at the UHF or other frequency band used in the RFID system. This process normally results in a moderate Quality factor (Q) which also makes the tag frequency selective in the band of interest. This joins the inherently low impedance of an antenna to the inherently much higher impedance of the integrated circuit at some middle ground, and provides a voltage boost to the switching circuitry of the RFID tag integrated circuit's power supply.

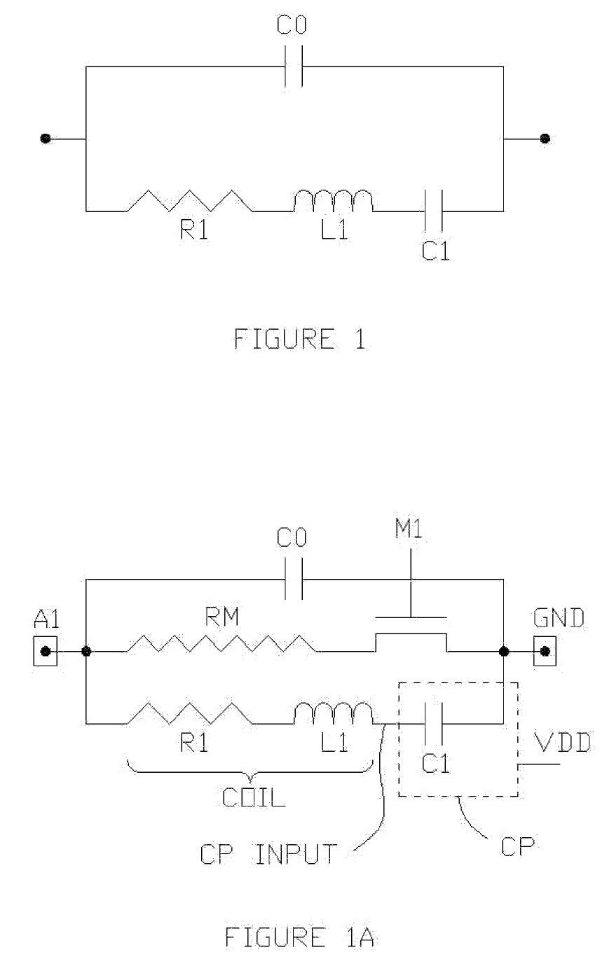

The antenna interface may contain a resonant input circuit to make an impedance transformation from the lower antenna impedance towards the higher impedance of the integrated electronic circuitry. The antenna output to the RFID integrated circuit chip is typically in the range of 50 to 70 ohms and the integrated electronic circuitry characteristically operates with impedances on the order of the kiliohm range and higher. The integrated parasitic capacitances are orders of magnitude lower than off chip parasitic capacitances, which allow for similar high frequency operation using higher impedance active integrated circuit elements. This impedance transformation can be achieved by means of a resonant circuit tuned to ring around the carrier frequency of the tag's antenna RF input energy. See FIG. 1 for a first order resonant circuit as a concept to visualize the principle to be employed in the RFID Tag integrated circuitry. The resonant circuit is similar to a quartz crystal equivalent resonant circuit [Statek Technical Note 32, The Quartz Crystal model and its frequencies, Statek Corporation, 512 Main St., orange, CA 92868, Rev. A, which is incorporated by reference herein in its entirety], but the values are vastly different. For example, this resonant circuit can have a series branch consisting of an inductor (L₁), with its combined effective series resistance (R₁), and integrated capacitance (C₁). The shunt capacitance element (C₀) is made up from various parasitic capacitances, which primarily come from the integrated circuit bonding pad capacitance through the substrate (Vₛₛ) or Gnd. One of the tricks is to realize the series capacitance (C₁) as a charge pump. From here, the concept is to get as much of the current from the antenna input to resonate through the charge pump (C₁) and not shunt around it through the various parasitic loads (C₀). The resonant circuit can be made up of both integrated and off-chip elements, which include circuit elements to best, match the antenna impedance to the chip. If the impedance is low at the pads, the voltage swing will be lower resulting in a lower parasitic loss of energy here.

C. Resonant Circuit to Boost Voltage into Active Circuitry

The entire chip power should be derived from rectifying the UHF RF field imposed onto the antenna by the RFID tag reader. Rectifiers are nonlinear devices that require some voltage swing to produce differences between the two extremes of their conductance known as ON and OFF states. Resonant circuits are linear devices that do not depend on having a minimum voltage swing to provide their effect. They have the same characteristic operation even down into the microvolt range, i.e. their response scales linearly with signal level. A key part of this invention disclosure is to exploit the linear characteristics of a resonant circuit to boost the voltage into a switching rectifier circuit known as an active rectifier or charge pump. From this, the lower voltage swing at the lower impedance antenna terminals will be translated to higher impedance resulting a higher voltage into the charge pump. This functions as the equivalent of a voltage boost transformer. Since the lower impedance nodes of a resonant circuit operate at relatively lower voltage swings, their parasitic capacitances will bypass less energy around the chip power supply. This circuit node contains the close proximity to the chip antenna connections, the chip bonding pads, the input protection, and the backscatter modulator. The charge pump and data stripper (RFID tag receiver) is located inboard at the higher impedance node of the resonant circuit where relatively higher voltage swings are required to operate the nonlinear switching transistor circuitry.

C. Resonant Circuit to Boost Voltage into Active Circuitry

The entire chip power should be derived from rectifying the UHF RF field imposed onto the antenna by the RFID tag reader. Rectifiers are nonlinear devices that require some voltage swing to produce differences between the two extremes of their conductance known as ON and OFF states. Resonant circuits are linear devices that do not depend on having a minimum voltage swing to provide their effect. They have the same characteristic operation even down into the microvolt range, i.e. their response scales linearly with signal level. A key part of this invention disclosure is to exploit the linear characteristics of a resonant circuit to boost the voltage into a switching rectifier circuit known as an active rectifier or charge pump. From this, the lower voltage swing at the lower impedance antenna terminals will be translated to higher impedance resulting a higher voltage into the charge pump. This functions as the equivalent of a voltage boost transformer. Since the lower impedance nodes of a resonant circuit operate at relatively lower voltage swings, their parasitic capacitances will bypass less energy around the chip power supply. This circuit node contains the close proximity to the chip antenna connections, the chip bonding pads, the input protection, and the backscatter modulator. The charge pump and data stripper (RFID tag receiver) is located inboard at the higher impedance node of the resonant circuit where relatively higher voltage swings are required to operate the nonlinear switching transistor circuitry.

This disclosure employs an integrated inductor/capacitor resonant circuit to provide a 2× to 20× advantage. The inductor/capacitors are linear circuit elements and, as such, they do not have to overcome the threshold voltage switching effect. They work at lower levels to boost the voltage into the switching part of the charge pump/rectifier circuit. Putting the inductor on chip provides the design with a low voltage swing nodes at the integrated circuit pads as well as the higher voltage swing point at the charge pump input. These low voltage swing nodes at the pads are proportionally less sensitive to parasitic loading capacitance. The antenna backscatter modulator and the pad input protection devices are located at the pads in order to take advantage of the lower voltage swing which increases the chip input power efficiency. Antenna matching is also very important here. Matching transfers the maximum power into the charge pump. Antennas inherently are about 50 ohms and CMOS circuitry inherently is on the order of 2K ohm. If external matching circuit is designed into the antenna, the voltage swing at the chip pad will be larger and much of the input power will go through parasitics to the antenna connections to the chip, the antenna backscatter modulator, and the pad input protection devices. Thus, a key factor is to include a resonant circuit in the antenna interface design to the chip input. FIG. 1A illustrates an operational standard series resonant circuit model to represent a RLC circuit elements with its parasitic bypass capacitance (C₀) that makes up the low-Q tank circuit including an external antenna connected between node (A1) and node (GND), a resonator (COIL), and a charge pump (CP). The LC resonant circuit uses the charge pump input capacitance to form the resonator capacitance (C₁), and uses an on-chip coil inductor (L₁) to forms the inductance for the LC resonant circuit. Additional inductance may be obtained from an external antenna (not shown) connected between node (A1) and node (GND). The coil resistance sets the Quality factor (Q) limiting Resistance (R₁). The parasitic capacitance between node (A1) and node (GND) is the unwanted bypass capacitance (C₀). To lower the voltage swing on the unwanted bypass capacitance (C₀), an embodiment of the present invention uses an integrated inductance (from inductor L₁ and/or the external antenna) to form part of this resonant circuit with the charge pump input capacitance. This provides integrated circuit access to both sides of the inductor (L₁). The antenna terminal node (A1) of the resonate circuit will operate from the lower impedance of the external antenna where the voltage swings are lower than the other inductor terminal node (CP INPUT), which interfaces to the electronic charge pump (CP) or a rectifier circuitry on chip in place of the charge pump (CP). The node (CP INPUT) between the inductor (L₁) and the capacitor (C₁) has a higher voltage swing roughly multiple by the quality factor Q. This has the distinct advantage of higher voltage swing into the charge pump (CP) and keeping most of the parasitic loading capacitance (C₀) attached to the lower voltage swing circuit node (A1) between the external antenna and the resonant circuit instead of the higher voltage swing node (CP INPUT) in the resonant circuit. The closeness of the input antenna circuitry and its terminals, the integrated circuit bonding pads and the necessary pad input protection diodes, e.g., node (A1) and node (GND), are among the parasitics kept at the lower voltage swing. The antenna impedance at the chip input node (A1) is modulated to transmit information out of the RFID tag to be read by the programmer by using backscatter sensing. This backscatter antenna impedance modulator (M and R_{M}) can also be placed directly on the antenna/pad side of the resonator circuit where its parasitic capacitance (e.g., part of C₀) is subject to the lower voltage swings there. This higher voltage swing node on the inside of the coil uses the capacitance (C₁) of the charge pump devices to make up the charge pump as discussed above as well as part of the resonator of FIG. 1. Charge pump efficiency at the minimum antenna input energy level quantifying the charge pump design. Charge pump efficiency may be low, but the tag functions at the lowest input power here.

The higher the coil Quality factor (Q), the higher the resonant circuit voltage boost that appears at the charge pump input. This Q decreases the bandwidth into the charge pump which is desirable in reducing out of band interference. Conversely, if the Q is too high and off center, it can reduce the signal into the chip. The normal integrated coil Q is from 4 to as high as 10 with special design considerations. This Q will provide a bandwidth sufficiently wide to accept both US and European RFID UHF frequencies.

There are some special considerations in constructing the integrated inductor, of which some of them are counter-intuitive for making an efficient RFID integrated circuit. They consist of using thick top metal for the coil and enhancing this with tying multiple metal layers in parallel to reduce the coil resistance and exclude interlayer coupling capacitance at the expense of number of turns. The parallel connected coils are tied together with as many metal to metal vias as the design rules permit so as to include the vias in the coil resistance reduction. The coil metal is also as wide as possible with minimum spacing between the turns to reduce its resistance. The corners should at least be cut at 45 degrees, but round, or spiral coil geometry is best. The coil's spiral shape, width, and spacing, and number of turns are designed for maximum Q. The capacitive load is designed to center the resonant frequency. A shield that has a maximum coverage and minimum spacing between its fingers eliminates the coil forming eddy current loops in the substrate or circuitry under it. About 25% of this higher Quality factor is achieved by using a shield under the coil. This shield is made up of thick fingers pointing all the way inward to the center with the loop with minimum design rule spacing between the fingers. The fingers are connected around their perimeter with a gap in the circular connection of these fingers so the shield will not make a single turn secondary transformer. This shield has a double duty as an energy storage capacitor to the substrate or well and layers beneath it. A poly shield with thin gate oxide under it works well here. However forming a secondary turn should be avoided here. The inductor is kept as far as practical from the shield beneath it. There is a tradeoff of using more layers of metal to lower the resistance to spacing between the inductor and the shield. The manufacturing tolerance of the coil inductance should also be considered. For increased inductance, a MEMS (silicon micro machining) process can be employed to make a higher coil Quality factor for increased sensitivity at additional cost to the tag chip, but the cost impact limits it.

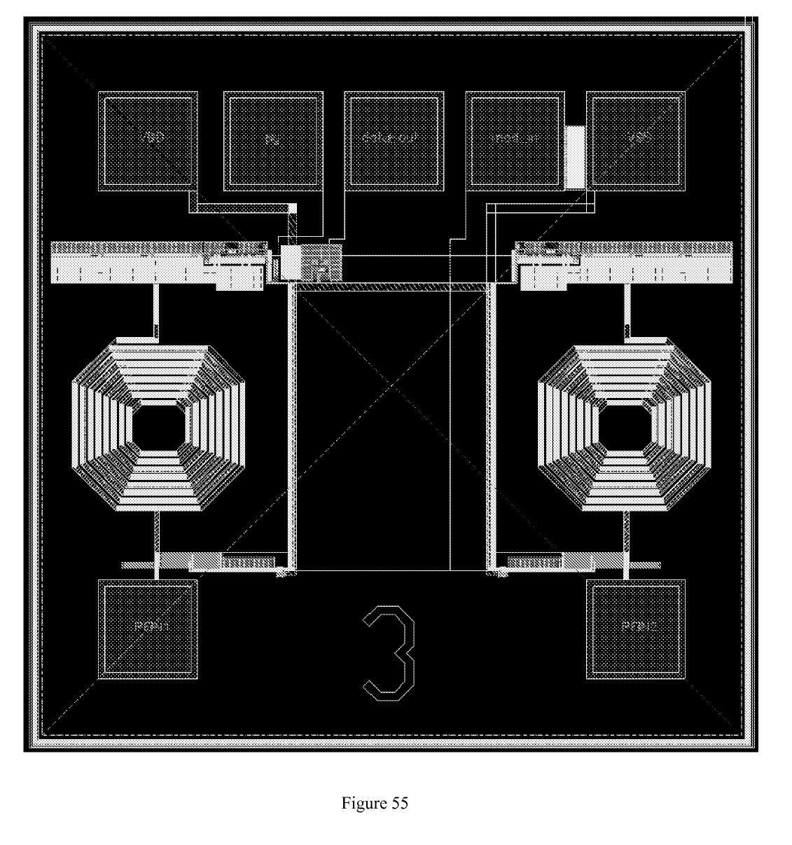

Examples of the resonant circuit are contained in FIGS. 55 to 78 that are included in the “Various Charge Pump Configuration Layout” below. There are many examples of the charge pump circuitry in the layout and accompanying schematics. These are provided to give examples of their implementation, and not to be construed with limiting their implementation to these examples. There are coils with and without shields included in these figures. The shield equivalent layouts have “s” appended to their names.

D. Where the Power is Measured is Rather Important.

There are three important types of power measurements. They are listed below:

FIRST, the power imposed on the antenna, which is normally specified in fractions of watts per square meter. This is the RF field from the reader, which reaches the tag antenna. The field that actually gets to the RFID tag antenna varies greatly in the real world due to absorption, reflections, and multi-paths incurred between the reader and the tag. In order to standardize this measurement, a line-of-sight “ideal” test is made where there are not any absorbers or reflectors present. This provides what is normally the highest field number seen in practice. Higher fields occur in reader RF field “hot-spots” where there is the addition of multi-paths from the tag reader and the tag due to reflecting surfaces along multiple paths from the reader to the tag. Likewise, there are reader RF field “cold-spots.”

The return path from the tag to the reader has similar additional attenuation, which is a major factor in reader sensitivity. The tag should return a signal with sufficient backscatter signal for the reader to detect it. This path, although a serious design consideration, is not the limiting factor in the RFID reader-tag system. The limit is the ability to supply the tag integrated circuit with power to operate.

SECOND, there is chip input power from the antenna at the chip's antenna pads. For comparable numbers, this technology is around 1.0 to 50 microwatts for this invention disclosure, as opposed to the existing technology being around 250 to 400 microwatts. Worst-case process parameters have to be included in this number in order to manufacture RFID tags as a low cost commodity product. The worst-case factor is around 2× to 4× depending on the design agility. Numerous features are contained in this invention disclosure that auto-adapt to these parameter variations and cancel out their effect allowing lower power operation.

These 1.0 to 50 microwatt levels can only be reached if “Native Zero Threshold” MOS devices or equivalent are employed which is part of the startup and low condition operating point enabling technology. Conventional technology uses Schottky diodes as rectifiers. They take considerably more voltage to turn ON, which is around a quarter of a volt.

The difference between the FIRST and the SECOND power definition point is the result of the antenna's energy gathering efficiency and the antenna's match to the integrated circuit input complex impedance.

THIRD, there is the RFID tag electronics internal power consumed by the chip after the RF-AC to DC power converter on chip. Here this technology is around 0.1 to 1.0 microwatt as compared to 50 to 100 microwatts for existing technology as comparable numbers for the entire RFID tag internal chip power consumption. The difference between the SECOND and the THIRD power definition point, is the result of the RFID tag's power supply efficiency. The efficiency decrease accelerates rapidly as the power or input voltage is dropped. This is because RFID tag integrated circuit power supply should have electronic switching circuitry (˜large signal) that requires a threshold of input signal voltage to switch between the required OFF and ON states.

E. Energy Storage on Integrated Circuit Only

The RFID tag chip is powered by UHF energy applied to the tag antenna by the reader. The RF field imposed on the RFID tag is modulated between 100 percent and a lower but stronger modulation amplitude. The amplitude modulation is the means of communication from the reader to the tag. The resting modulation of the RF field from the RFID tag reader is maintained at 100 percent to keep the tag charged to its operation level. This energy charges small integrated storage capacitors on the tag integrated circuit to maintain circuit voltage throughout fluctuations of the UHF power level. Occasionally the RF field is briefly interrupted for the required frequency hops. This capacitance should keep the tag alive during these conditions. External printed capacitors are possible in the 1 to 2 nanofarad range, but significantly add to the cost and reduce reliability of the tag. These conditions weighed against the peak tag circuit drain defines the energy storage requirements of the RFID tag integrated circuit. The amount of energy storage required is set by the difference in input signal energy levels and the time spent at the lower energy level. If the modulation were always at 100 percent, there would not have to be any energy storage, but the communication scheme and frequency hopping requires it even with phase keyed reader modulation. The storage capacitors supply the peak integrated circuit current spikes caused by occurrences like counters resetting where many stages of logic transition coincidently. Other areas of this disclosure, like the grey-code class of logic design and clockless logic design, discuss the design disclosures to minimize these peak current demands. The ultra low current consumption of the RFID tag circuitry is paramount in making an ultra sensitive RFID tag and is the subject of many disclosures included in this patent disclosure. These considerations all work together to make the tag efficient, low cost, and producible.

F. Frequency Hopping and Marginal Operating Provisions

The following list pertains to a tag hold mode that occurs during frequency hopping and shorter null periods experienced by RFID tags. The tag circuit goes into a preserve state mode where operations cease and the state of the tag is preserved as long as possible. When the power comes up above the OK detector, the tag resumes its operation interacting with the reader.

1. Senses the carrier absence during the frequency hopping inter-frequency time periods.

2. Turns OFF clocks to the appropriate parts of the RFID tag circuit.

3. Preserves the RFID tag state so that it can pick up after the frequency hopping or low power interval.

4. Uses extra low voltage circuits like symmetric differential latches that can hold their states at a lower voltage than the other logic circuitry.

5. Cuts back or disables bias currents during this time interval.

6. Puts the tag circuit onto its lowest power consumption and leakage mode.

7. Uses multiple threshold voltage devices to lower leakage during frequency hopping periods.

8. Uses a power supply margin circuit to insure that the energy storage capacitor has sufficient voltage to provide the extra voltage which is lost in decay during the frequency hopping times.

G. Charge Pump

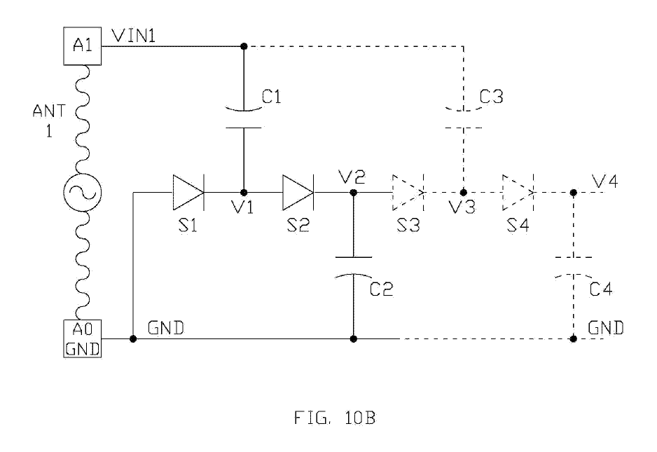

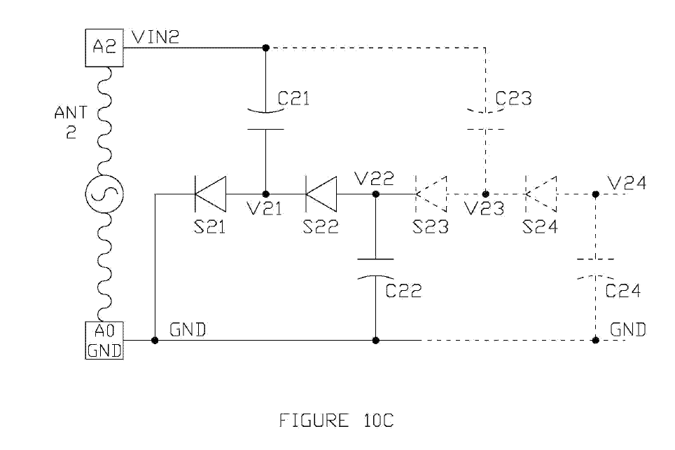

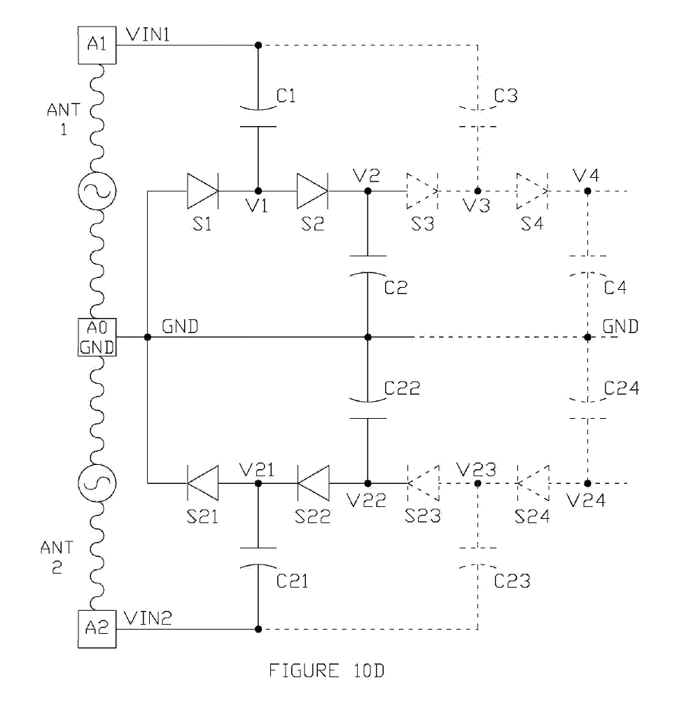

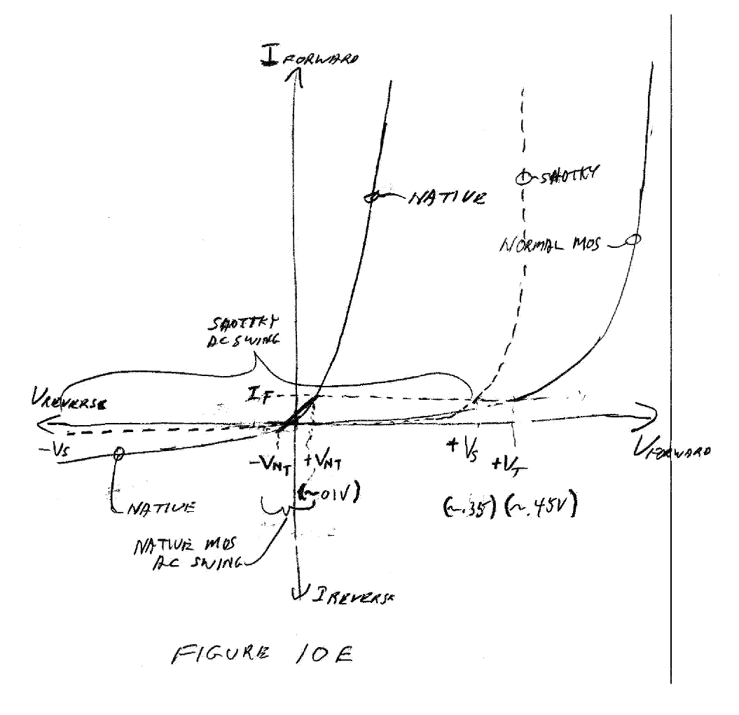

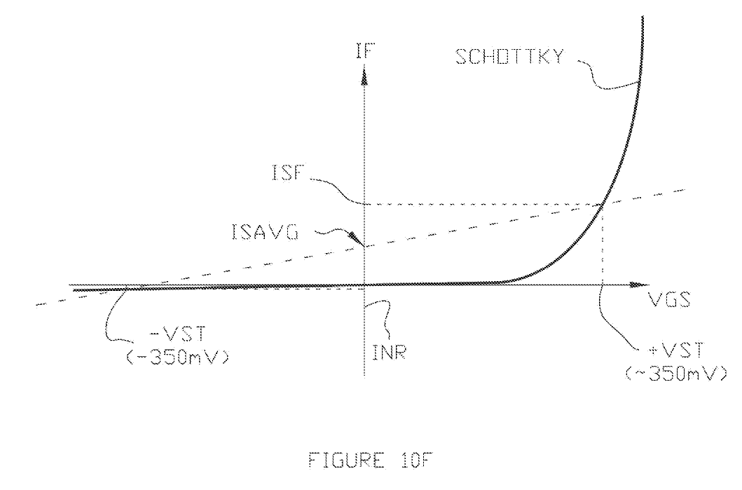

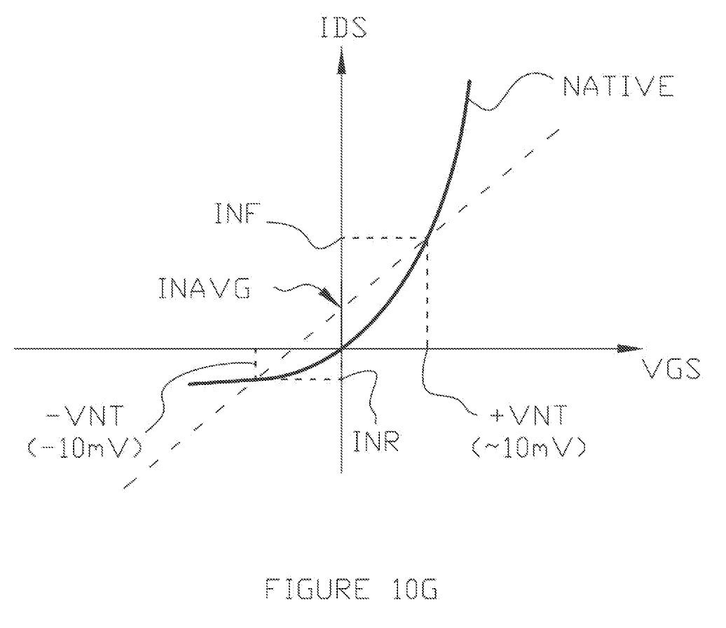

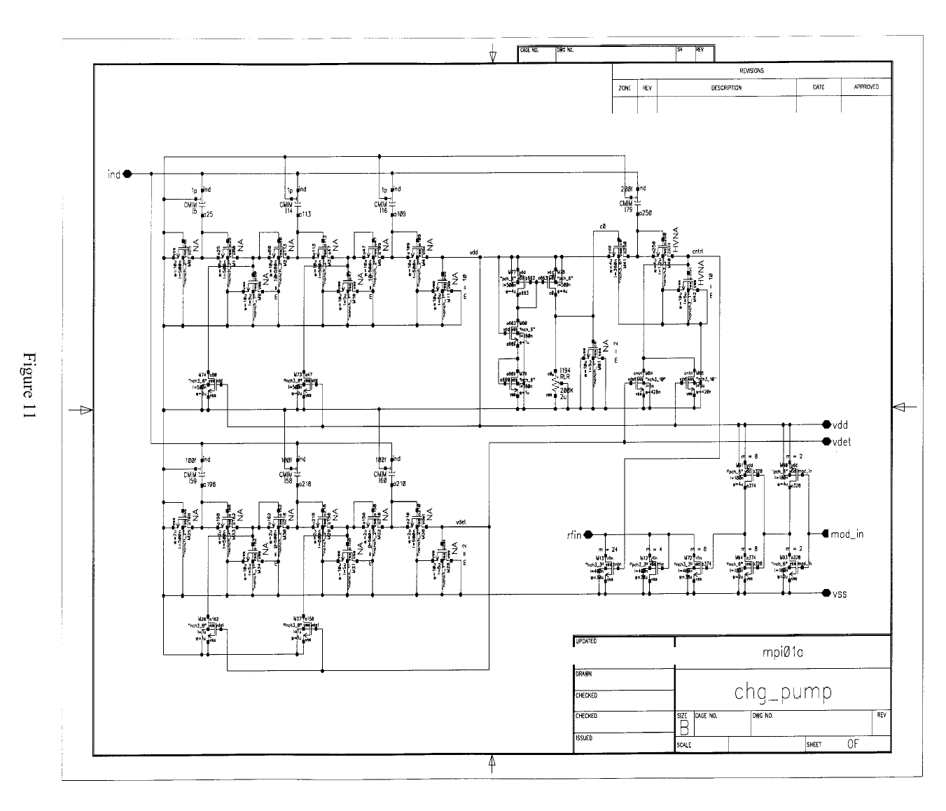

Prior passive (does not use batteries) RFID tag art powers the tag chip from the antenna by means of a charge pump voltage multiplier network similar to the Dickson charge pump cited in the references. Here the prior art employs Schottky diodes to do its rectification switching functions. Schottky diodes are used for RFID tags because they operate at lower voltages and have better ON to OFF resistance ratios, at lower input voltages, than diode-connected MOS or diode-connected bipolar transistors. For example, a diode-connected MOS transistor has its gate electrode tied to its source electrode, and a diode-connected bipolar transistor uses base-emitter or base-collector junction as a diode. These rectifying components have to be realizable within a mainstream integrated circuit process. Mainstream integrated circuit processes should be used in order to keep silicon costs down and insure an adequate supply of wafers. As a revelation from the need for mainstream integrated circuit process, a high volume production of RFID tags will consume more than half the world's production of silicon as RFID becomes commonplace. A very key ultra-low power enabling concept is to use some MOS devices in the charge pump at critical locations which have a near zero threshold voltage. Such devices are “native” MOS transistors and exist in the newer mainstream processes. FIG. 10E illustrates drain-to-source current (Ids) vs. gate-to-source voltage (Vgs) comparison of a native MOS transistor, a regular MOS transistor, and a Schottky diode of equivalent current carrying capacity. FIG. 10F illustrates a more detail view in the operating region of the Schottky diode shown in FIG. 10E. FIG. 10G illustrates a more detail view in the operating region of the native MOS transistor shown in FIG. 10E. It can be seen that in the regular MOS transistor and Schottky diode are not ON (or there is no current flow) until they approaches their threshold voltages of 0.45 or 0.35 Volts while the native MOS transistor is ON (or there is a current flow) at near zero Volts (i.e., at about 10 mVolts) for equivalent current flow. In addition, as shown in FIGS. 10E and 10G, the native MOS transistor has a relatively lower AC voltage swing defined by its lower threshold voltages ±V_{NT}, but has a relatively higher peak backward current INR at the negative part of its AC swing than that of the Schottky diode, thereby resulting in a relatively lower efficiency shown by its relatively lower average current INAVG at less than half of its forward peak current INF while achieving the desired low voltage operation. By contrast, as shown in FIGS. 10E and 10F, the Schottky diode has a relatively higher AC voltage swing defined by its relatively larger threshold voltages ±Vₛ, thereby requiring a much higher voltage operation, but has a relatively higher efficiency shown by its relatively higher average current ISAVG at half of its forward peak current ISF. Some other examples of “native” MOS transistors are referenced in J. B. Burr and A. M. Peterson. Ultra low power CMOS technology, in NASA VLSI Design Symposium, pages 4.2.1, 4.2.13, October 1991, C. C. Enz, F. Krummenacher and E. A. Vittoz, “An Analytical MOS Transistor Model Valid in All Regions of Operation and Dedicated to Low-Voltage and Low-Current Applications”, AICSP on Low-Voltage and Low-Power Circuits, November 1994, K. Mahmood, personal talks on IBM9flp 90 nm Native MOSFET's and EKV Modeling, Qualcomm Technologies, Inc., San Diego, Calif., July 2004, D. A. Neaman, “Semiconductor Physics and Devices”, McGraw-Hill, 2003, E. A. Vittoz, “Micropower techniques”, in “Design of MOS VLSI circuits for telecommunications”, edited by J. Franca and Y. Tsividis, Prentice-Hall, 1993, and E. A. Vittoz, “MOS transistor”, Intensive Summer Course on CMOS & BiCMOS VLSI Design, Analog & Digital, Lausanne (EPFL), Switzerland, September 2003, which are incorporated by reference herein in their entirety. That is, “native” MOS transistors are essentially MOS transistors that have not had their threshold adjusted to the normal threshold voltage specifications. These MOS transistors are simply not included in the threshold adjust masks. Some high volume mainstream MOS processes are available that have native device options available which have feature sizes useful for RFID tags. Therefore, the use of native devices will meet the essential requirements of high volume and low cost.

Due to the light channel doping, the native devices require about twice the channel length to hold off the drain voltage. For this application, since there is not significant drain voltage, the channel length is kept to the shortest functional length. For example, transistors (or diode-connected transistors) should have respective channel lengths adjusted according to their respective maximum hold off voltages. This increases the native transistor performance and speed that is needed to operate efficiently at UHF frequencies.

An efficient charge pump circuit should use non-linear rectifying devices for switches. These switches have a large OFF to ON impedance difference or spread. As stated, Schottky or other diodes are typically used in RFID tags, but these rectifiers can be constructed from transistor switches. Ideally, these transistor switches require the addition of a control voltage to operate them. However, they can be hooked up in the diode configuration which has the body and gate terminals tied to the drain terminal. This results in a two terminal element with diode characteristics. Here the MOSFET device behaves like a diode turn-ON voltage which is defined by the threshold voltage of the MOS transistor. The diode knee voltage is the threshold voltage of the MOSFET.

For the passive RFID tag, there is no bias voltage to operate the first switch without the use of a battery. The operating voltage for the first switch should come from the antenna. The common low voltage device is a Schottky diode with a turn-on voltage in the order of a quarter of a volt. This requires that there is a lot of power available at the (50 to 70 ohm) antenna to get the process started let alone maintain operation through backscatter modulation. With enough input voltage swing, once in operation, the Schottky diode has reasonably low OFF leakage for an efficient charge pump that operates well at UHF frequencies, but the Schottky diodes require too much voltage swing to get started at the desired RFID Tag antenna input power levels. Higher impedance antennas help, but this increases the voltage swing at the pads results in a lot of the power going around the charge pump through the input parasitics.

A key counter-intuitive concept is to use a switch that does not turn OFF. This is where the native MOS device is employed. The concept is to use switches that turn ON harder with a little input voltage above zero volts and does not turn OFF very well when the antenna input voltage goes a little below zero. This makes a very leaky low efficiency charge pump, but it solves the problem of operation at zero volts which is required to get the RFID tag into operation. In reality, it does not matter how efficient the charge pump is at voltages above the tag system startup voltage, everything has to just work at the lowest possible antenna chip input voltage. Extra energy is stored on chip to carry the tag through variations in input power. Therefore the best device, within reason, is one that the highest OFF to ON resistance ratios around zero volts. For an RFID Tag, the circuit element having the best diode characteristic around zero volts may be viewed as the circuit element having the greatest slope or gain around the zero volt bias point. This is not necessarily the circuit device with the highest ON to OFF impedance at higher operating voltage.

The charge pump is inactive until it has enough input voltage swing to turn ON its first diode switch. This conduction rectifies some charge into the tag from the antenna. In the second or reverse part of the input voltage cycle, this switch does not fully turn OFF causing a back flow of charge during this OFF part of the input voltage cycle. There is more forward charge transferred during the positive part of the voltage input cycle than the loss of charge during its reverse cycle resulting in a net charge buildup. The relatively low semiconductor diode conduction levels keep the rectifier-storage capacitance time constant long enough to bridge the UHF input cycle times. This results in a very low efficiency rectifier, but there is some charge built up on the tag that makes up the tag power supply. A little charge buildup is better than no charge buildup resulting from a diode rectifier without enough voltage to turn it ON. This disclosure employs native near zero threshold transistors that operate in the active region with zero volts applied to perform this rectifying function.

Since the charge pump operates in the UHF region, these devices should operate sufficiently well in this region. Native MOS devices have intrinsically lower channel doping than normal threshold voltage adjusted MOS devices. This is because a channel implant process step is used to adjust the MOS device threshold voltage resulting in higher channel doping. The low-doped intrinsic channel of native MOS devices build up wider depletion regions as voltage is applied between the source and drain areas. This wider depletion region will expand from the drain to the source regions and result in drain-source punch-through. These wider depletion regions require higher than normal drain-source separation or longer channel lengths. These longer MOS channel lengths do not perform as well at higher UHF frequencies required for operation in the RFID Tag's reader field. Non-Quasi static conditions in the channel get worse at long channels using higher frequencies and trap charge in the channel. Non-quasi-static conditions in the MOS channel do exist for longer channel length devices and should be considered in selecting process geometry. Which MOS devices to use for the native or zero threshold voltage are an important tradeoff in designing the charge pump and will vary with circuit configuration. The transistors that provide the lowest operating antenna input voltage at the given circuit load is the normal optimization criteria.

Another key element for increasing RFID Tag sensitivity is to make the native device channel length shorter than the process design rules permit, but not shorter than the process critical minimum dimensions which are used for the normal CMOS transistors. Native MOS with short channels that work at low drain voltage work well for these charge pump circuits operating at UHF and higher frequencies. This can be done since the process design rules are made for the MOS transistor to hold off the highest specified process voltage and the RFID tag charge pump is operating at much lower voltages. This is especially true for the first transistor in the charge pump input where the device should operate at its best near zero volts. The drain-source spacing can be adjusted according to the maximum voltage it should hold off when maximum power is applied to the chip. In reality, the very first MOS device in from the antenna sets the sensitivity for the entire RFID Tag electronics much as the input stage of a high sensitivity amplifier does. Every succeeding MOS device has more voltage to operate with after the first MOS device gets started.

Still another Key element for high RFID Tag sensitivity is to keep the first stage as light and easy to operate as possible. The first stage has to start operation at the lowest possible input level, but it can operate at a lower efficiency or not pump as much voltage as the next stage. Since smaller charge pumps will start at lower voltages, a small charge pump may be used to bias the main charge pump for decreasing the minimum operating voltage. One or more smaller charge pumps can also be used as a data stripper since smaller pumps react faster to input changes.

Referring to FIG. 10C, when multiple antennas are used, they can be differentially combined in a manner where one pump pushes the positive supply (Vdd) up and the other pushes the negative supply (Vss) down. In this manner, the energy of the two charge pump or active rectifier circuits add to the voltage instead of the current as a result of parallel connection.

H. Active Rectifier

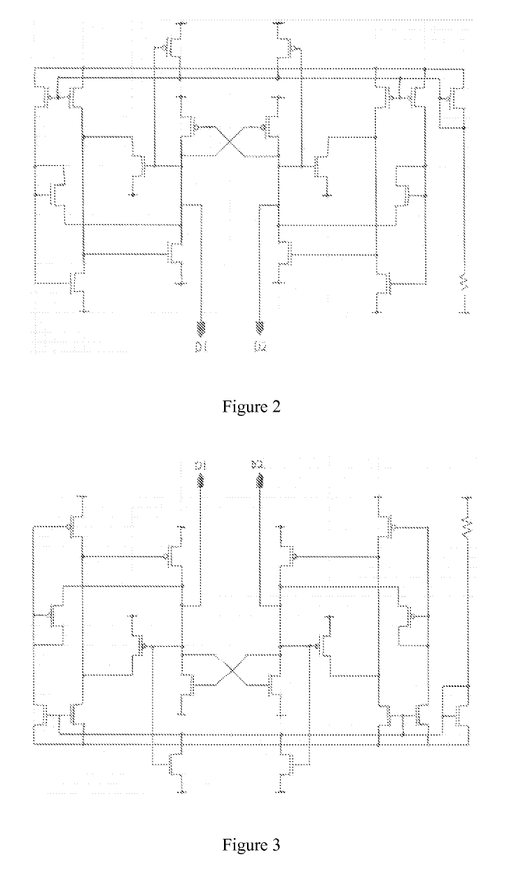

The active rectifier consists of actively controlled MOS switches, instead of rectifier diodes that are normally constructed with either Schottky diodes, diode-connected MOS transistors, or p-n junction diodes. The active rectifier has an ideal diode transfer function in that there is no forward voltage drop in the ON-state, and no appreciable leakage current in the OFF state. The other diode rectifier circuits require a forward drop and have a poor OFF-state reverse leakage current. The active rectifier gain at zero volts defines how well this circuit switches around its zero volt input switching point. The battery biases this circuit. The active rectifier is ideal for battery assisted RFID tags in that it switches at 0 volts. The current drain should be kept down to leakage currents when not in use. The active rectifier should wake up upon applying power to the antenna. It can then operate like a passive RFID tag, or the reverse—the passive RFID tag can start the bias current using native transistors. The primary advantage of the active rectifier is that it operates efficiently due to the gain loops. The primary disadvantage is that it consumes current waiting for its wakeup. This can be taken care of through the use of a small native device charge pump. This inefficient zero volt startup pump only has to provide the bias currents to the active rectifier long enough to get it started. Examples of active rectifier circuit schematics are shown in FIGS. 2 and 3. FIG. 2 is a schematic of an active rectified, and FIG. 3 is a schematic of an active rectifier with polarity revised.

I. Staged Rectifier/Charge Pump to Wake-Up Tag Power Supply

A voltage regulator measures the operational voltage of the ring oscillator and provides a regulated voltage for powering the logic. This provides the RFID circuitry with a minimum operating point voltage, which is guaranteed to be consistent with integrated circuit processing parameters and the environmental conditions at the RFID tag. Excess energy in the form of voltage is stored in small integrated capacitors both before and after the regulator. When the tag logic is powered with its minimum functional current, the limited current drain keeps the storage voltage maintained at its maximum, providing an operating margin, which bridges signal variations during weak or fluctuating reader signals. Thus, an on-chip voltage regulator is employed for the chip power where previous art has no power conserving regulation for the logic during normal operation. Here, system issues such as modulation type, level, duration, field patterns, and stability come into play. Based on these, operating margins are established.

A series of power good signals are derived from the oscillator voltage. These signals indicate that the unregulated voltage stored on the integrated capacitor is sufficiently high to power the chip through the modulation and frequency hopping scenarios of the RFID tag reading protocol. After the reader has been calibrated and initialized in a power up sequence, different signals indicate various power supply voltages for insuring that the RFID tag's circuit power level is sufficiently high for the tag to participate in the reader communication. Some of the various power supply voltage signal logic signals indicate that:

1. Tag power has achieved a sufficient level to start the oscillator,

2. Ok to operate the tag state machine,

3. Read tag's memory data into internal latches,

4. Ok to transmit back to the reader,

5. Ok to program memory,

6. Chip voltage near maximum—reflect energy back to limit voltage,

7. Put tag into a sleep mode to preserve its state,

8. Tag States may be lost due to near zero voltage.

J. Energy Limiting for Input Overdriving

In certain embodiments, the RFID tag not only needs a very high sensitivity, but it should also operate at very high field levels. The RFID tag should function normally without damage when it is placed in close contact with the reader's antenna mouth because, in the field, people may place the tag close in proximity to the reader's output antenna mouth (and/or forces the tag to operate at very high filed levels) to check its operation. Here the antenna input voltage to the chip is potentially around 7 volts which is applied to the 1.8 to 3.5 volt semiconductor process. Absorbing this excess antenna energy requires large input protection diodes and dissipate a lot of heat. This will not work because of the parasitic capacitance of the protection diodes at this critical node pair will bypass the desired RF energy around the charge pump. The small RFID tag integrated circuit does not have enough mass to dissipate this energy. The charge pump should reflect energy back out the antenna instead of absorbing it by means of mismatching the input impedance. This is performed in the charge pump circuitry.

K. Rotating Critical P-Channel Transistors by 45 Degrees

Rotating critical P-Channel devices by 45 degrees is done to take advantage of the different crystal structure orientation. Normally, the silicon devices are orientated in the 110-crystal plane as indicated by the flat edge on the wafer. Rotating the transistor by 45 degrees orients their channel in the 100-crystal plane thus enhancing the conductivity of the P-channel devices by about 20%. The change in leakage current should also be taken into account since the leakage is increased also. The opposite effect applies to the N-channel devices, which may be used to an advantage in reducing the leakage at the expense of conduction. The N-channel effects for comparison are about 15% different due to the 45 degree rotation.

L. Bandgap Self-Cascoded MOSFET (BgSCFET) Device for Low-Power Applications

1. Abstract of BgSCFET

Cascoded circuits are useful for increasing the output impedance of MOSFET devices. They also reduces the Miller feedback from the output drain to input gate of the MOSFET. The only setback is that cascodes require generating bias voltages and they also increases noise coupling between transistors through their common bias voltage wire. A Bandgap Self-Cascoding MOSFET (BgSCFET) device is disclosed which has many advantages here.

A Bandgap Self-Cascoded MOSFET (BgSCFET) circuit which operates best in weak inversion and in low leakage OFF-state regions is disclosed. The BgSCFET circuit has been shown to exhibit in excess of a twenty-fold increase in the output resistance and similar reduction of OFF state leakage current. This is without paying a significant penalty in silicon real estate and power. The circuit has demonstrated significant increase in gain in the input stages of operational amplifiers, reduced leakage current for OFF state logic, switches, memory, and improved performance from analog current copier circuits.

2. Introduction to BgSCFET

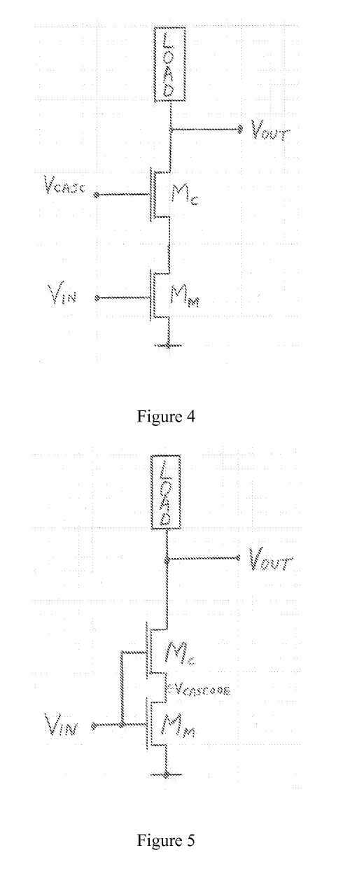

A conventional cascode circuit is shown in FIG. 4. The cascode circuit consists of two transistors (Mm, Mc) connected in series. They are usually biased to operate in saturation. There are two major reasons for the use of cascode circuits [A. Abidi, “On the operation of cascode gain stages,” IEEE J. Solid State Circuits, vol. SC-23, no. 6, pp. 1434-1437, 1988, which is incorporated by reference herein in its entirety]. First, the output resistance of a cascode circuit is higher than that of an ordinary MOSFET. Secondly, input capacitance can be kept low due to reduced miller effect on the main transistor. On this device, the capacitance reduction is not as much as the full cascode circuit. In many applications such as current memory circuits [G. Wegmann and E. Vittoz, “Basic principles of accurate dynamic current mirrors,” Proc. IEEE, vol. 137, no. 2, pp. 95-100, 1990, and S. Daubert, D. Vallancourt, and Y. Tsividis, “Current Copier Cells, Electron Letters, vol. 24, no. 25, pp. 1560-1562, 1988, which are incorporated by reference herein in their entirety], capacitive transimpedance amplifiers, low input capacitance may not be required. Yet such circuits can benefit from an increased output resistance, leading to higher gain in amplifiers and lower error in current copier circuits.

For proper operation of a cascode circuit, the it is required to be biased in saturation. This is usually accomplished by generating a gate bias voltage, for the cascode transistor, on-chip at the cost of increased power and real-estate. Furthermore, the performance of certain class of cascode circuits, called regulated cascode circuits, depends critically on the bias currents [E. Sackinger and W. Guggenbuhl, “A high-swing, high-impedance MOS cascode circuit,” IEEE J. Solid State Circuits, vol. SC-25, no. 1, pp. 289-298, 1990, which is incorporated by reference herein in its entirety]. An alternate cascode circuit, called bandgap self-cascoded FET (BgSCFET), is disclosed for use in applications where low-power and minimal real-estate are important. The cell design is simple, and unlike existing cascode circuits, does not require significant additional real-estate and power for its operation. It also eliminates noise coupling between stages through the common cascode gate bias connection. In this disclosure, the operation of BgSCFET is explained. Test results from both n-channel and p-channel BgSCFET test-chips are disclosed. The enhancement of performance of amplifier, logic, low leakage switches, and current memory circuits by the use of BgSCFET is evidenced below.

3. Operation of a BgSCFET

A BgSCFET consists of two appropriately scaled transistors (a Main transistor Mm, and a Cascode transistor Mc), with both their gates tied to a common input voltage (Vin), as shown in FIG. 5. The bandgap voltage to drive the cascade circuit is derived in a manner similar to the familiar bandgap reference circuit. When two transistors with different W/L ratios are biased with an identical drain-source current, the gate-to-source voltages are different due to their bandgap. When these two transistors are connected in series (instead of parallel as in common bandgap voltage reference circuits), the two W/L ratios of Mm and Mc force transistor biasing at different current densities. This provides a bandgap voltage difference, which is used to bias the cascode pair instead of the normal cascade bias voltage (Vcasc). The current in the cascode transistor Mc is spread out over the width of the physically wider transistor to provide a lower gate-to-source voltage (Vgsc) than that of the physically longer signal transistor Mm gate-to-source voltage (Vgsm). The drain-to-source voltage of the main transistor is higher than the gate-to-source voltage of the cascade device by the bandgap voltage. When the gates are tied together, the junction between the two transistors (drain of Mm to source of Mc) is raised by the bandgap difference. The island of active area between the two transistors is important in that the two transistors merge into a single device with a varying current density, thus losing the cascade effect. By joining a narrow and a wide channel in a T-shaped like transistor, the cascode properties do not have the same pronounced effect. The addition of a block of diffusion between these two “Tee” transistors produces this bandgap cascode effect. This series method of deriving a bandgap is useful in generating a bandgap reference circuit also.

The resultant structure is very similar to a conventional cascode circuit shown in FIG. 4, with the exception that the cascode transistor (Mc) does not require additional bias. The circuit operates in the bandgap self-cascoded mode best when Mc is biased in weak inversion, (Mm may operate in weak or moderate inversion). This is made possible by two reasons. First, in weak or moderate inversion, the main transistor (Mm) is required to be larger for only a few times the thermal voltage, VT=kT/q. Since the thermal voltage at room temperature is only 26 mV, Mm can operate in saturation only with a one or two tenths of a volt. Secondly, when a transistor is biased in weak inversion, it does not require the normal threshold drop across its gate to source for channel conduction. These two factors allow the transistors to remain approximately in saturation when Mc is biased in weak or moderate inversion. When the two transistors are biased in saturation, the circuit operates essentially as a conventional cascode circuit, with the increase in output resistance being given by gm2/gds2, where gm2 is the transconductance of Mc, and gds2 is its output impedance. On the other hand, when the circuit is biased in strong inversion, the gate to source voltage of Mc is greater than a threshold drop, causing the main transistor to operate as a switch (low output resistance), and the net output resistance is lowered, being equal to the output resistance of Mc.

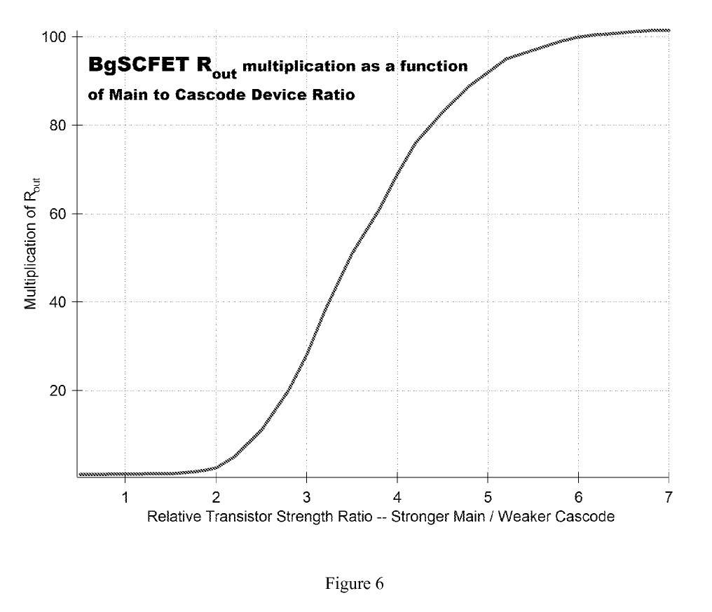

The W/L ratios of the two transistors are scaled in order to ensure that both the transistors are biased in or near saturation, so that a large output resistance is obtained. For typical values of sub-threshold range, the main transistor (Mm) is biased near saturation. Therefore, it is desirable to keep the gate to source voltage drop in the cascading transistor as small as possible. This can be achieved by making the W/L ratio of Mc to be larger than the W/L ratio of Mm. For a BgSCFET circuit this ratio R=(W/L)c/(W/L)m is the main design parameter. The BgSCFET circuit was simulated in PSPICE for different values of R. The results of the simulation, shown in FIG. 6, exhibit the expected dependence of the output resistance on R. The output resistance was found to increase with an increase in R, the increase tailing off for R>6.

More specifically, FIG. 6 illustrates simulated output resistance of p-BgSCFET (normalized to the output resistance of a p-FET of same dimensions) versus the ratio between the main transistor length (Lₘ) to cascode transistor length (L_{c}). A ratio of 3 times stronger (cascode transistor to main transistor) produces around a 30 times higher drain output resistance in the BgSCFET device. Going beyond a ratio of 6 times provides diminishing gains where the advantage is around 100 times for the device simulated.

An alternate form of achieving the BgSCFET approximation is to use two different threshold voltage transistors in the cascade stack. Here the Main transistor employs a lower threshold voltage than the cascade transistor. In the limit, the main transistor can be implemented as a native transistor which has near-0 threshold voltage.

In considering the input capacitance, the BgSCFET does not enjoy all the benefits of greatly reduced Miller feedback since there is a Miller feedback path from the cascade transistor to the input. The Miller effect is reduced by a factor derived from the difference in the cascade transistor area to the main transistor area. The main transistor does not see variations in drain voltage that produces the miller effect on it. The cascode transistor can be designed minimize the Miller feedback effect to obtain some advantage.

When this BgSCFET is switched to the OFF state for logic and switching applications, the drain-to-source leakage current is significantly reduced. This is because the main device does not have significant drain-to-source voltage to pass the OFF leakage current. Instead all OFF drain voltage is across the cascade device where it produces a leakage current. However this BgSCFET cascode transistor OFF leakage current path should go through the series main BgSCFET device. This OFF leakage current path sets the voltage on the node between the BgSCFET transistors to a point that supports a low leakage current. In doing so, the BgSCFET cascode device gets back-biased (negative gate-to-source voltage) resulting in a significant reduction of the BgSCFET overall OFF leakage current. A merged version of the BgSCFET device does not have the benefit of this lowered OFF state leakage.

4. Results and Discussion of BgSCFET

BgSCFET circuits were fabricated using commercially available a standard CMOS process through a prototype shuttle run. The test chip contained differential amplifiers, current memory circuits, low leakage switches, memories, and logic constructed with BgSCFETs and regular MOSFETs of similar dimensions. Test structures were also included to measure the D.C. characteristics and noise performance of the BgSCFET and a regular MOSFET of same dimensions. The MOSFET dimensions were W/L ratio of 3/10. The dimensions of the main transistor of the BgSCFET were chosen to be W/L ratio of 3/8, and that of the cascode transistor was W/L ratio of 3/2 for the overall equivalent W/L ratio of 3/10.

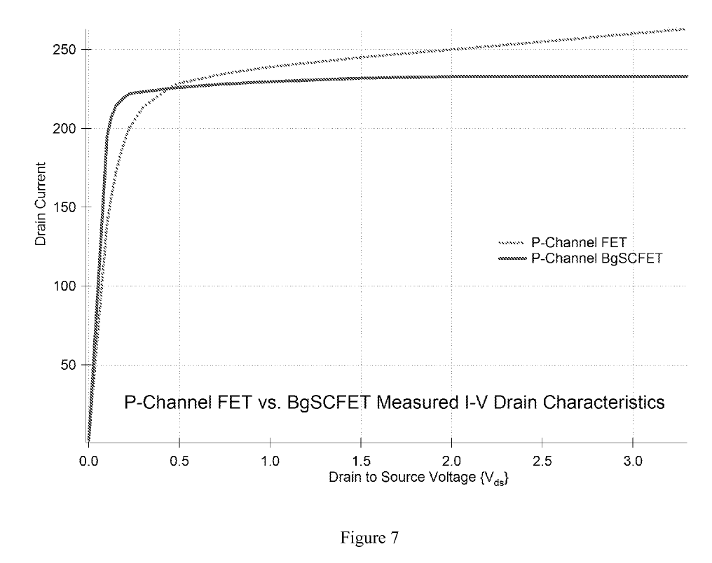

The D.C. characteristics of the BgSCFET and the MOSFET were measured using a HP 4145 dynamic signal analyzer. In order to carry out meaningful comparison, both the devices were biased in weak inversion at a nominal drain current of 225 nA. The results of the test are shown in FIG. 7.

More specifically, FIG. 7 illustrates measured I-V characteristics of a p-BgSCFET and a p-FET of same dimensions (W/L ratio of 3/10). The BgSCFET has a steeper slope near 0 volts and is much flatter as the drain voltage is increased. This represents higher gain and higher output resistance respectively.

It can be easily seen from the FIG. 7 that the BgSCFET exhibits lower output conductance compared to an ordinary MOSFET. From FIG. 7, the output conductance of the BgSCFET was calculated to be 3.675 nA/V at a drain current of 225 nA, and is 22.5 times smaller than the MOSFET of same dimension. The calculated output conductance is larger than that predicted by simulation because of the inaccuracy of model in weak inversion when BSIM models are used. The use of a compact model for low power operation such as the EKV (Enz, Kirummenacher, Vittoz) model found in most modern circuit simulators corrects this problem. The increase in the output resistance used for this example is less than optimum because for the channel dimensions chosen, the main transistor is biased at the edge of saturation, causing its output resistance to be lower than optimum. The output resistance was also found to be dependent on the channel lengths and widths of the two transistors. Further work, which is dependent on process parameters, can be performed to optimize these channel lengths and width relationships for largest output resistance, minimum real-estate, and other desired parameters.

A similar experiment was carried out using n-channel BgSCFETs of same dimensions as the p-channel devices. The output conductance of the n-channel BgSCFET biased at 210 nA was measured to be 3.162 nA/V, and is 18 times smaller than the ordinary n-channel MOSFET.

The BgSCFET circuits were used to construct CMOS differential amplifiers. The single stage differential amplifier was biased at a relatively large current of 500 nA. Even at these increased currents, the low frequency amplifier gain was found to be 56.75 dB, which is twelve times greater than that of an amplifier constructed with ordinary MOSFETs and biased at same current level. Thus, the output resistance of the BgSCFET differential amplifier is increased twelve times, which corroborates the data on the measured output resistance of a p-channel BgSCFET. The increase in BgSCFET output resistance is more pronounced at smaller current levels, as the transistors are biased deeper in weak inversion. For a 1 nA bias on a BgSCFET differential amplifier, gains larger than 120 dB has been achieved. Therefore, BgSCFET is ideally suited for use in ultra low-power circuits required in RFID tags and other analog integrated circuits.

The BgSCFET circuits were also used in current copier cells, in which the gate voltage corresponding to the drain current flowing through a MOSFET is stored on its gate. The finite output resistance of the cell causes an error between the current memorized and the current read out due to a change in the output voltage during readout. The current copier cells built with BgSCFET circuits were operated with less than 0.1% absolute error, indicating that the increase in the output resistance has been sufficient to render the error due to finite output resistance insignificantly small.

The noise in the BgSCFETs and the MOSFETs were measured using a HP 3541 dynamic signal analyzer. No difference in the noise power spectrum was noticed between a BgSCFET and a MOSFET of same dimensions.

5. Conclusion of BgSCFET

A new self-cascoded FET circuit is disclosed here. Compared to a single transistor, the BgSCFET adds minimal area to the unit cell and does not require extra power dissipation or additional bias supply lines for operation. In the BgSCFET device example, the output resistance was found to be more than 20 times larger compared to that of a MOSFET of same dimensions, and the BgSCFET off-state leakage was found to be a factor of 20 times lower. The BgSCFET circuits can be employed in a variety of situations—from increasing the gain in amplifiers, enhancing the performance of current copiers, to reducing the OFF switch leakage current. The channel lengths and widths of the two transistors can be optimized for the largest increase in the output resistance or smallest OFF leakage current. The main transistor can be made with less than the normal minimum channel length, for increased performance, since this transistor does not hold off any drain voltage, which causes drain-to-source punch-through. In other words, the drain does not incur depletion region widening produced by applied drain voltage. The main transistor can also be made with a native transistor to enhance the effect. Use of native transistors for both devices lowers the operating voltage required and increases the output swing.

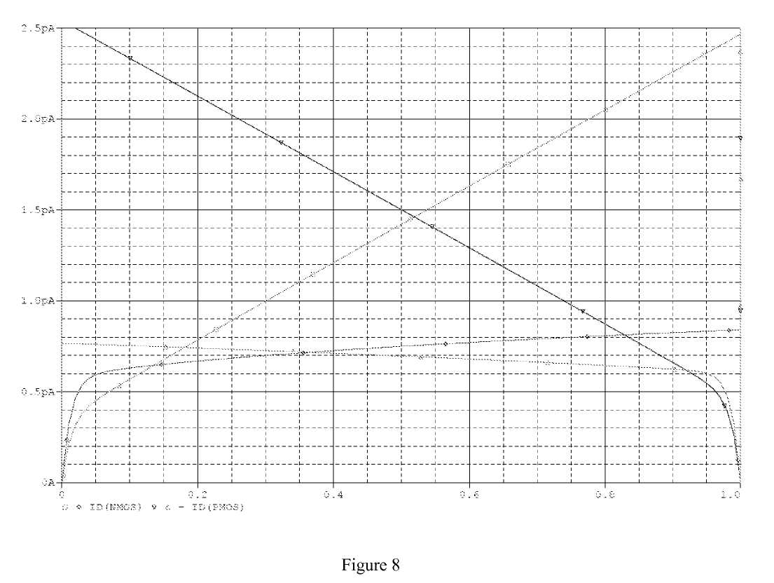

FIG. 8 illustrates CMOS Drain to Source “OFF” Leakage Current Reduction for Series-Coupled Bandgap Compound Transistor Configuration. In FIG. 8, the X axis is the drain to source voltage normalized from 0% to 100% of the rated drain voltage.

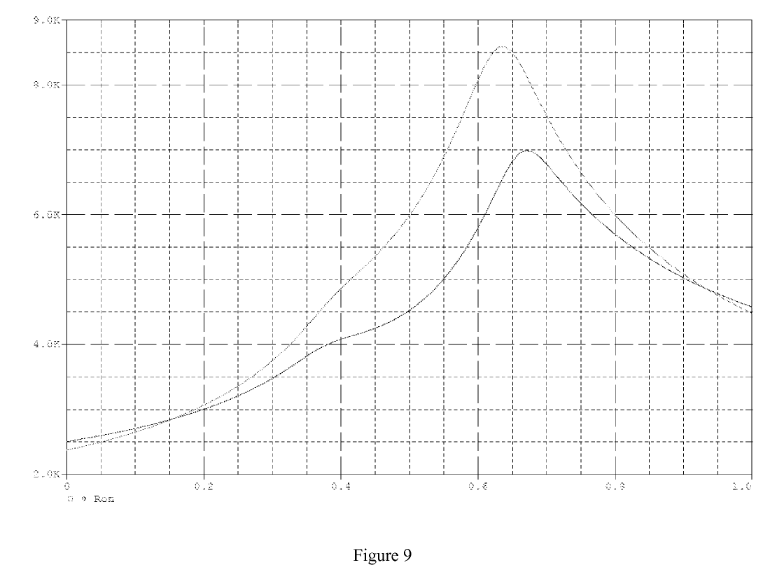

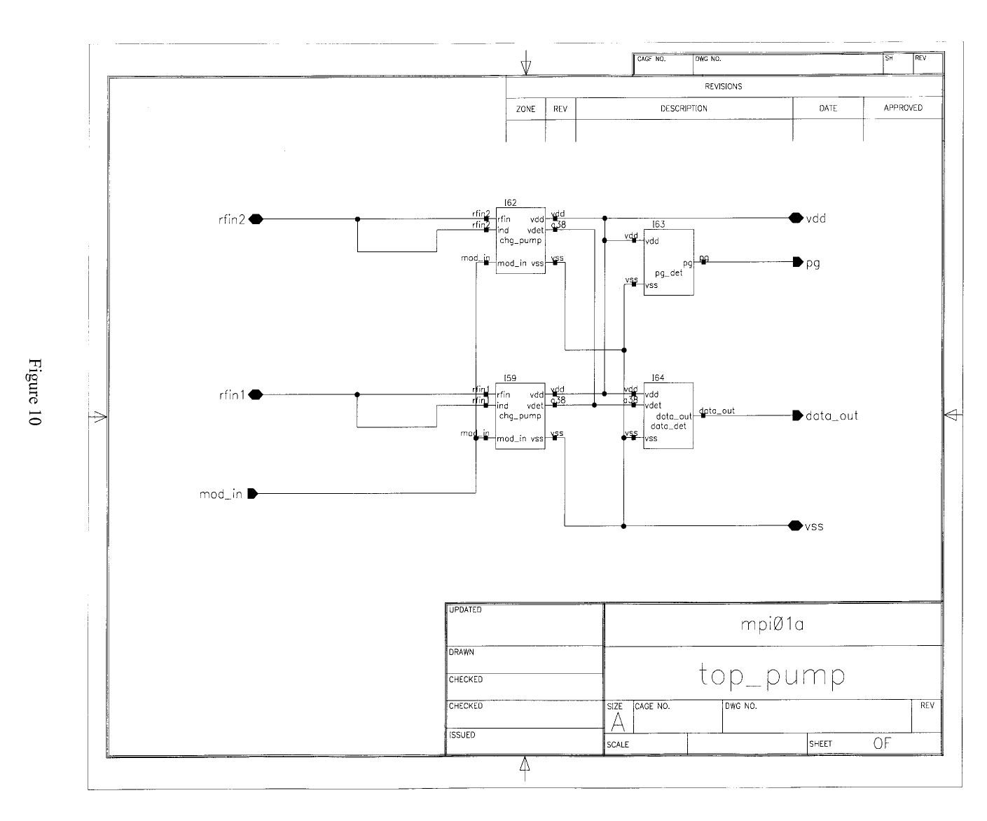

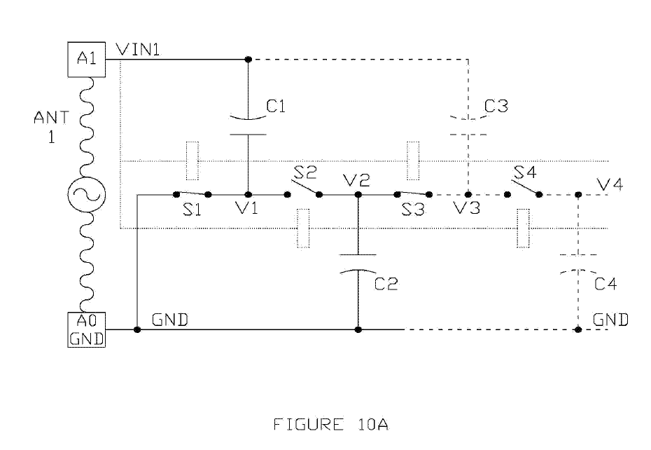

FIG. 9 illustrates reduction of “ON” Resistance of CMOS Transmission Gate for Series-Coupled Bandgap Compound Transistor Configuration (to shown that the BgSCFET reduces “ON” Resistance). In FIG. 9, the X axis is normalized for 100% of the rated transistor voltage.

M. Charge Pump Schematics & Simulation Plots

The RFID tags should operate very close to the tag reader as well as the normal minimum field location. In this case, a large RF power is available from the antenna. For 100 mW on a 75-ohm antenna, for example, the source voltage is 7.75V amplitude. Such high amplitude, if rectified directly, would destroy the sensitive MOS devices by gate breakdown. The circuitry disclosed here includes protection circuitry to prevent voltage overdrive at high RF power levels. Additional transistors connected to the output power supply level are use to bleed higher currents from internal nodes of the multiplying charge pump. This ensures a certain level of output supply regulation at moderate RP power inputs. A separate, single-stage, charge pump (driving the signal named “cntrl” in the mpi01a and mpi01b “chg_pump” schematics) is used to turn ON a NMOS device at the RF input pad. This is a large, high voltage device (thicker oxide), whose increase conductance with the increasing RF power level determines an increase fraction of the incident RF power to be reflected back to the antenna rather than absorbing it. The integrated resonant coil helps with correctly implementing the protection mechanism, since the RF input node is much lower impedance than the input of the charge pump.

Two antennas can be combined very easily, by using two charge pump independent circuits with the outputs connected together. This arrangement can be used for an arbitrary number of antennas. At least two antennas need to be used for tag orientation independence with the most efficient antennas. A single antenna should depend on signal path diversity and the antenna design to provide tag orientation independence. This antenna application can use a more divergent pattern at the expense of maximum sensitivity. It cost about 3 or 4 db.

The Data Stripper (“data_det” cell) uses a separate charge pump (part of the “chg_pump” cell) with lower charge storing capacitor at the output (“vdet” node). This charge pump reacts much faster to the incident RP power level. The current generated by the “vdet” level is filtered with an integrated RC filter, then two current comparators with built in threshold (intentional MOS device mismatch) are used to generate edges for the higher or lower input RF power levels. An output RS-latch constructed with NAND gates is used to latch the data.

Data strippers from multiple antennas can be combined the same way as the main charge pump. An auxiliary charge pump is needed for each antenna, with a single data detector “data_det” cell using the combined output from all the auxiliary charge pumps.

Data transmission from the tag to the reader is performed by antenna backscattering. The output data is used to modulate the input impedance of the tag integrated circuit (the impedance that the antenna sees). This is implemented by using a high voltage, thick oxide NMOS device driven directly by the modulation signal. It is connected directly to the antenna pads.

A power good signal (“pg”) is derived from the main power supply voltage. A simple implementation is shown in the pg_det cell. It uses a high voltage NMOS device (with a higher threshold) than the nominal NMOS thin oxide device) and a PMOS current source with a built-in hysteresis. Other power up signals are generated in the oscillator circuitry.

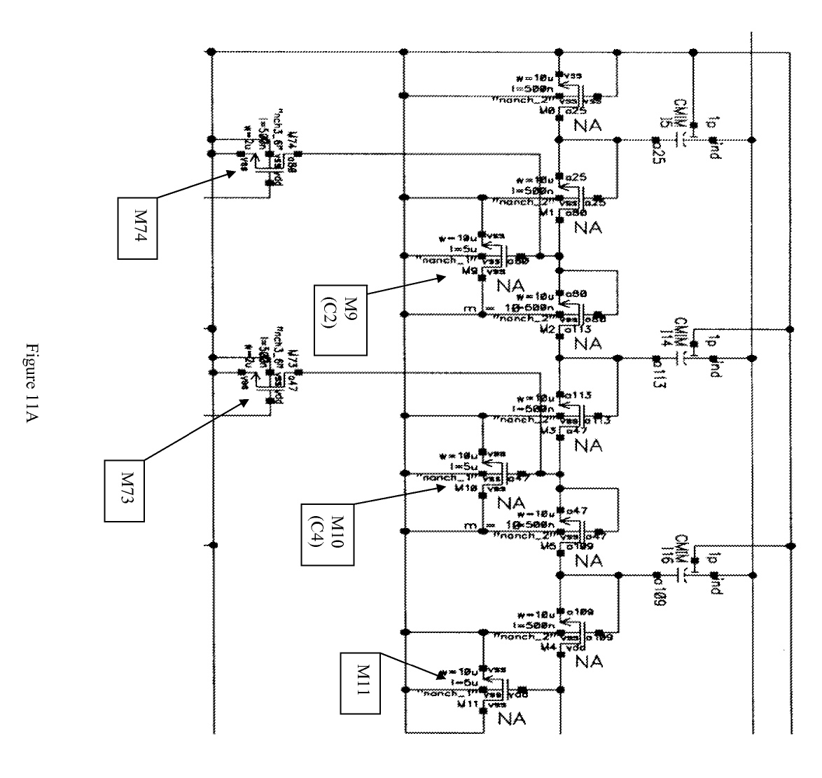

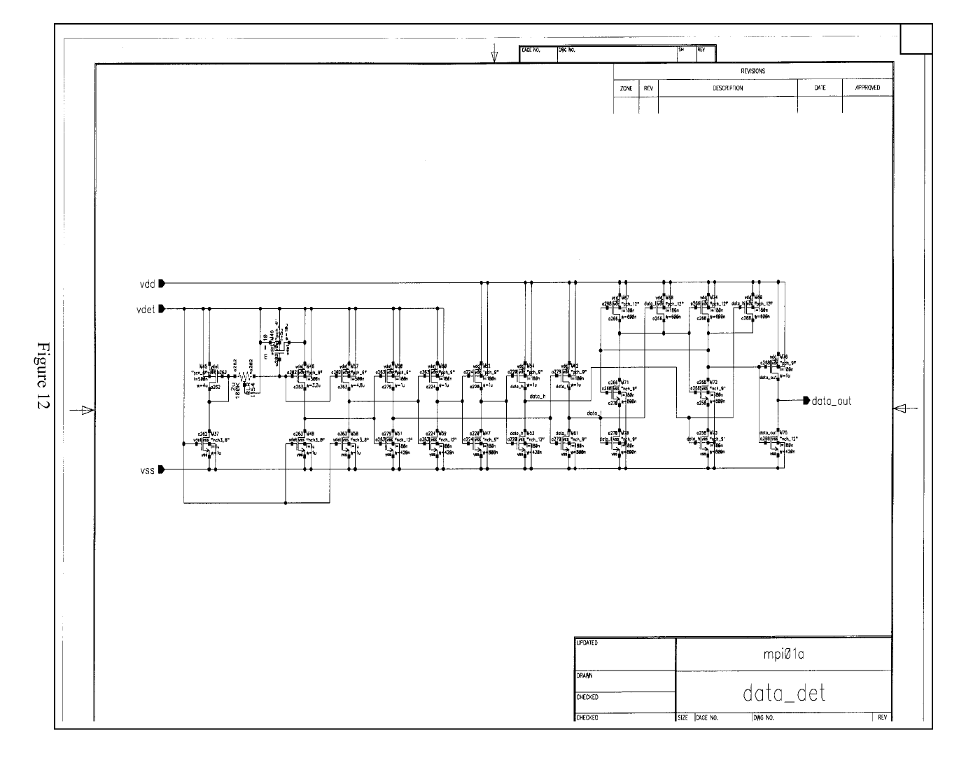

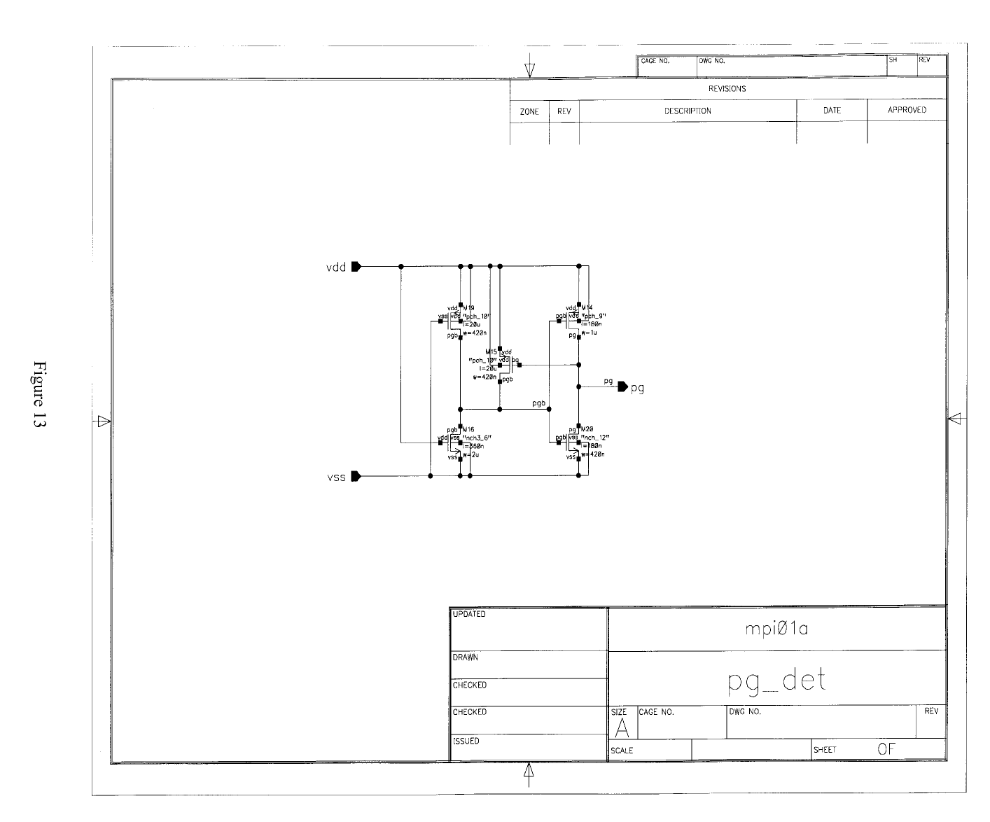

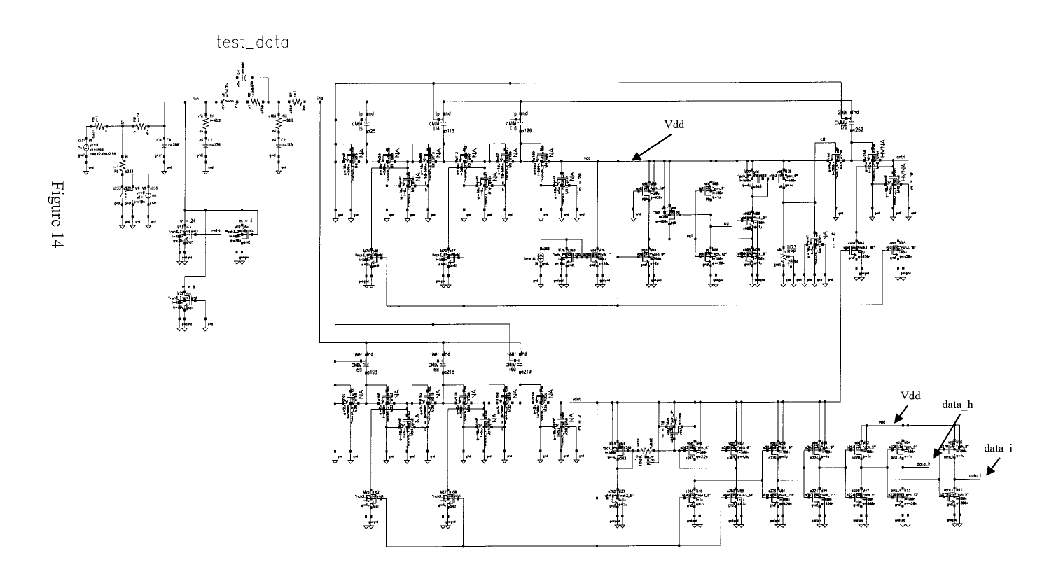

FIG. 10 is a charge pump block level Top Block Interconnect schematic. FIG. 10A illustrates a primary first stage part of the charge pump schematic of FIG. 10 in principle functionality using switches. FIG. 10B illustrates the same part shown in FIG. 10A using diodes. FIG. 10C illustrates a complementary configuration of the primary first stage part of the charge pump schematic of FIG. 10 using diodes of the opposite polarity. FIG. 10D illustrates interconnections between the parts shown in FIGS. 10B and 10C to construct a dual polarity (or input) charge pump. FIG. 10E illustrates drain-to-source current (Ids) vs. gate-to-source voltage (Vgs) comparison of a native MOS transistor that can be used in the charge pump schematic of FIG. 10 and a regular MOS transistor of same dimensions (W/L ratio). FIG. 11 is a three stage charge pump transistor level schematic. FIG. 11A is a more detail view of a main charge portion of the three stage charge pump transistor level schematic of FIG. 11 showing capacitors M9, M10, and M11 formed using native MOS transistors (NA). FIG. 12 is a Data Detector transistor level schematic. FIG. 13 is a Power Good Detector transistor level schematic. FIG. 14 is a simulation test transistor level schematic.

In more detail and referring to FIGS. 10A and 10B, a charge pump circuit in accordance with one embodiment of the present invention includes a first switch diode (e.g., a first diode-connected transistor or a first diode-connected NMOS transistor) S1, a first capacitor C1, a second switch diode (e.g., a second diode-connected transistor or a second diode-connected NMOS transistor) S2, and a second capacitor C2. As shown in FIGS. 10A and 10B, the first switch diode S1 has a first electrode connected with a first power source GND and a second electrode connected with a first node V1. The first capacitor C1 is connected between the first node V1 and a second power source VIN (A1). The second switch diode S2 has a first electrode connected with the first node V1 and a second electrode connected with a second node V2. The second capacitor C2 is connected between the second node V2 and the first power source GND. Here, the first switch diode S1 and/or the second switch diode S2 is formed using a MOS transistor having a substantially zero threshold voltage. That is, the MOS transistor may be a native MOS transistor as shown in FIG. 10E.

The first power source GND may be a reference node and the second power source VIN (A1) may be an alternating input node. That is, a plurality of terminals A1 and A0 are adapted through, e.g., an Antenna 1, to receive an alternative voltage signal, wherein the first power source GND is electrically coupled to one of the plurality of terminals, e.g., A1, and wherein the second power source GND is electrically coupled to another one of the plurality of terminals, e.g., A0. Here, the second node V2 is adapted to provide a substantially constant voltage.

In addition, more charge pump stages can implemented, as shown in FIGS. 10A and 10B with dotted lines. That is, for example, to form a second stage, the charge pump circuit may further include a third switch diode (e.g., a third diode-connected transistor) S3 having a first electrode connected with the second node V2 and a second electrode connected with a third node V3. The charge pump circuit may further include a third capacitor C3 connected between the third node V3 and the second power source VIN (A1), a fourth switch diode (e.g., a fourth diode-connected transistor) S4 having a first electrode connected with the third node V3 and a second electrode connected with a fourth node V4, and a fourth capacitor C4 connected between the fourth node V4 and the first power source GND. Additional stages may further be added as needed.

Since each succeeding stage creates more voltage, the first, second, third, and fourth switch diodes S1, S2, S3, and S4 may have respective channel lengths adjusted according to their respective maximum hold off voltages. Native transistors normally require extra channel length due to the lighter channel doping.

The first, second, third, and fourth switch diodes S1, S2, S3, and S4 may have a body electrode electrically coupled to the first power source GND or the output node of the charge pump circuit (e.g., the second node V2 or the fourth node V4). Here, the body electrode is electrically coupled to the first power source GND when the first power source has a voltage level higher than the second node, and the body electrode is electrically coupled to the second node V2 or the fourth node V4 when the second node V2 or the fourth node V4 has a voltage level higher than the first power source GND. Additional stages are implemented by repeating the addition of the dotted area of the schematic to the chain of stages.

Here, the charge pump circuit may be incorporated within a Radio Frequency IDentification (RFID) tag having a modulator electrically coupled between the first and second power sources GND and VIN (A1), the modulator being adapted to modify an impendance between the first and second power sources GND and VIN (A1). In FIG. 10C, the diodes are reversed resulting in the opposite output voltage polarity.

In addition, as shown in FIGS. 10C and 10D, a second charge pump circuit may be electrically coupled the first power source GND and a third power source VIN (A2) to increase a differential charge pump output voltage level. Here, the second charge pump circuit in accordance with one embodiment of the present invention includes a first switch diode (e.g., a first diode-connected transistor or a first diode-connected PMOS transistor) S21, a first capacitor C21, a second switch diode (e.g., a second diode-connected transistor or a second diode-connected PMOS transistor) S22, and a second capacitor C22. The first switch diode S21 has a first electrode connected with the first power source GND and a second electrode connected with a first node V21. The first capacitor C21 is connected between the first node V21 and the third power source VIN (A2). The second switch diode S22 has a first electrode connected with the first node V21 and a second electrode connected with a second node V22. The second capacitor C22 is connected between the second node V22 and the first power source GND. Here, the first switch diode S21 and/or the second switch diode S22 is formed using a MOS transistor having a substantially zero threshold voltage. The second charge pump requires consideration of the substrate diodes (e.g., the ground or the first power source GND). Twin well processes can provide an example solution to the substrate diode consideration.

Furthermore, as shown in FIGS. 10C and 10D, the second charge pump circuit may further include a third switch diode (e.g., a third diode-connected transistor) S23 having a first electrode connected with the second node V22 and a second electrode connected with a third node V23. The second charge pump circuit may further include a third capacitor C23 connected between the third node V23 and the third power source VIN (A2), a fourth switch diode (e.g., a fourth diode-connected transistor) S24 having a first electrode connected with the third node V23 and a second electrode connected with a fourth node V24, and a fourth capacitor C24 connected between the fourth node V24 and the first power source GND.

Moreover, as shown in FIGS. 11, 31, 32, and 33, the charge pump circuit may have a first storage capacitance, and additional charge pumps may be electrically coupled to the first and second power sources GND and VIN (A2). The additional charge pumps have a second storage capacitance lower than the first storage capacitance to detect data from signals provided to the first and second power sources GND and VIN (A2). Also, to detect the data from the signals provided to the first and second power source GND and VIN (A2), a current comparator electrically may be coupled to the charge pump circuit, and a second current comparator electrically may be coupled to the third charge pump circuit.

Also, referring to FIG. 11A, beside using native MOS transistors (NA) as switch diodes, a charge pump in accordance with an embodiment of the present invention uses native MOS transistors (NA) as capacitors. Typically, regular MOS transistors are not used as capacitors when they are in their transistor OFF state (i.e., when they do not have more than the threshold voltage across them because one of the capacitor plates is not conductive, i.e., it lacks enough carriers). This is because the carriers in the channel (one of the capacitor plate areas) of a regular MOS transistor are depleted and thus there are no carriers on the channel plate—thus: no capacitance near zero volts—just where RFID tags according to embodiments of the present invention should start-up and operate. By contrast, in a native MOS transistors (NA), there should always be carriers in the channel because the native MOS transistor is in a moderate on state at zero volts. Thus, as shown in FIG. 11A, capacitors M9, M10, and M11 in accordance to an embodiment of the present invention are formed using native MOS transistors (NA), in which capacitors M9 and M10 substantially correspond to capacitors C2 and C4 of FIGS. 10A, 10B, and 10D. In addition, in FIG. 11A, there are two additional transistors M74 and M73 that are used for bleeding off excessive charges to limit an over-voltage condition on native MOS capacitors (e.g., capacitors M9 and M10) or any other suitable capacitors.

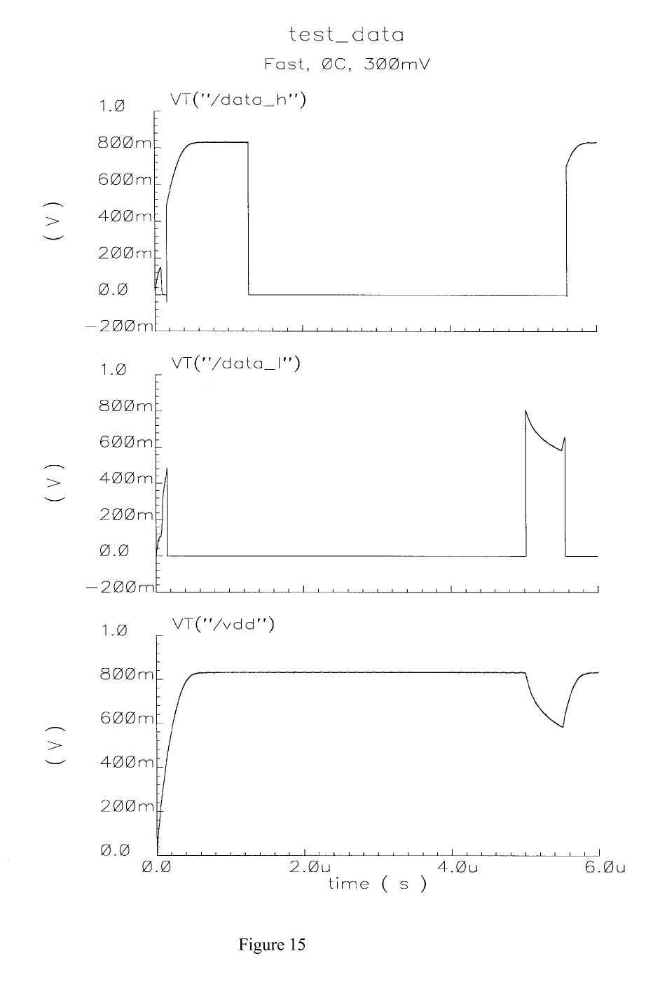

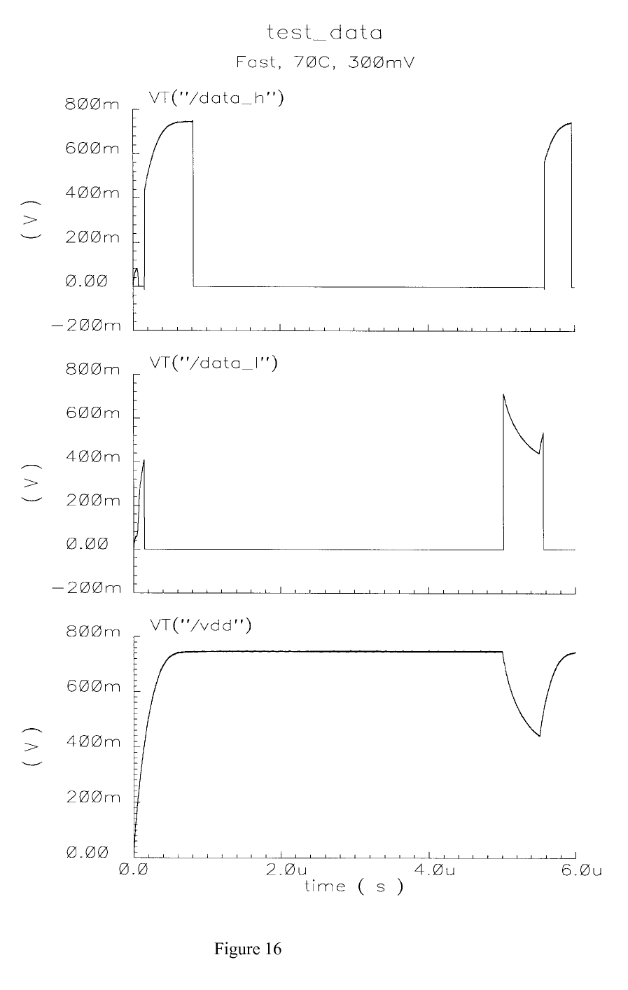

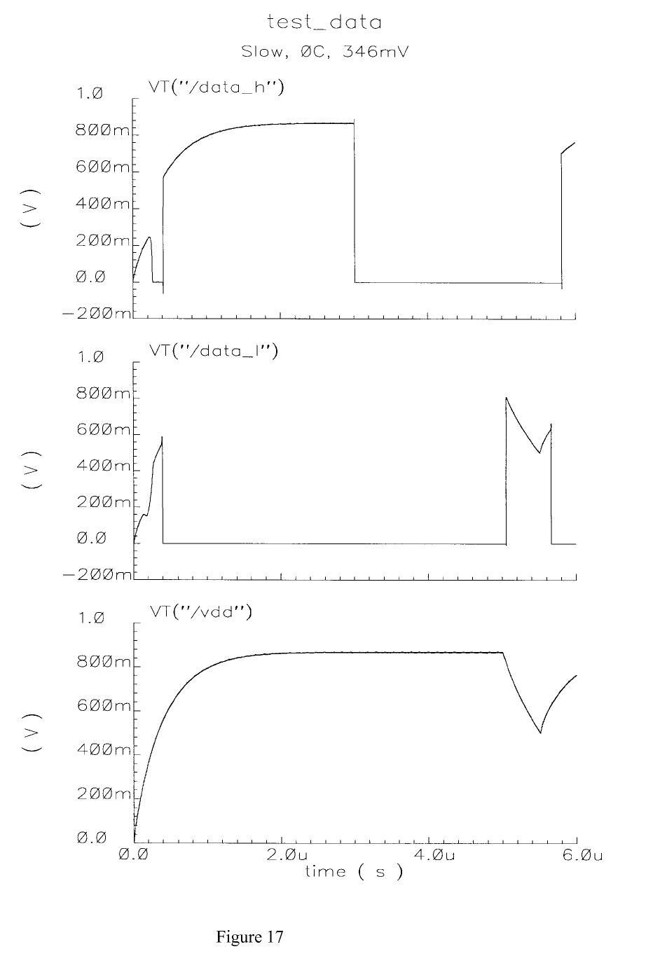

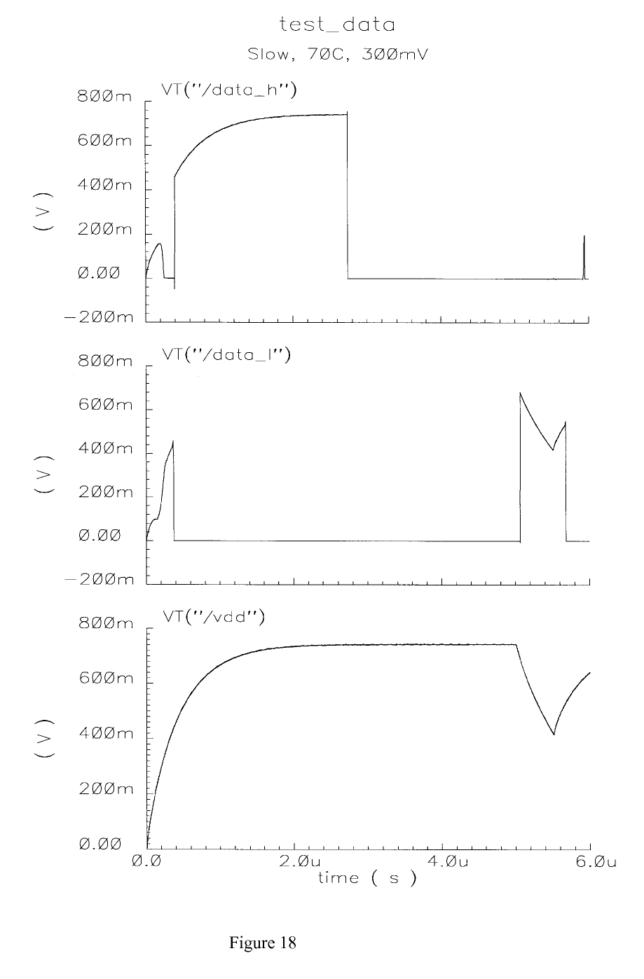

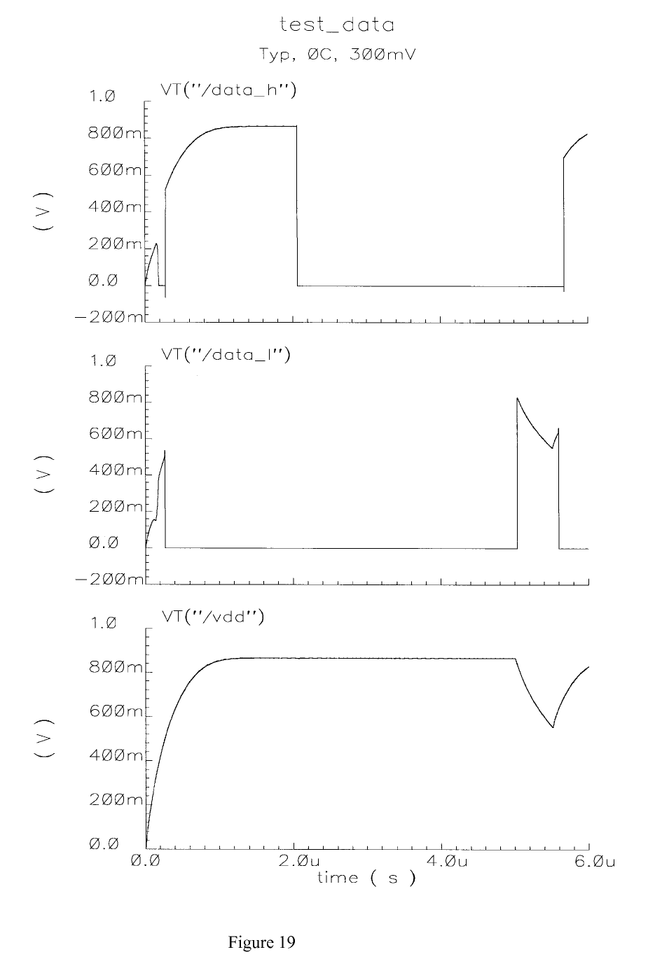

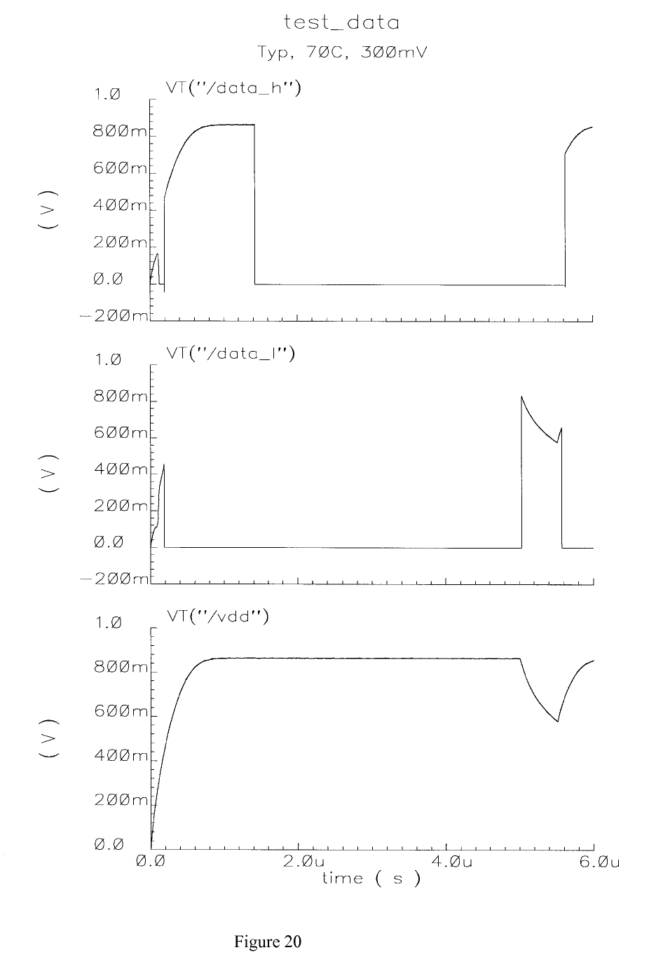

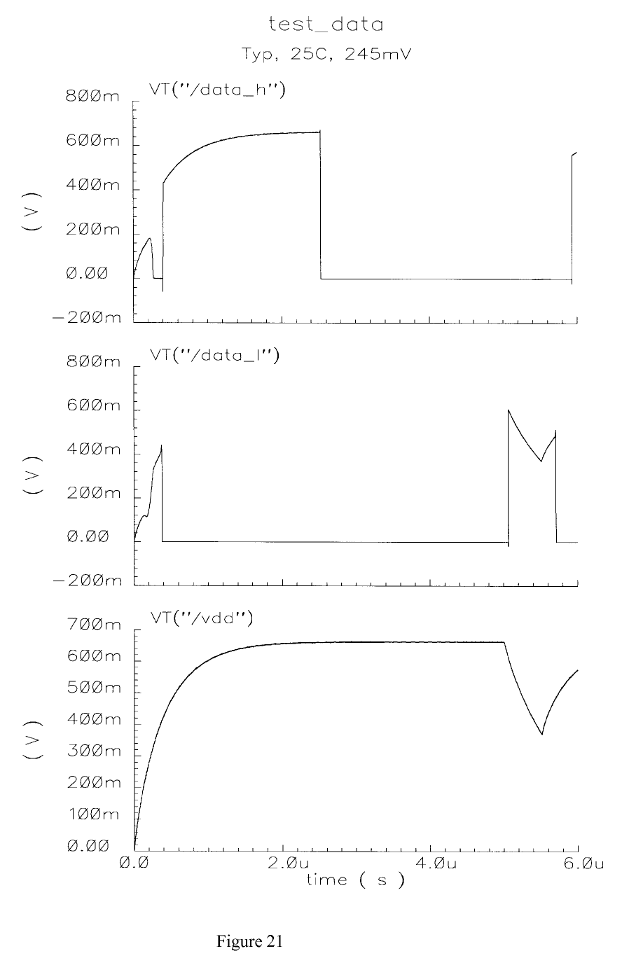

FIG. 15 illustrates simulation test plots of voltages (or signals) at nodes data_h, data_i, and vdd of the circuit of FIG. 14 with Fast parameters at 00 C, and 300 mV. FIG. 16 illustrates simulation test plots of voltages (or signals) at nodes data_h, data_i, and vdd of the circuit of FIG. 14 with Fast parameters at 700 C, and 300 mV. FIG. 17 illustrates simulation test plots of voltages (or signals) at nodes data_h, data_i, and vdd of the circuit of FIG. 14 with Slow parameters at 00 C, and 346 mV. FIG. 18 illustrates simulation test plots of voltages (or signals) at nodes data_h, data_i, and vdd of the circuit of FIG. 14 with Slow parameters at 700 C, and 300 mV. FIG. 19 illustrates simulation test plots of voltages (or signals) at nodes data_h, data_i, and vdd of the circuit of FIG. 14 with Typical parameters at 00 C, and 300 mV. FIG. 20 illustrates simulation test plots of voltages (or signals) at nodes data_h, data_i, and vdd of the circuit of FIG. 14 with Typical parameters at 700 C, and 300 mV. FIG. 21 illustrates simulation test plots of voltages (or signals) at nodes data_h, data_i, and vdd of the circuit of FIG. 14 with Typical parameters.

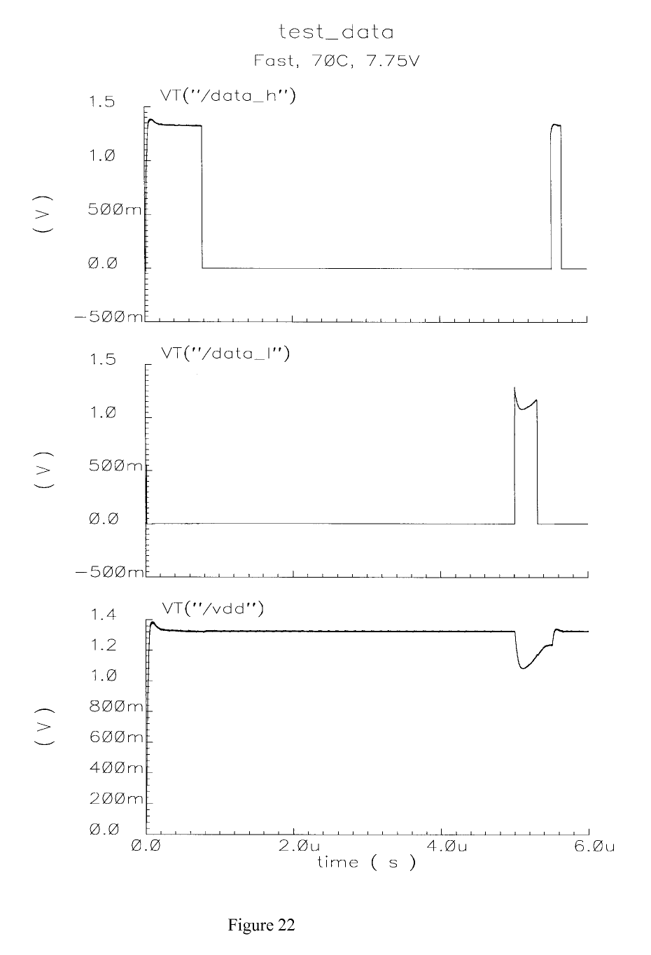

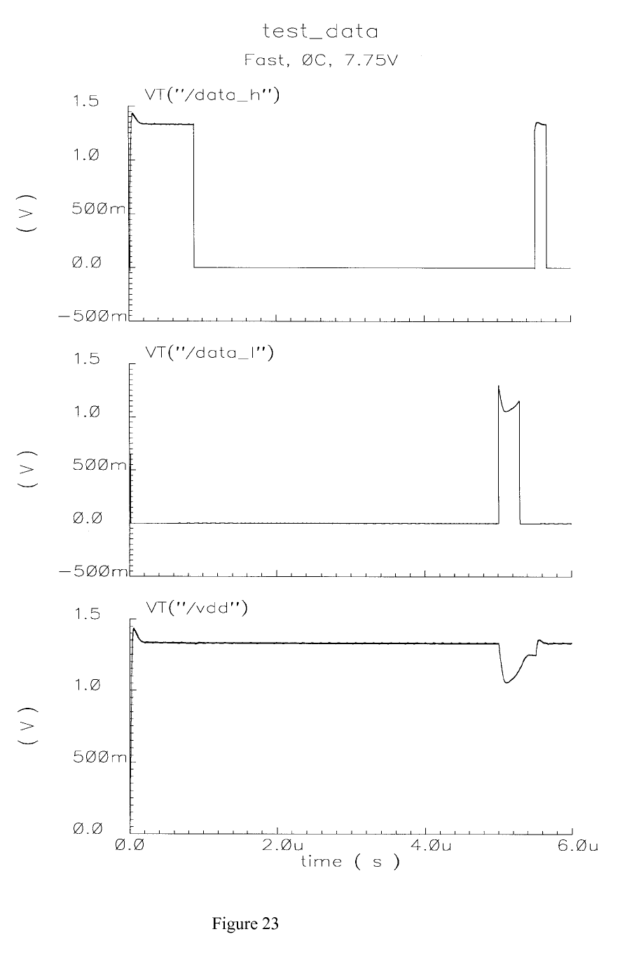

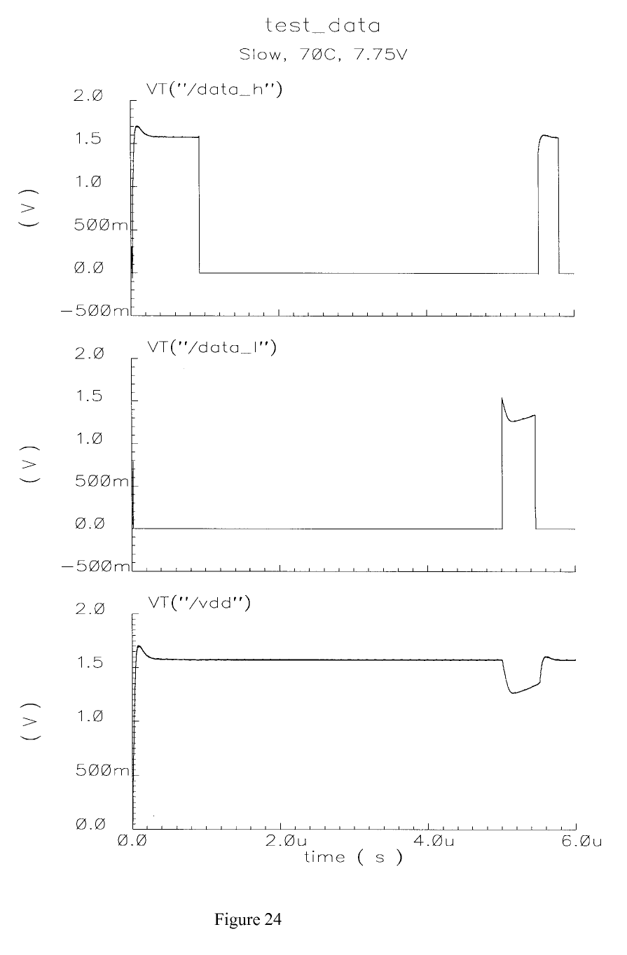

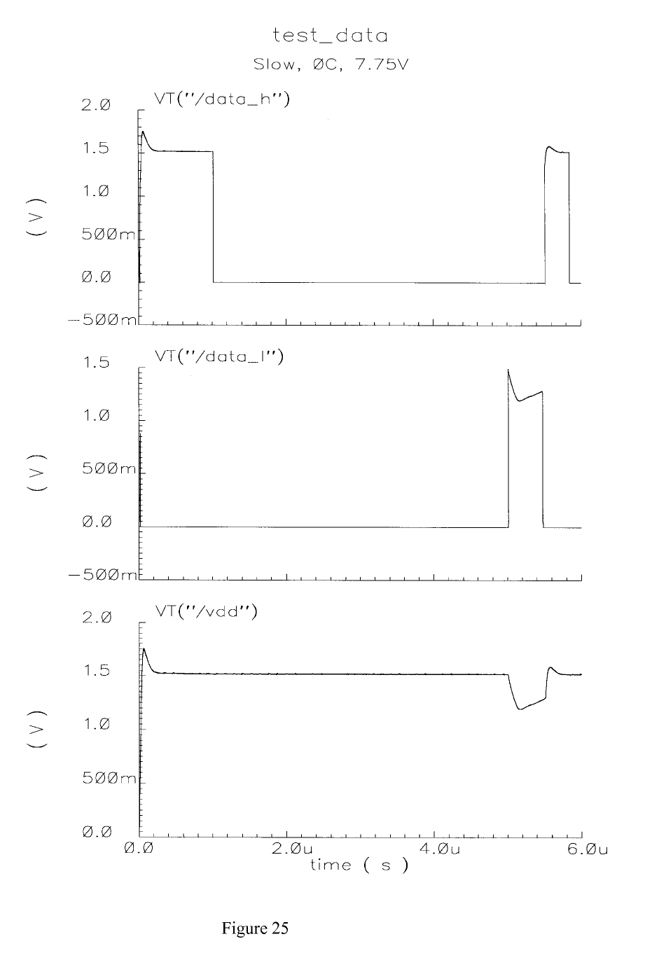

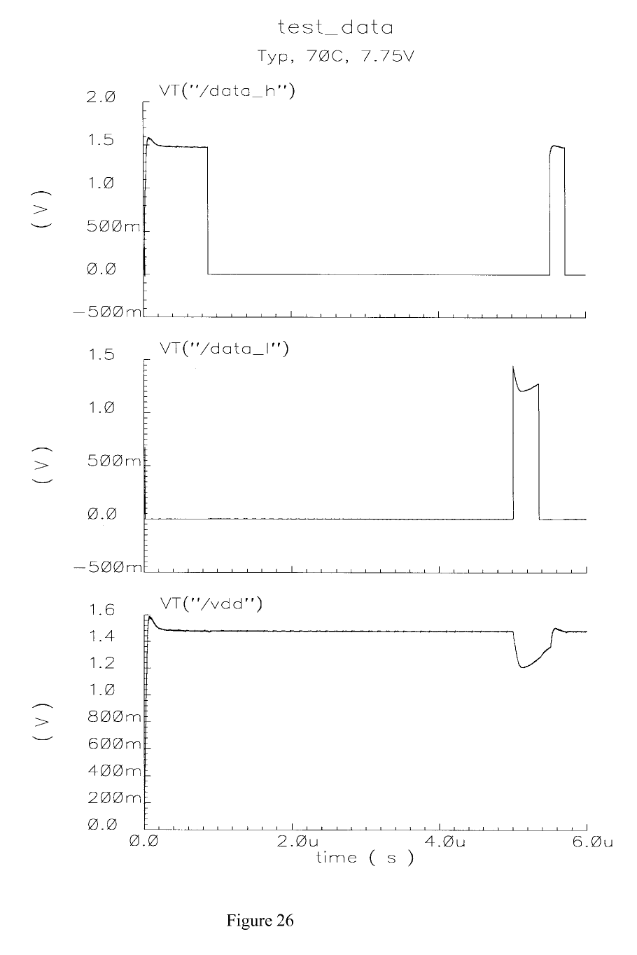

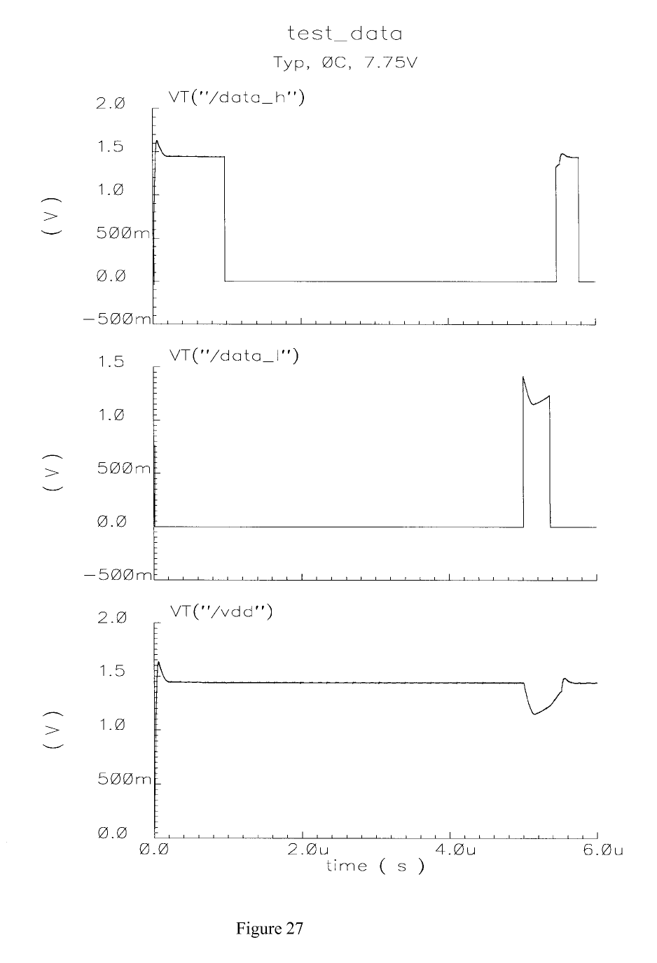

FIG. 22 illustrates simulation test plots of voltages (or signals) at nodes data_h, data_i, and vdd of the circuit of FIG. 14 with high input signal limit and with Fast parameters at 700 C, and 7.75V. FIG. 23 illustrates simulation test plots voltages (or signals) at nodes data_h, data_i, and vdd of the circuit of FIG. 14 with high input signal limit and with Fast parameters at 00 C, and 7.75V. FIG. 24 illustrates simulation test plots of voltages (or signals) at nodes data_h, data_i, and vdd of the circuit of FIG. 14 with high input signal limit and with Slow parameters at 700 C, and 7.75V. FIG. 25 illustrates simulation test plots of voltages (or signals) at nodes data_h, data_i, and vdd of the circuit of FIG. 14 with high input signal limit and with Slow parameters at 00 C, and 7.75V. FIG. 26 illustrates simulation test plots of voltages (or signals) at nodes data_h, data_i, and vdd of the circuit of FIG. 14 with high input signal limit and with Typical parameters at 700 C, and 7.75V. FIG. 27 illustrates simulation test plots of voltages (or signals) at nodes data_h, data_i, and vdd of the circuit of FIG. 14 with high input signal limit and with Typical parameters at 00 C, and 7.75V.

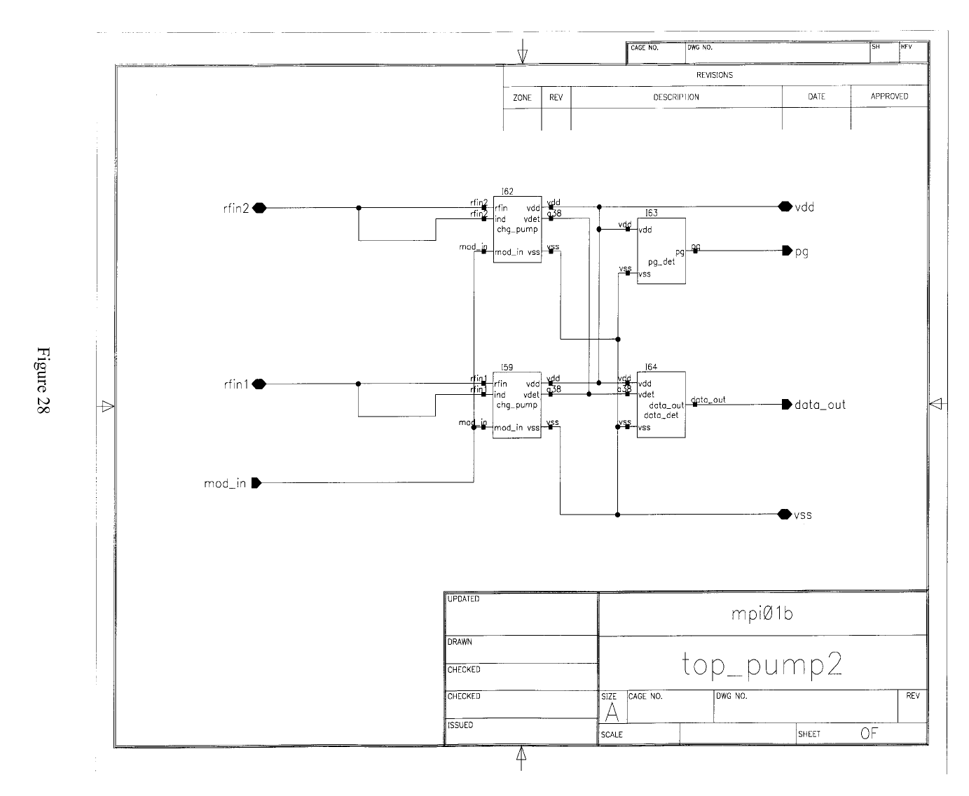

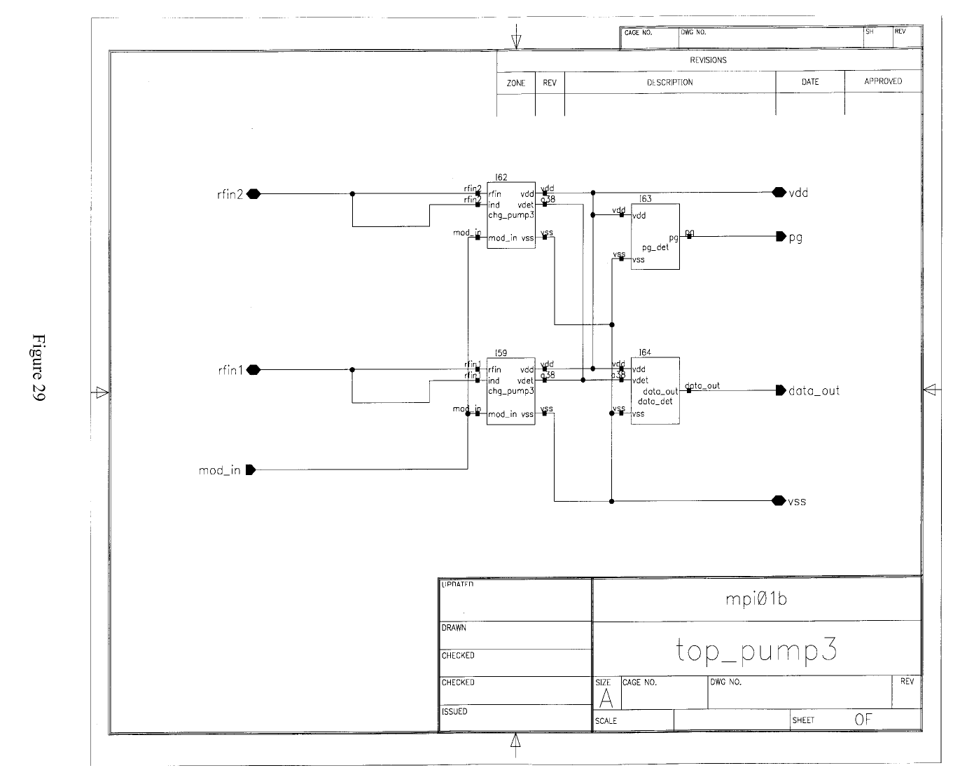

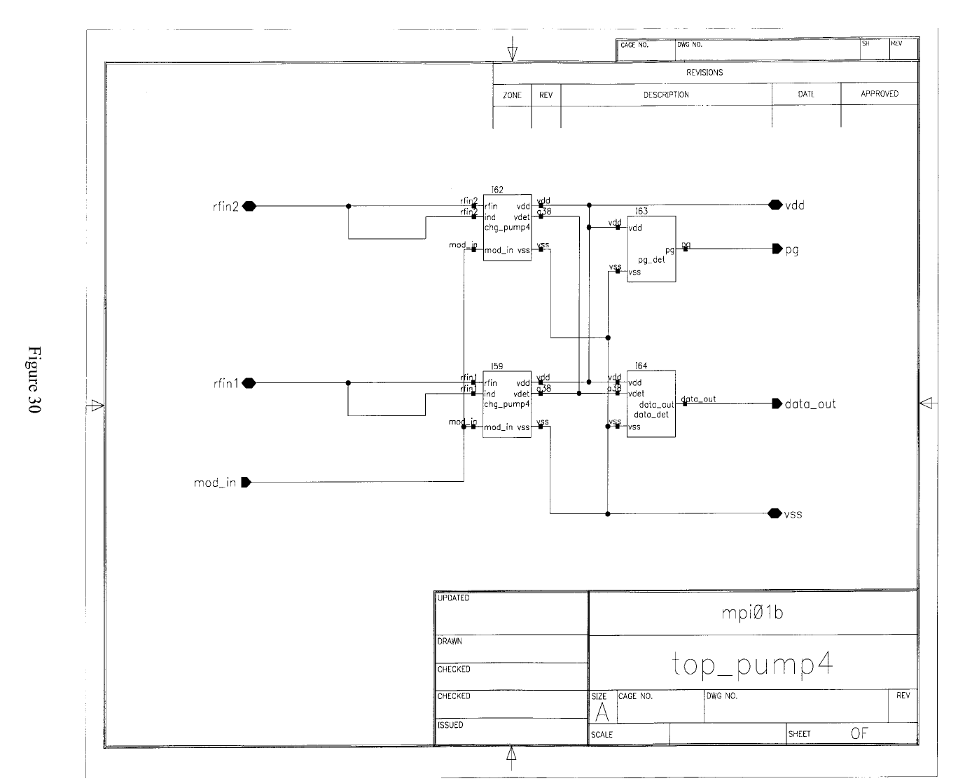

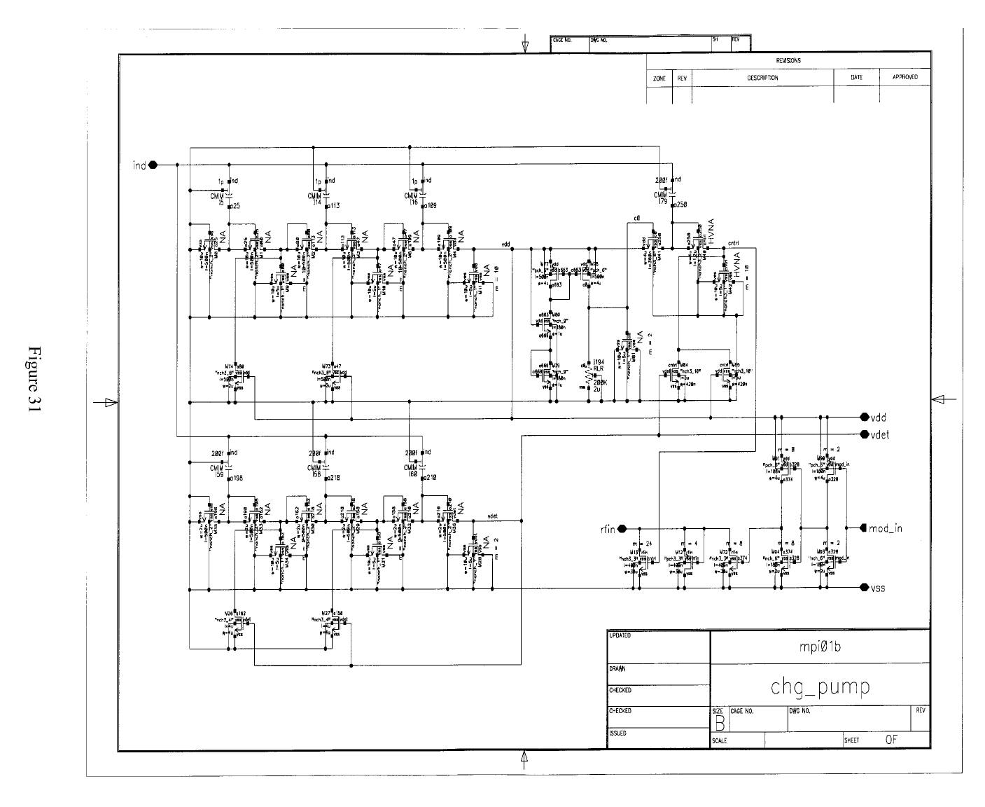

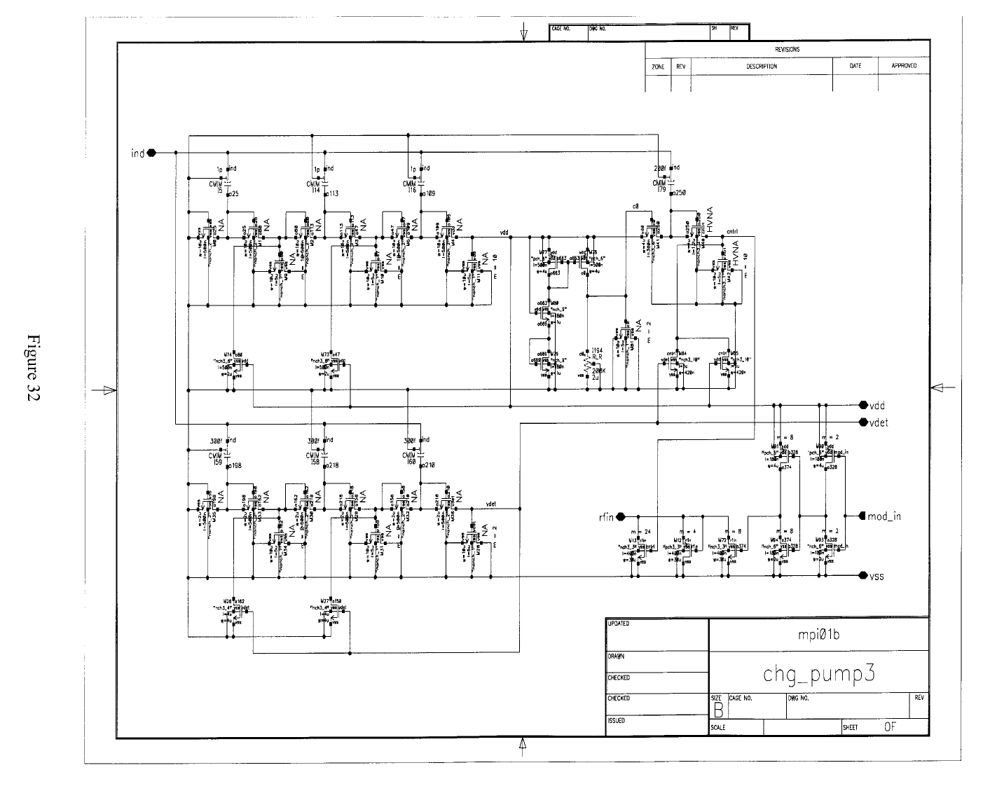

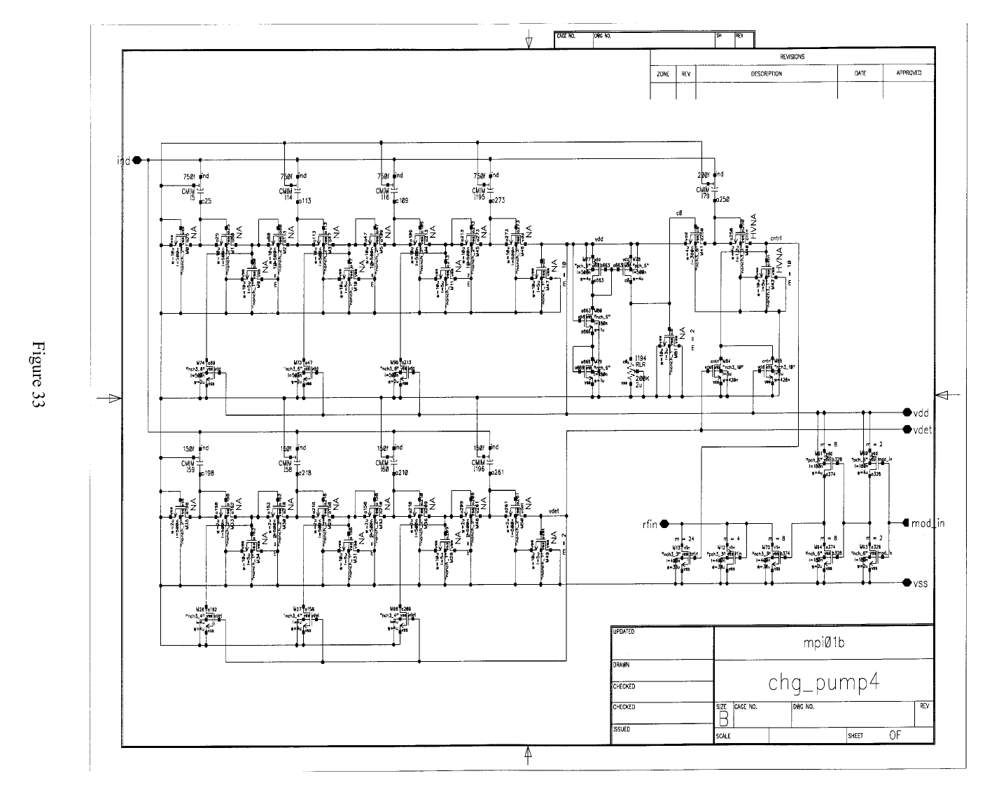

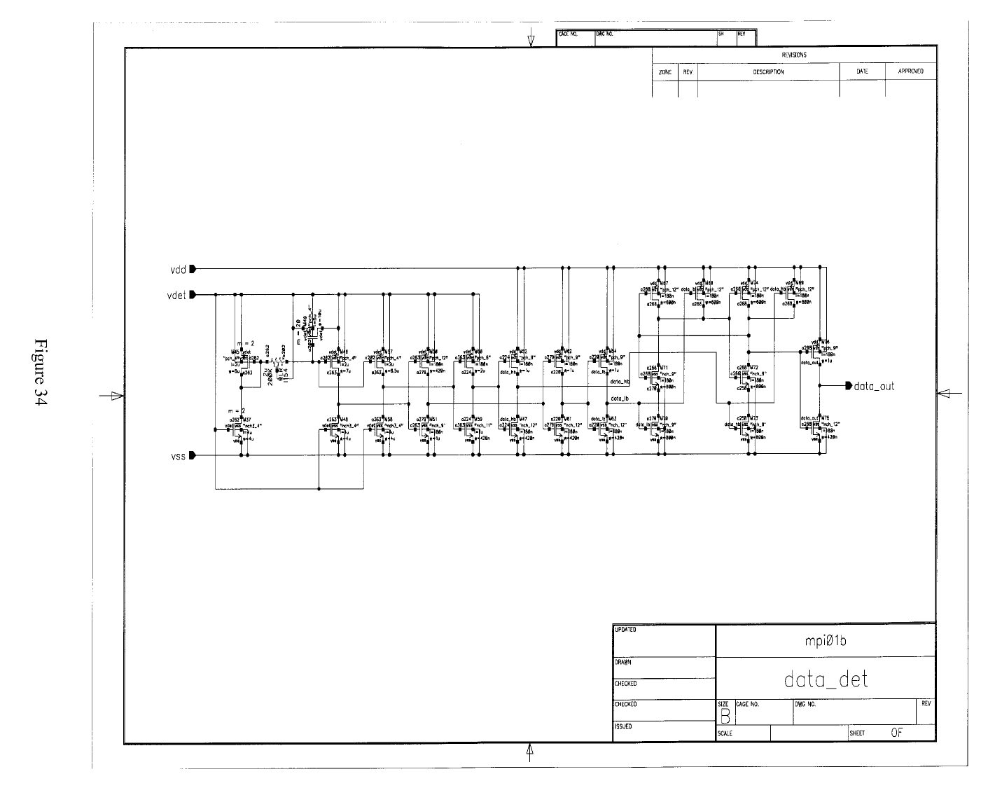

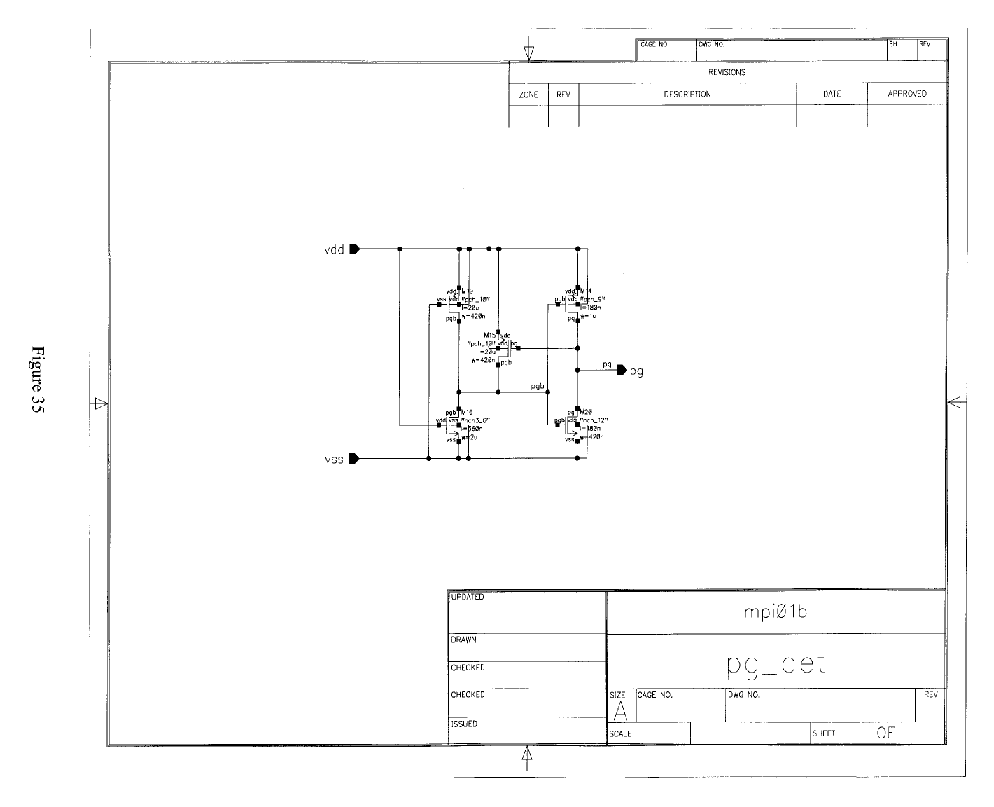

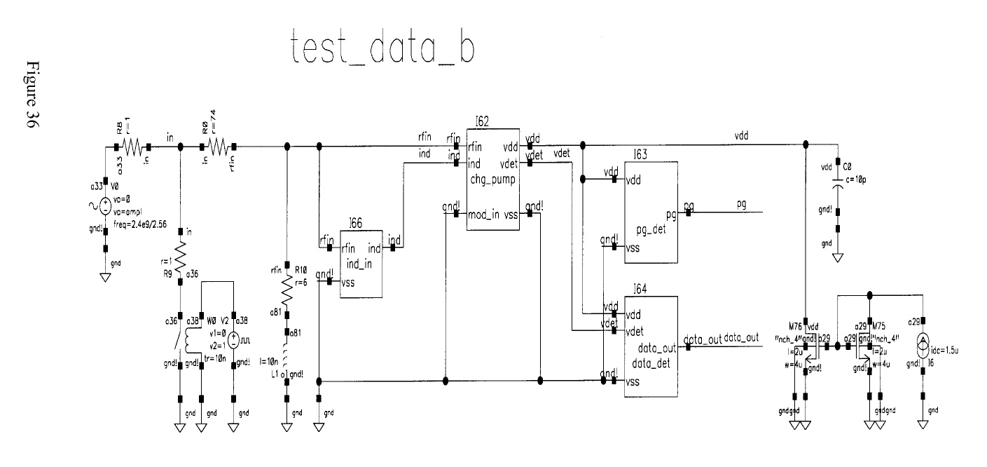

FIG. 28 is a charge pump 2 block level Top Schematic Block Interconnect schematic. FIG. 29 is a charge pump 3 block level Top Schematic Block Interconnect schematic. FIG. 30 is a charge pump 4 block level Top Schematic Block Interconnect schematic diagram. FIG. 31 is another three stage charge pump transistor level schematic with different design parameters. FIG. 32 is yet another three stage charge pump transistor level schematic with different design parameters. FIG. 33 is a fourth stage charge pump transistor level schematic. FIG. 34 is a Data Detector B transistor level schematic. FIG. 35 is a Power Good Detector B transistor level schematic. FIG. 36 is a simulation test B transistor level schematic.

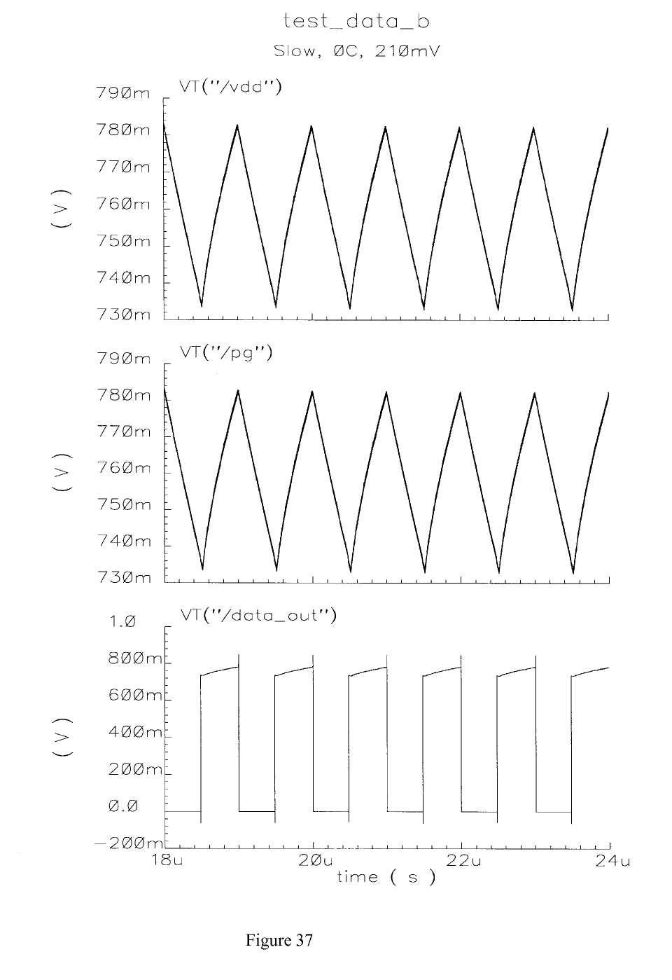

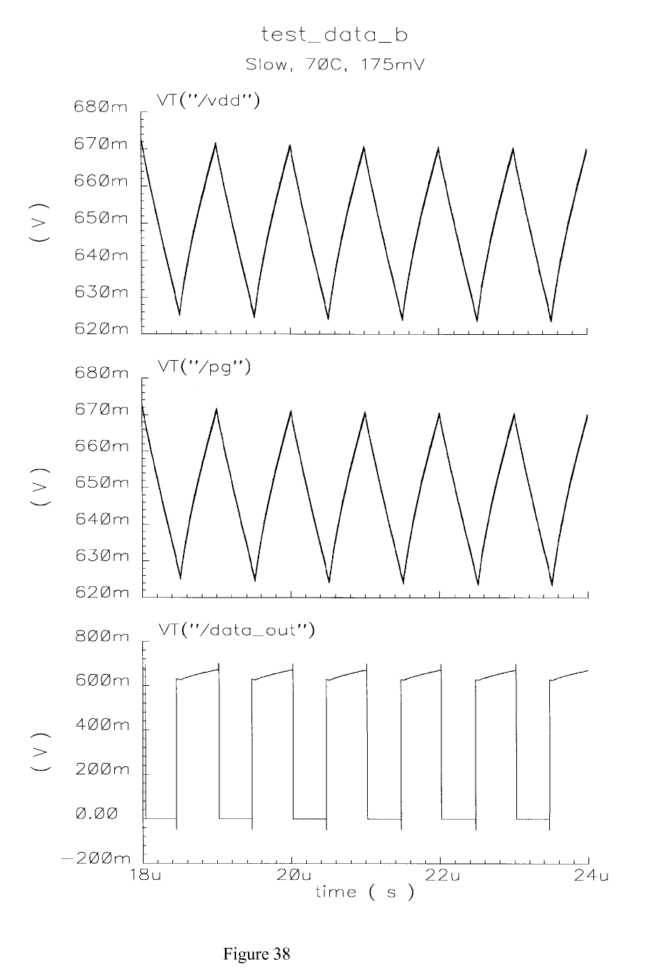

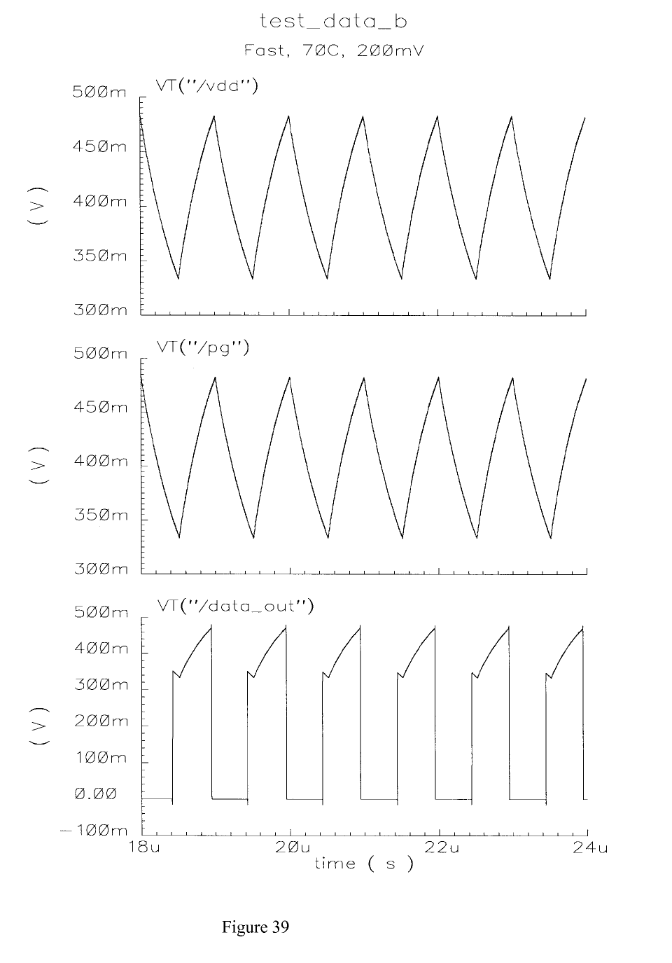

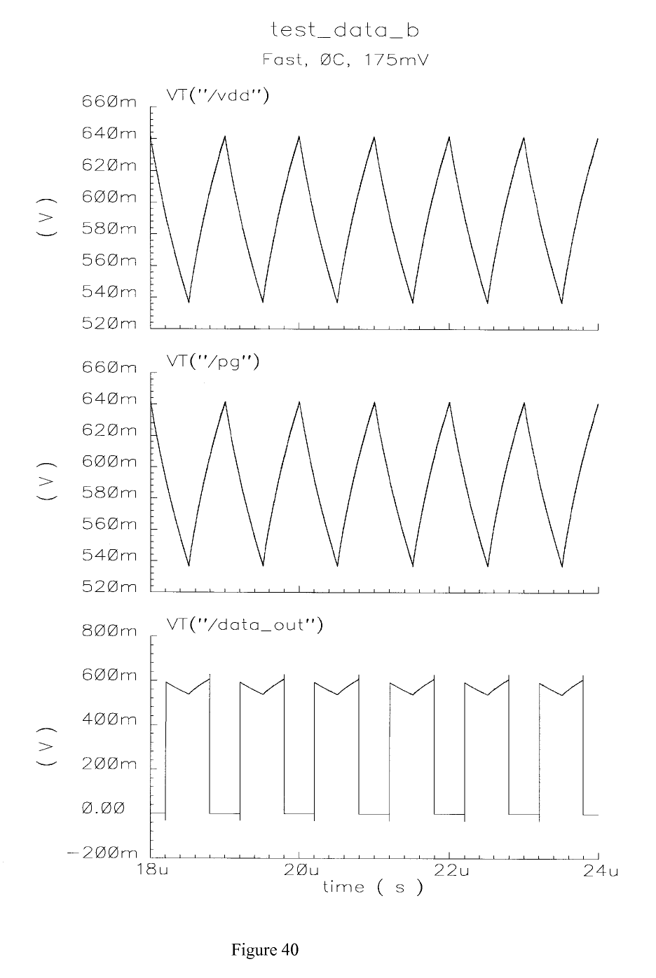

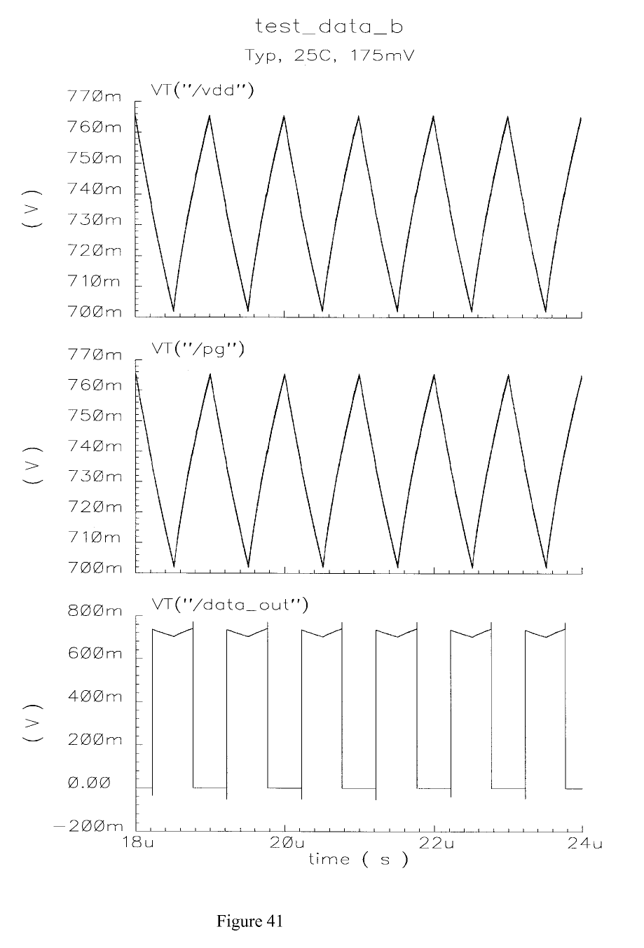

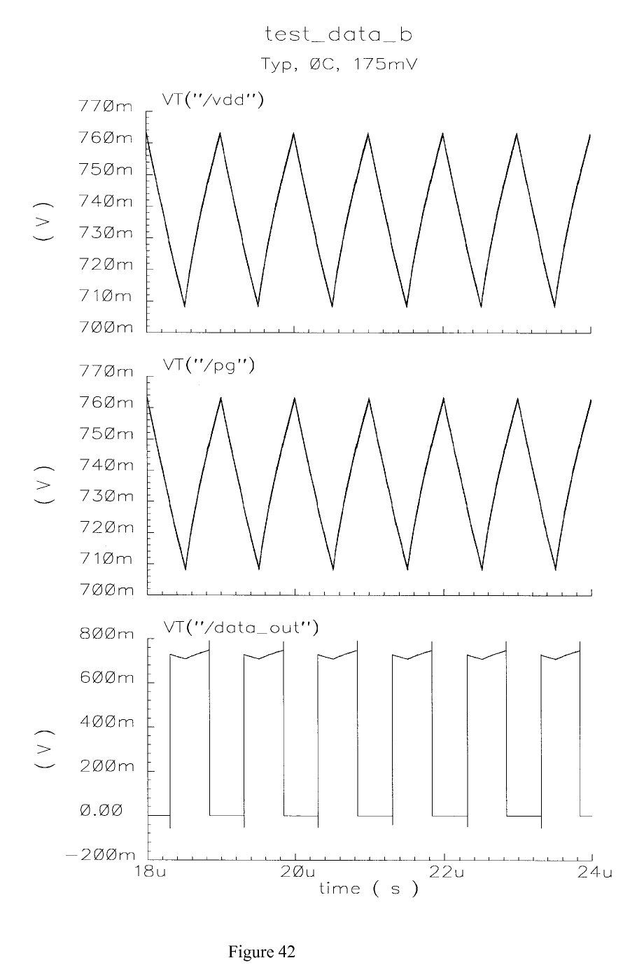

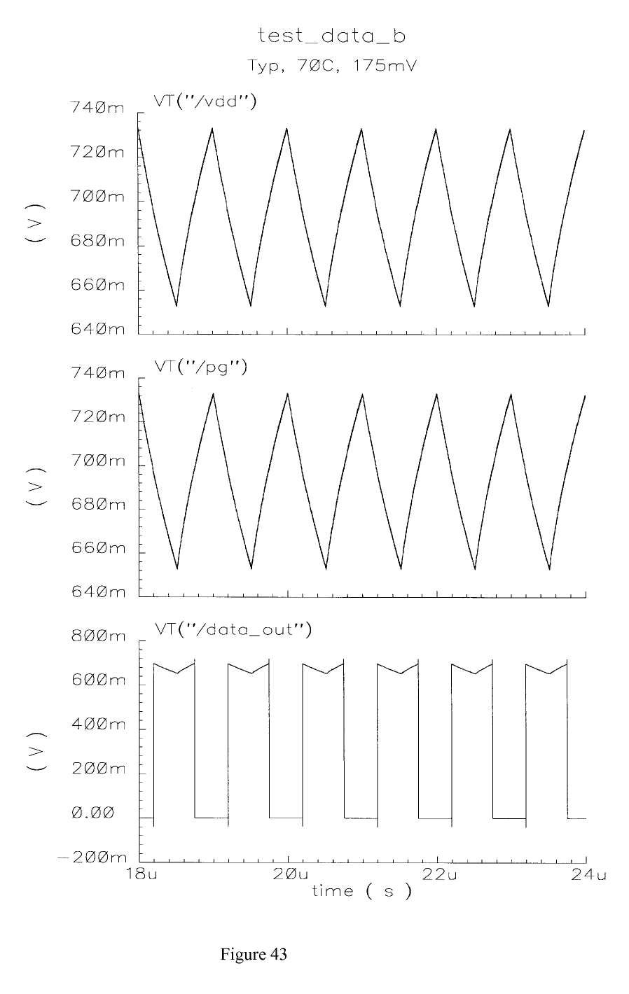

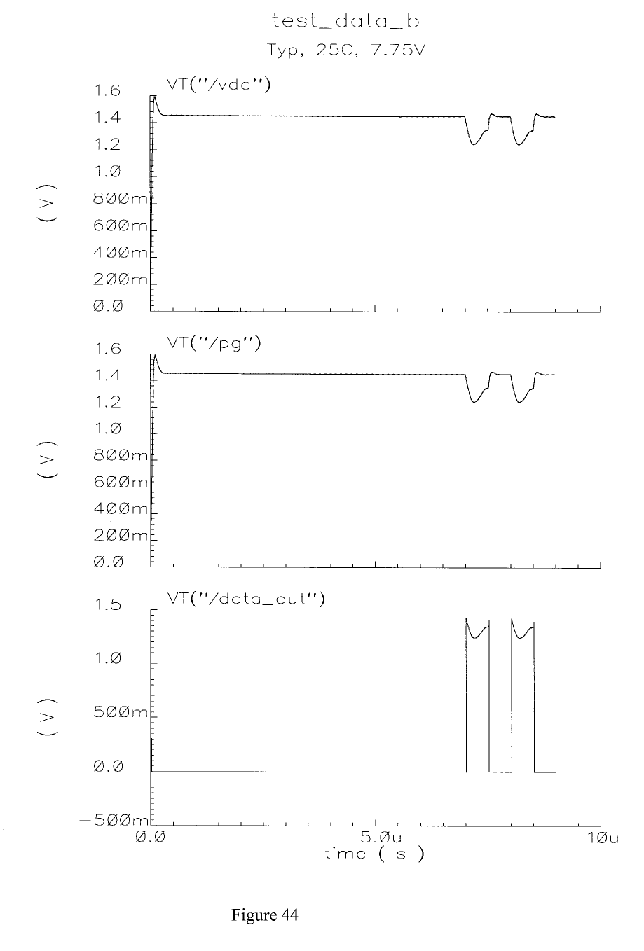

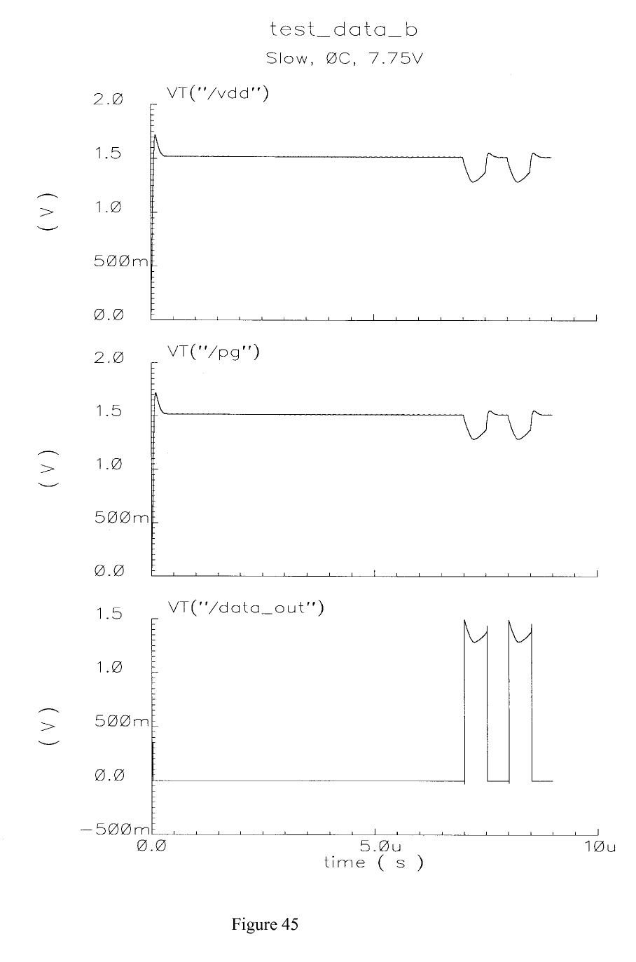

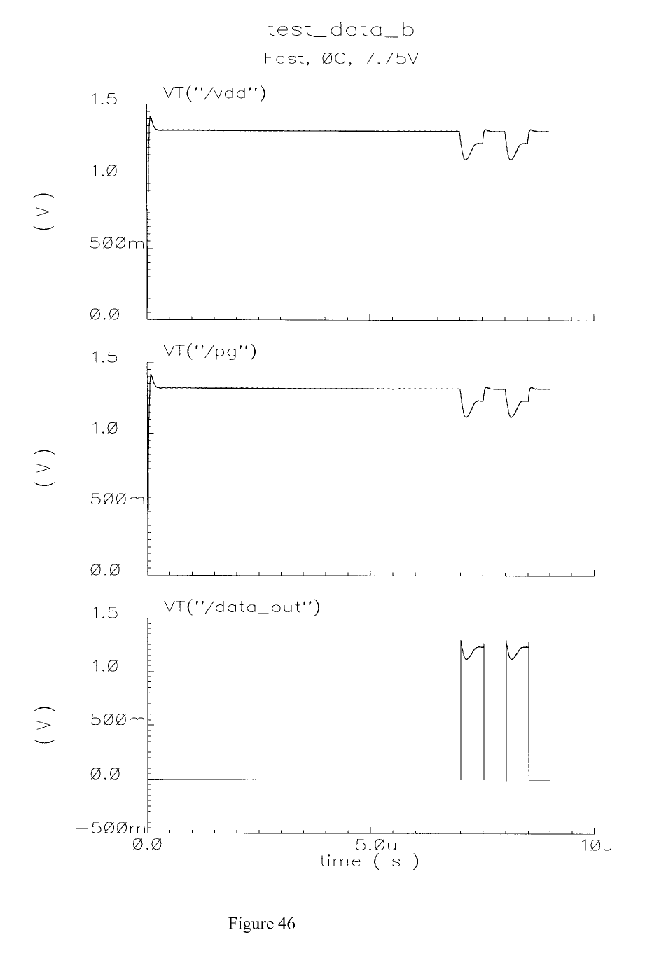

FIG. 37 illustrates simulation test B plots of voltages (or signals) at nodes vdd, pg, data_out of the circuit of FIG. 36 with Slow parameters at 00 C, and 210 mV. FIG. 38 illustrates simulation test B plots of voltages (or signals) at nodes vdd, pg, data_out of the circuit of FIG. 36 with Slow parameters at 700 C, and 175 mV. FIG. 39 illustrates simulation test B plots of voltages (or signals) at nodes vdd, pg, data_out of the circuit of FIG. 36 with Fast parameters at 700 C, and 200 mV. FIG. 40 illustrates simulation test B plots of voltages (or signals) at nodes vdd, pg, data_out of the circuit of FIG. 36 with Fast parameters at 00 C, and 175 mV. FIG. 41 illustrates simulation test B plots of voltages (or signals) at nodes vdd, pg, data_out of the circuit of FIG. 36 with Typical parameters at 250 C, and 175 mV. FIG. 42 illustrates simulation test B plots of voltages (or signals) at nodes vdd, pg, data_out of the circuit of FIG. 36 with Fast parameters at 00 C, and 175 mV. FIG. 43 illustrates simulation test B plots of voltages (or signals) at nodes vdd, pg, data_out of the circuit of FIG. 36 with Fast parameters at 700 C, and 175 mV. FIG. 44 illustrates simulation test B plots of voltages (or signals) at nodes vdd, pg, data_out of the circuit of FIG. 36 with maximum input and with Typical parameters at 250 C, and 7.75V. FIG. 45 illustrates simulation test B plots of voltages (or signals) at nodes vdd, pg, data_out of the circuit of FIG. 36 with maximum input and with Slow parameters at 00 C, and 7.75V. FIG. 46 illustrates simulation test B plots of voltages (or signals) at nodes vdd, pg, data_out of the circuit of FIG. 36 with maximum input and with Fast parameters at 00 C, and 7.75V.

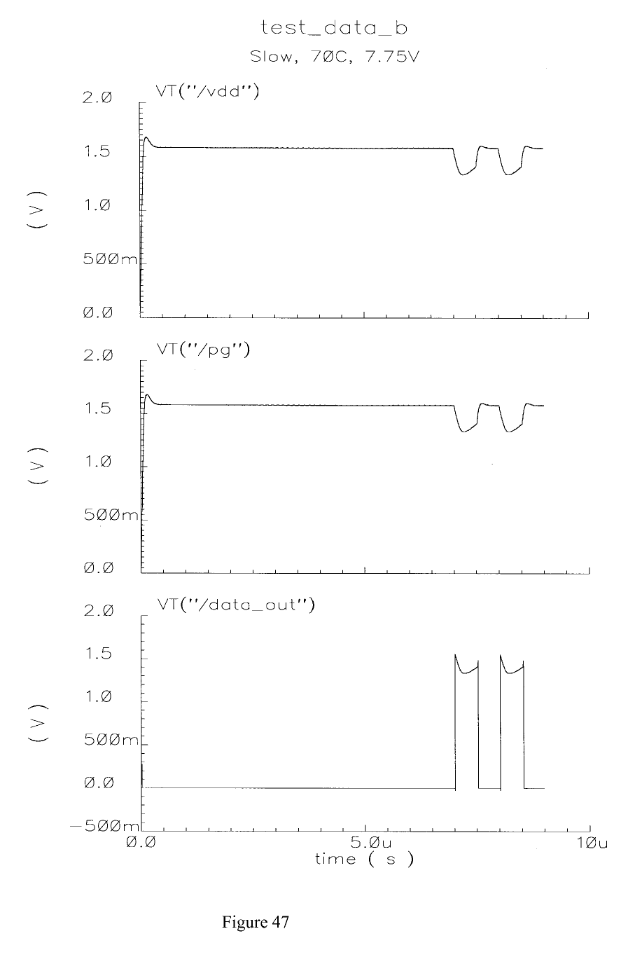

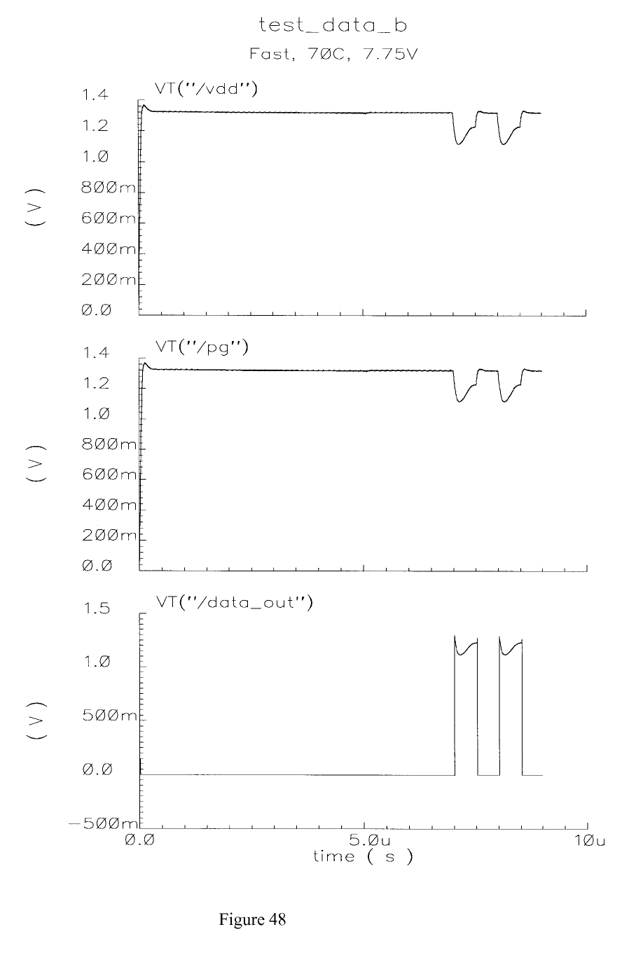

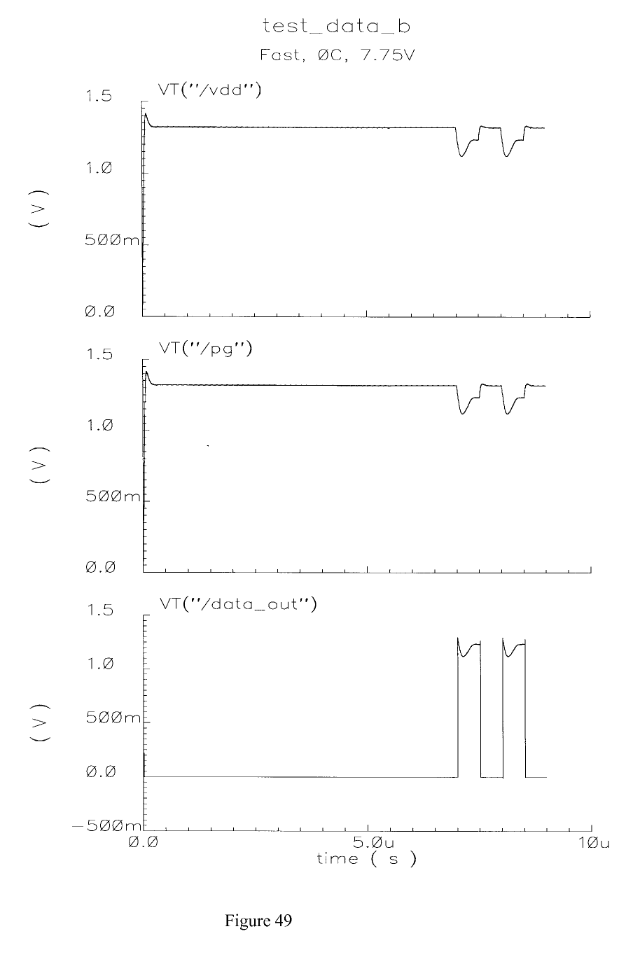

FIG. 47 illustrates simulation test B2 plots of voltages (or signals) at nodes vdd, pg, data_out of the circuit of FIG. 36 with maximum input and with Slow parameters at 700 C, and 7.75V. FIG. 48 illustrates simulation test B2 plots of voltages (or signals) at nodes vdd, pg, data_out of the circuit of FIG. 36 with maximum input and with Fast parameters at 700 C, and 7.75V. FIG. 49 illustrates simulation test B2 plots of voltages (or signals) at nodes vdd, pg, data_out of the circuit of FIG. 36 with maximum input and with Fast parameters at 00 C, and 7.75V.

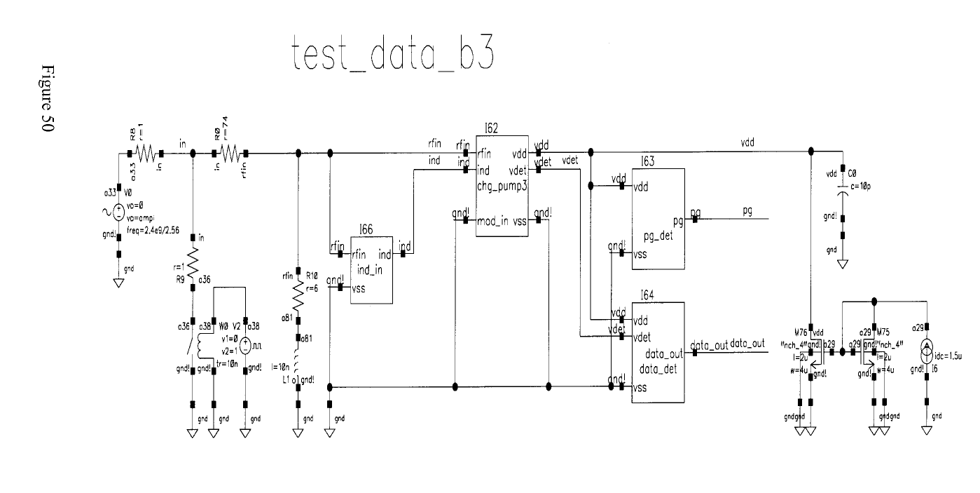

FIG. 50 illustrates a simulation test B3 transistor level schematic.

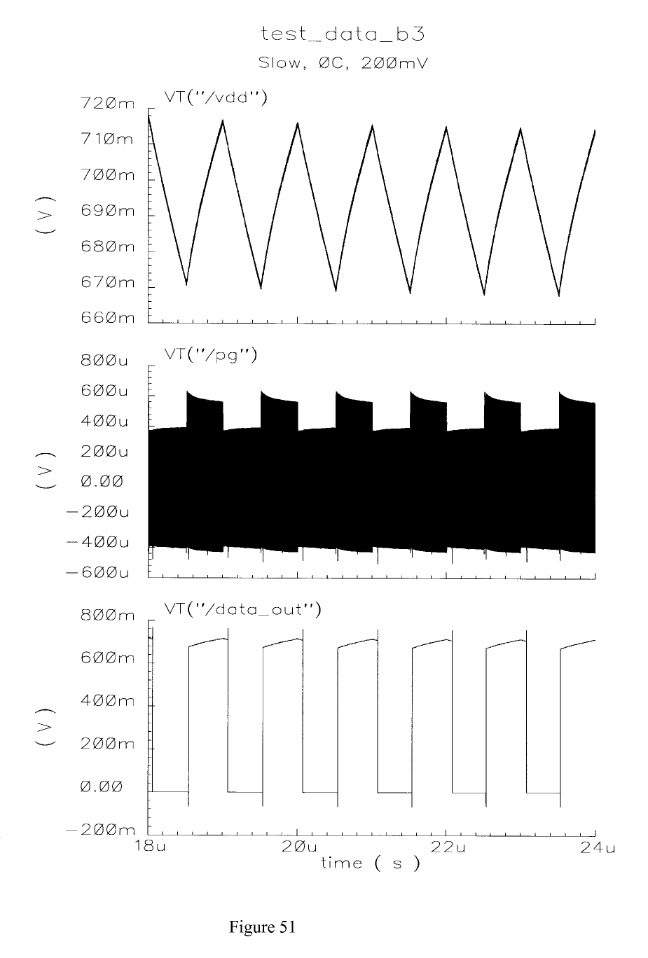

FIG. 51 illustrates simulation test B3 plots of voltages (or signals) at nodes vdd, pg, data_out of the circuit of FIG. 50 with worst-case condition Slow parameters at 00 C, and 200 mV.

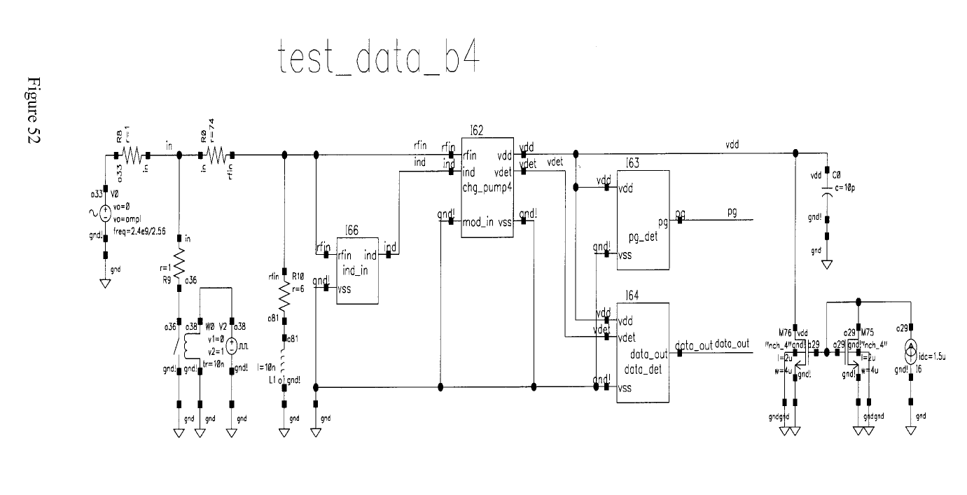

FIG. 52 illustrates a simulation test B4 transistor level schematic.

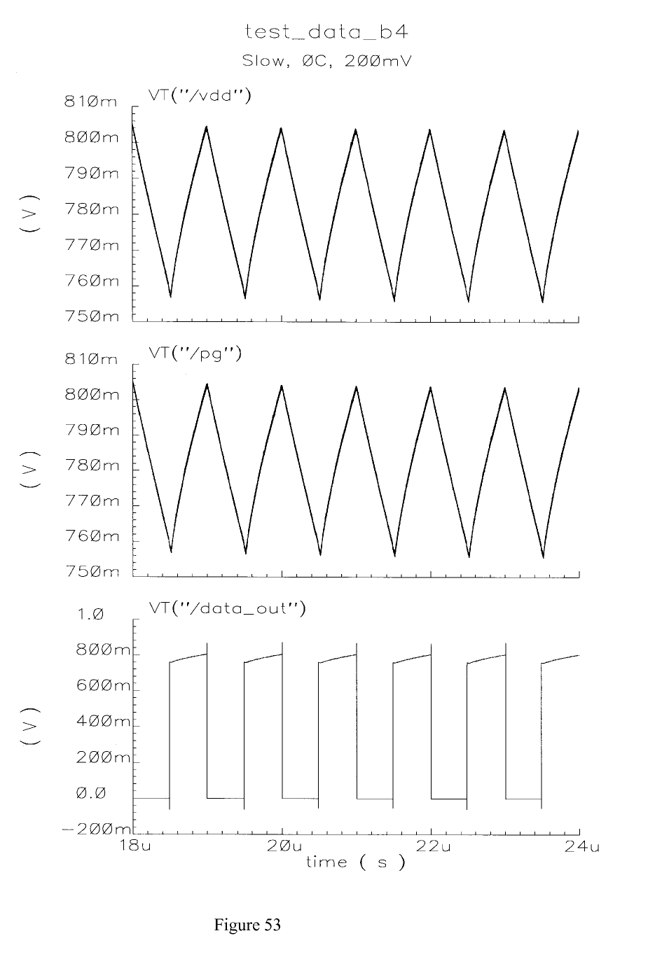

FIG. 53 illustrates a simulation test B4 plots of voltages (or signals) at nodes vdd, pg, data_out of the circuit of FIG. 36 with worst-case condition Slow parameters at 00 C, and 200 mV.

N. Array of Charge Pump Configuration Layout

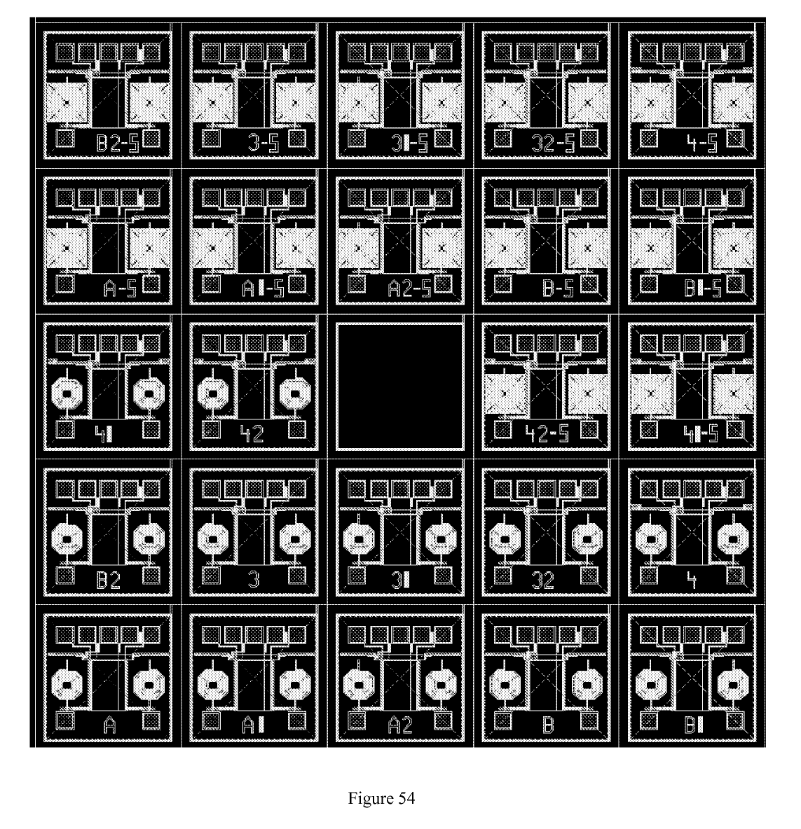

FIG. 54 illustrates Arrayed Layout of RFID tag dual charge-pump/resonator test chips. The inductors are not shielded for the 12 lower-left coils and shielded for the 12 upper-right coils.

O. Various Individual Charge Pump Layout Configurations

The series of charge pump configurations contained in FIGS. 55 to 78 are in the form of layout. The three top middle pads are for performance testing only and are not in a normal RFID tag integrated circuit. These pads are connected to the test VCO and the output modulators. Each circuit layout is first displayed without a coil shield, then followed by the addition of a low area coverage coil shield. Note the shield fingers pointing inward. The shields shorted turn prevention gap is at the middle bottom of the shield.

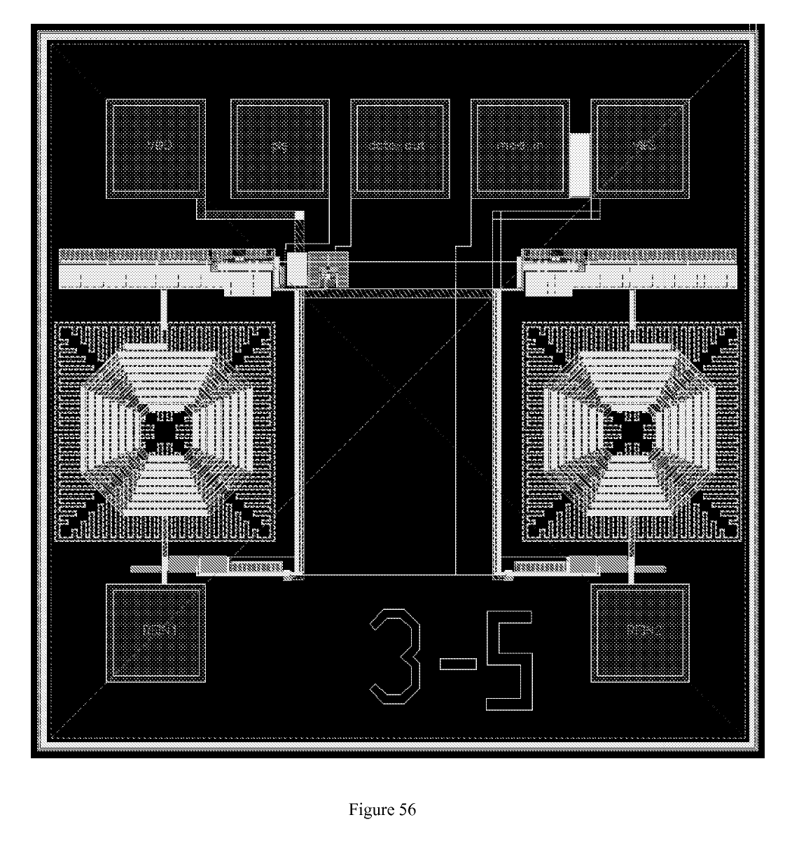

FIG. 55 illustrates Layout 3 of RFID tag dual charge-pump/resonator. In Layout 3, the inductors are not unshielded. FIG. 56 illustrates Layout 3-s of RFID tag dual charge-pump/resonator. In layout 3-s, the inductors are shielded.

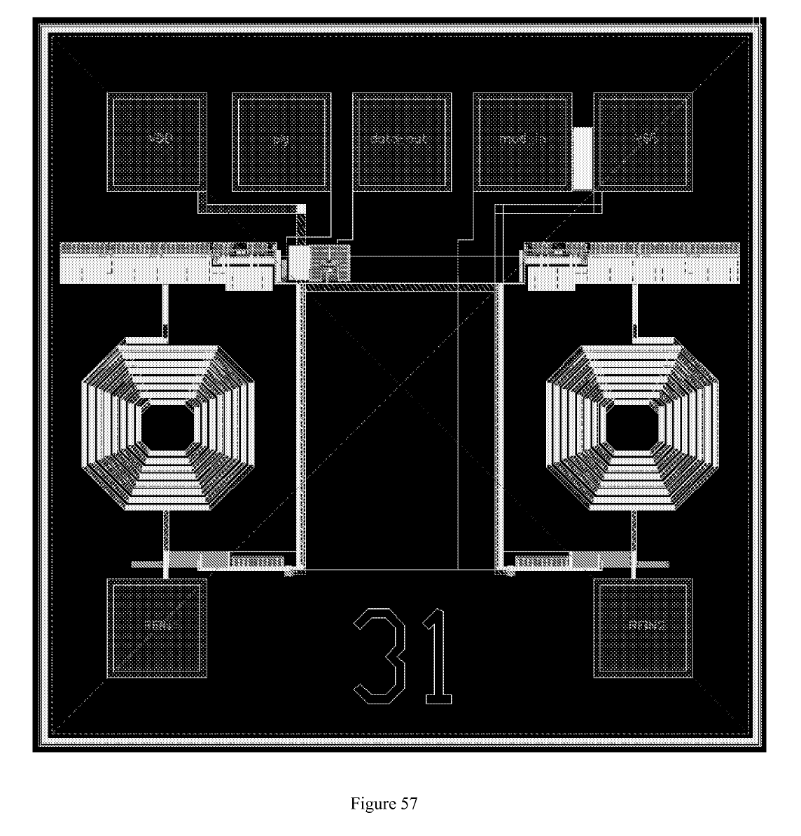

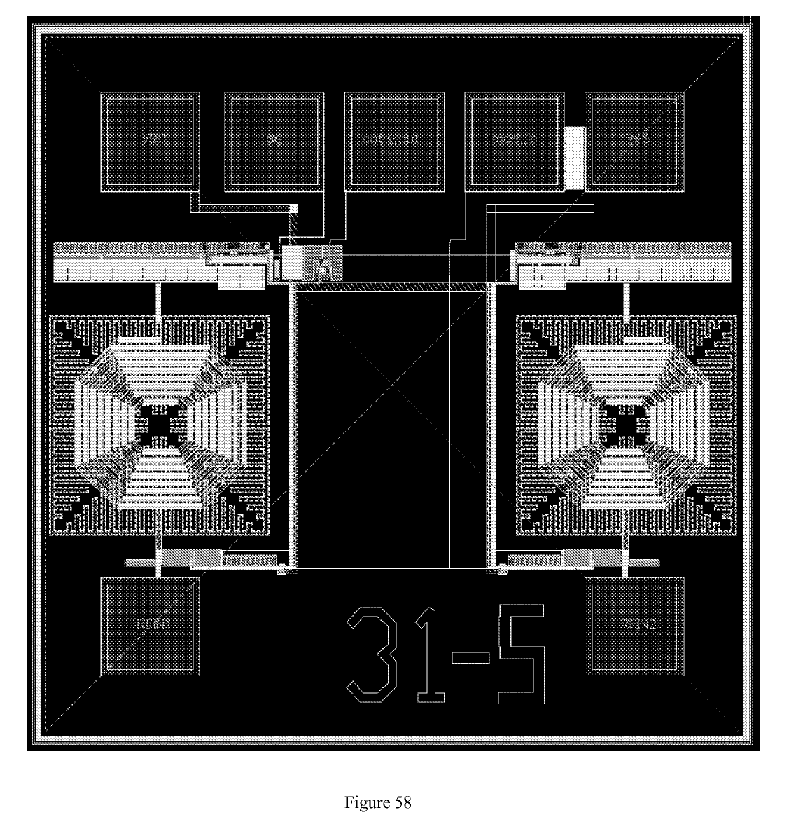

FIG. 57 illustrates Layout 31 of RFID tag dual charge-pump/resonator. In Layout 31, the inductors are unshielded. FIG. 58 illustrates Layout 31-s of RFID tag dual charge-pump/resonator. In Layout 31-s, the inductors are shielded.

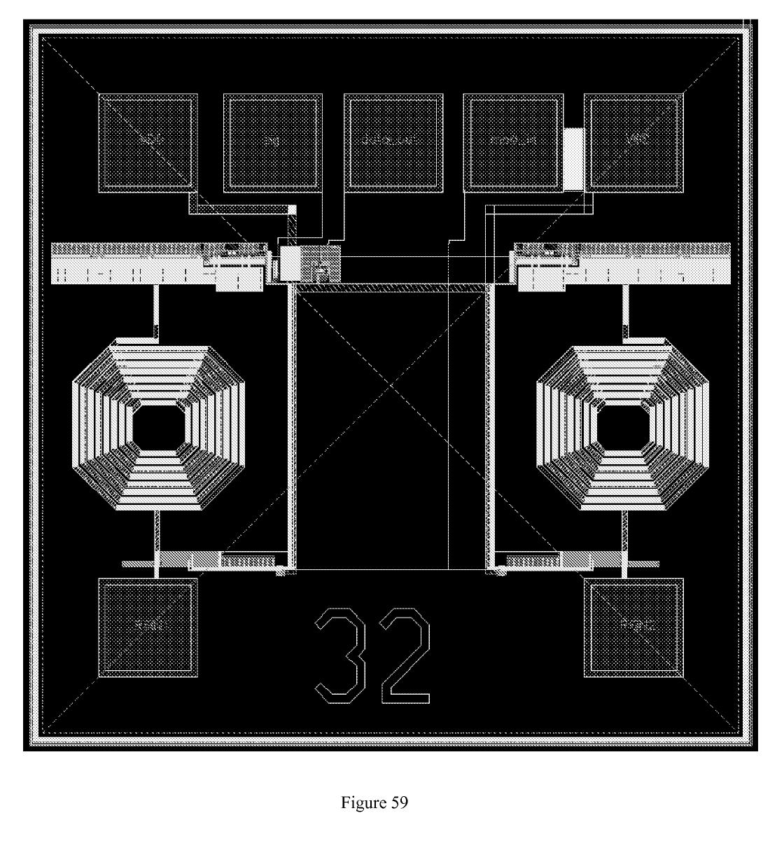

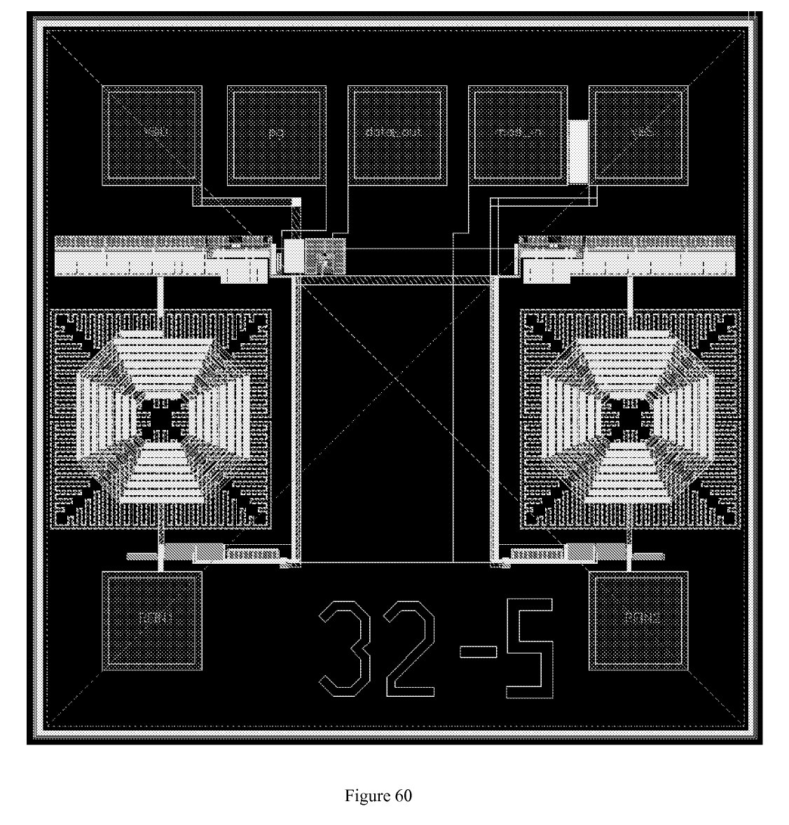

FIG. 59 illustrates layout 32 of RFID tag dual charge-pump/resonator. In Layout 32, the inductors are unshielded. FIG. 60 illustrates Layout 32-s of RFID tag dual charge-pump/resonator. In Layout 32-s, the inductors are shielded.

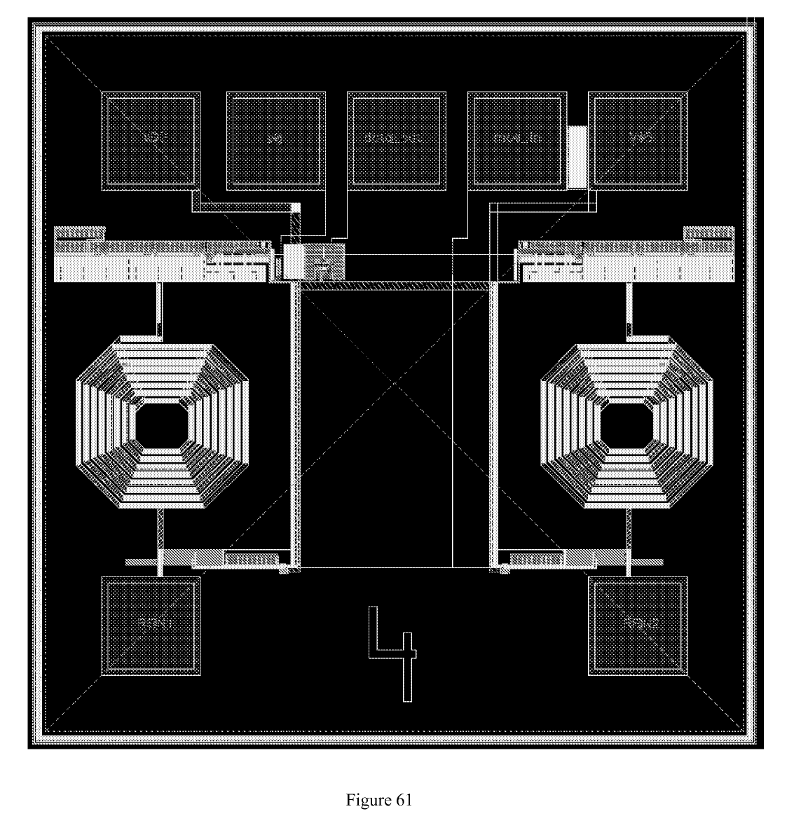

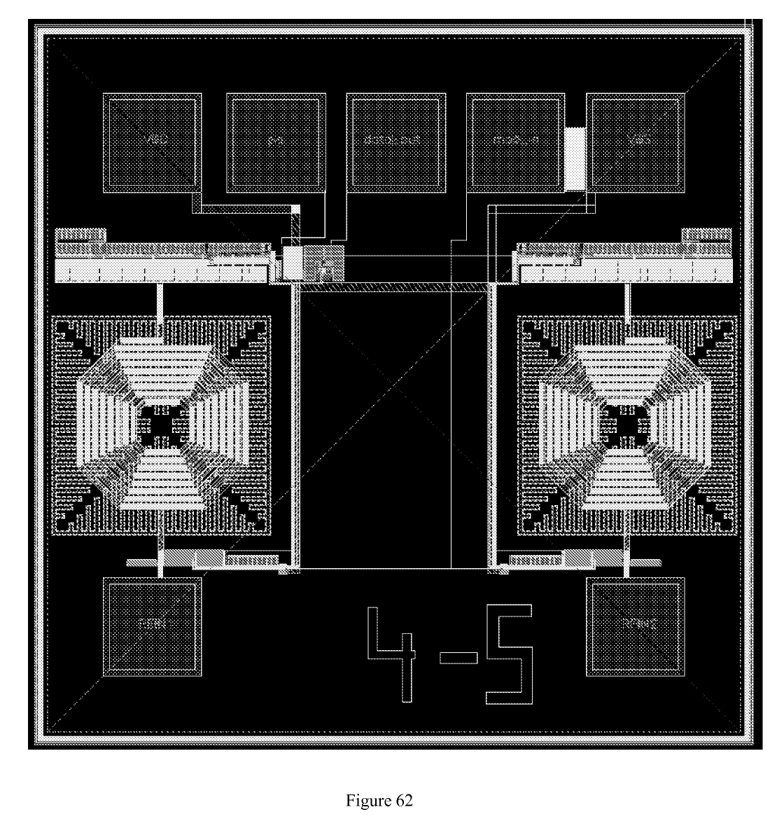

FIG. 61 illustrates Layout 4 of RFID tag dual charge-pump/resonator. In Layout 4, the inductors are unshielded. FIG. 62 illustrates Layout 4-s of RFID tag dual charge-pump/resonator. In Layout 4-s, the inductors are shielded.

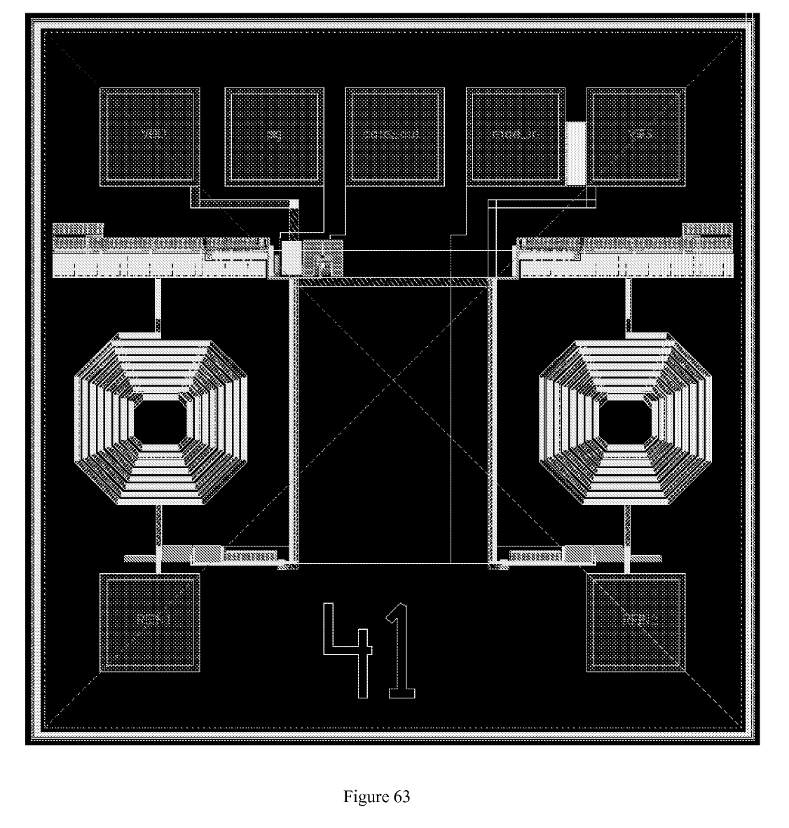

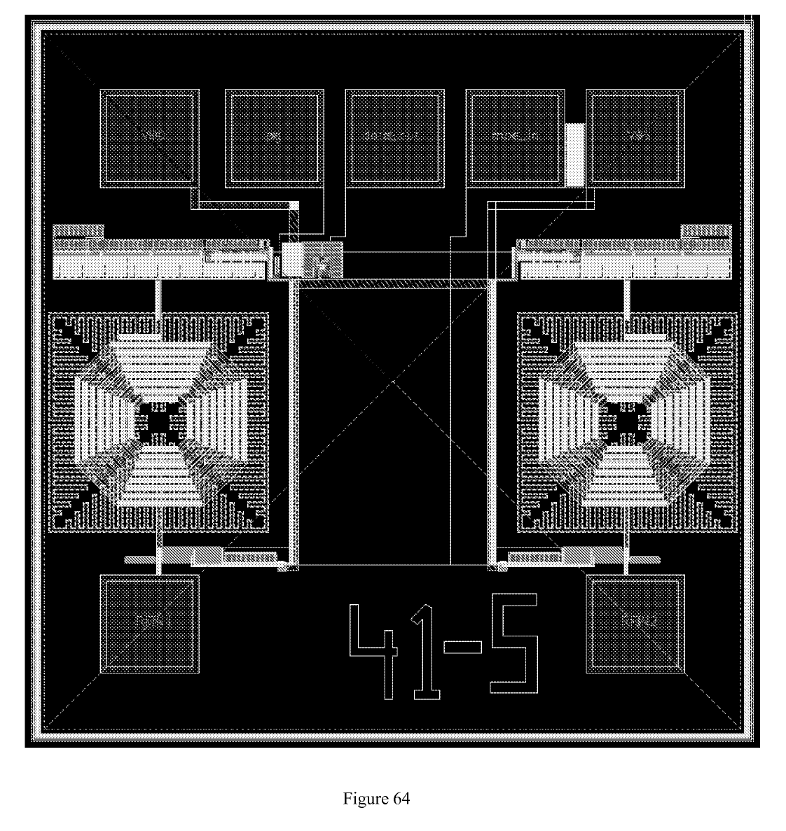

FIG. 63 illustrates Layout 41 of RFID tag dual charge-pump/resonator. In Layout 41, the inductors are unshielded. FIG. 64 illustrates Layout 41-s of RFID tag dual charge-pump/resonator. In Layout 41-s, the inductors are shielded.

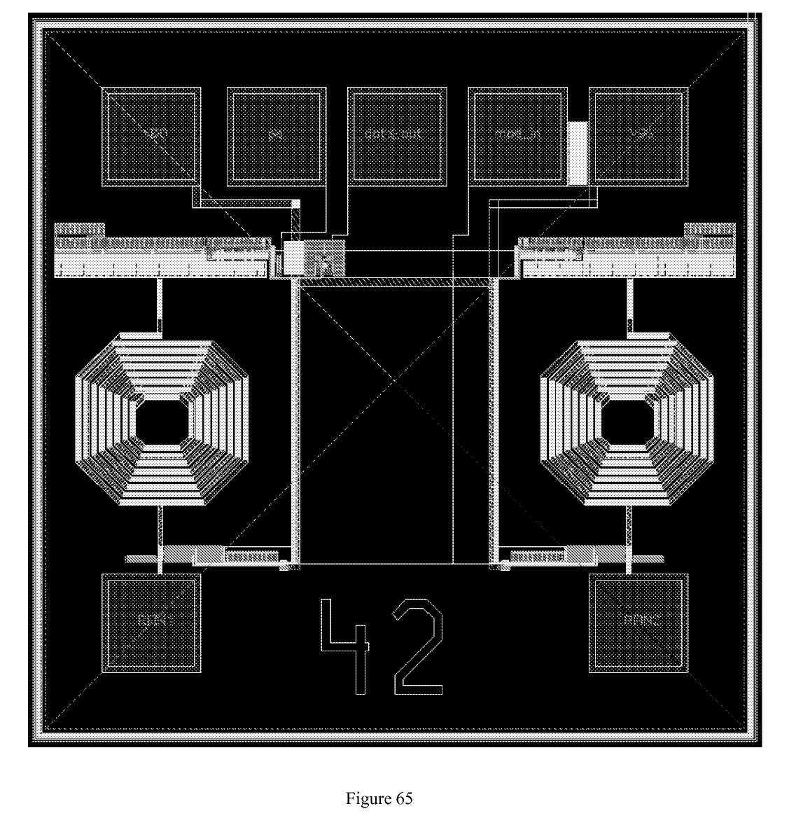

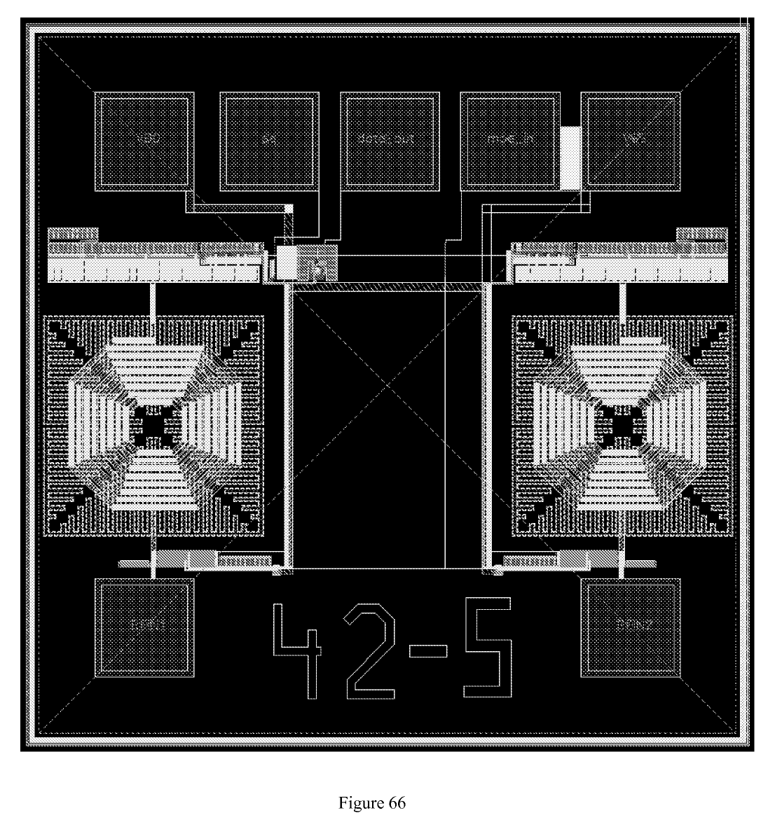

FIG. 65 illustrates Layout 42 of RFID tag dual charge-pump/resonator. In Layout 42, the inductors are unshielded. FIG. 66 illustrates Layout 42-s of RFID tag dual charge-pump/resonator. In Layout 42-s, the inductors are shielded.

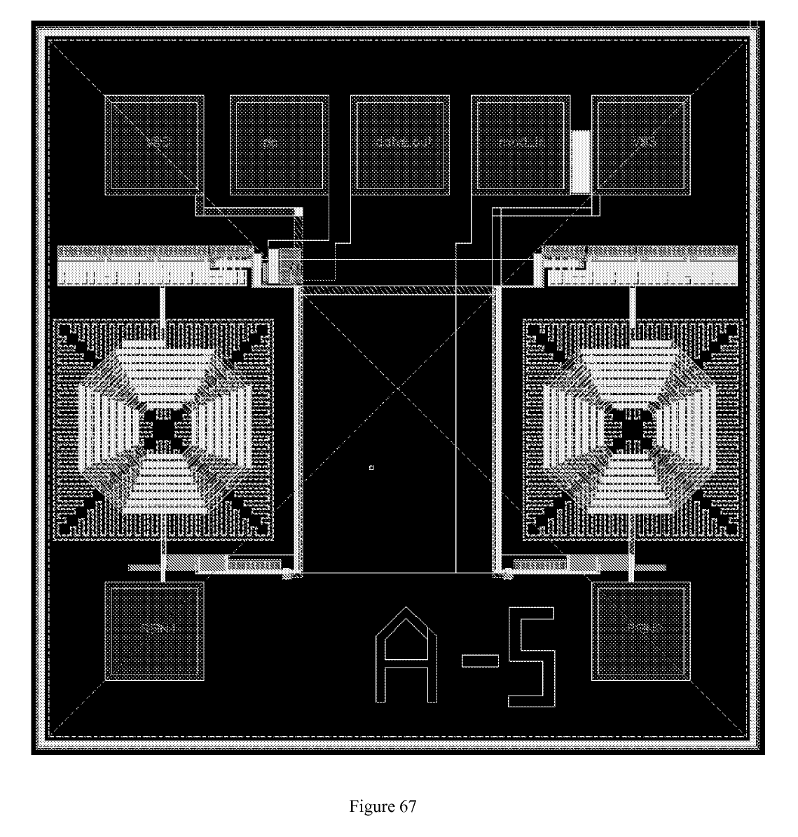

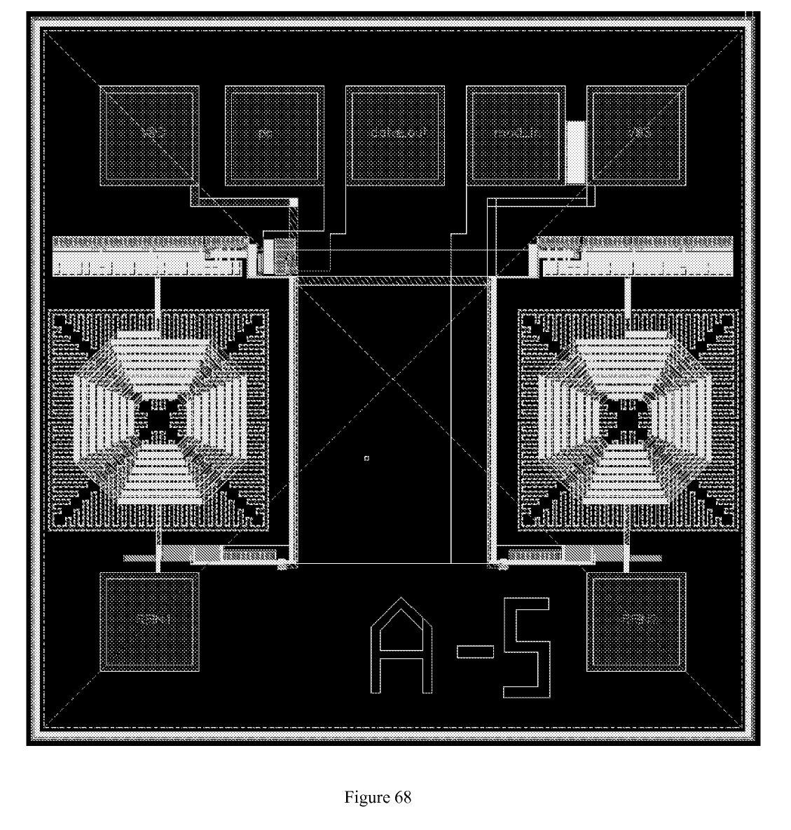

FIG. 67 illustrates Layout A of RFID tag dual charge-pump/resonator. In Layout A, the inductors are unshielded. FIG. 68 illustrates Layout A-s of RFID tag dual charge-pump/resonator. In Layout A-s, the inductors are shielded.

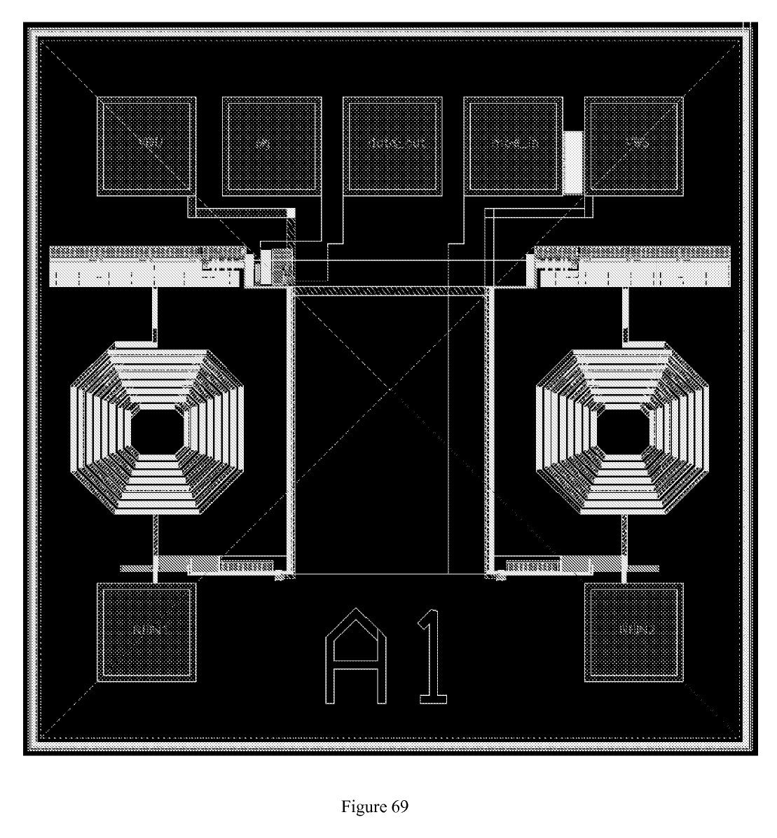

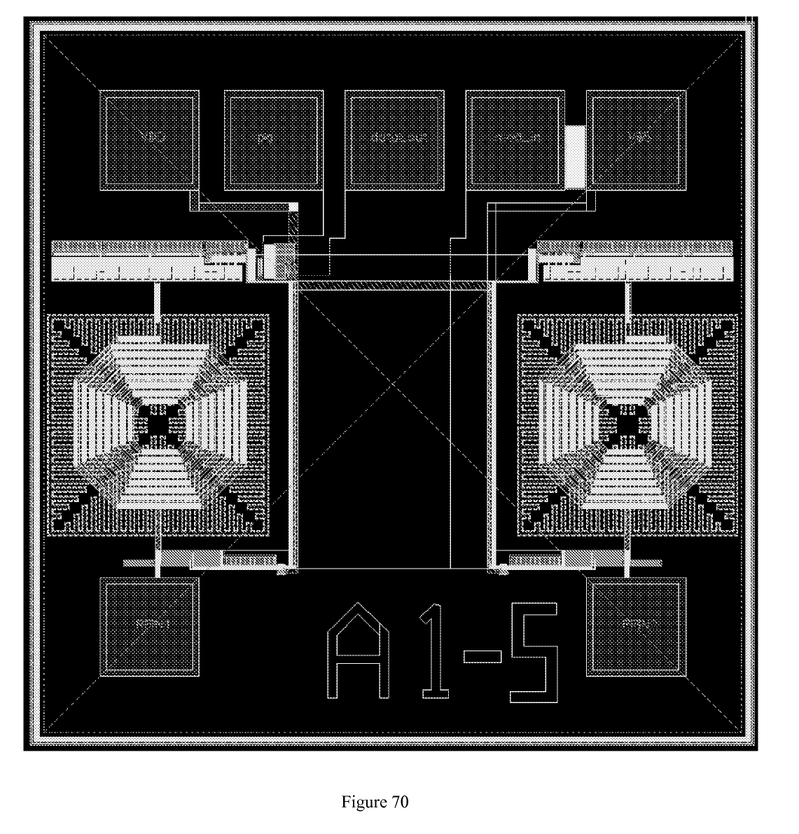

FIG. 69 illustrates Layout A1 of RFID tag dual charge-pump/resonator. In Layout A1, the inductors are unshielded. FIG. 70 illustrates Layout A1-s of RFID tag dual charge-pump/resonator. In Layout A1-s, the inductors are shielded.

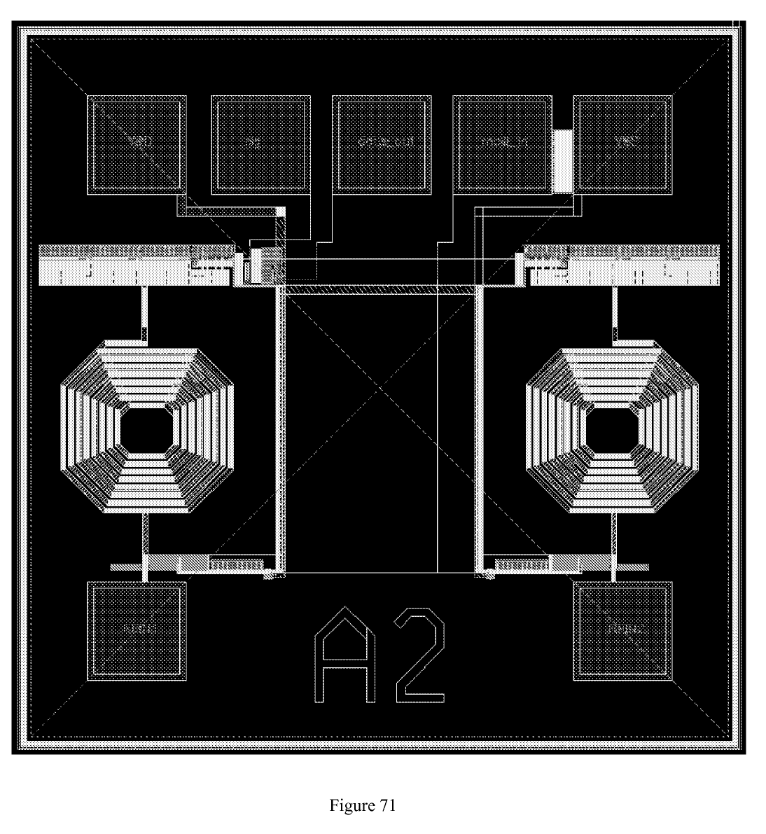

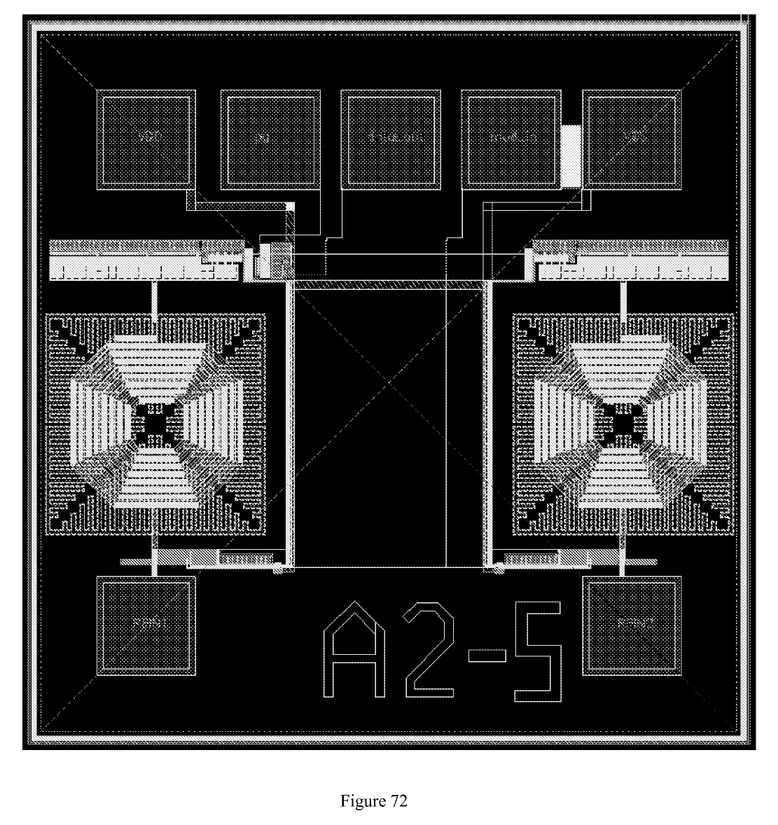

FIG. 71 illustrates Layout A2 of RFID tag dual charge-pump/resonator. In Layout A2, the inductors are unshielded. FIG. 72 illustrates Layout A2-s of RFID tag dual charge-pump/resonator. In Layout A2-s, the inductors are shielded.

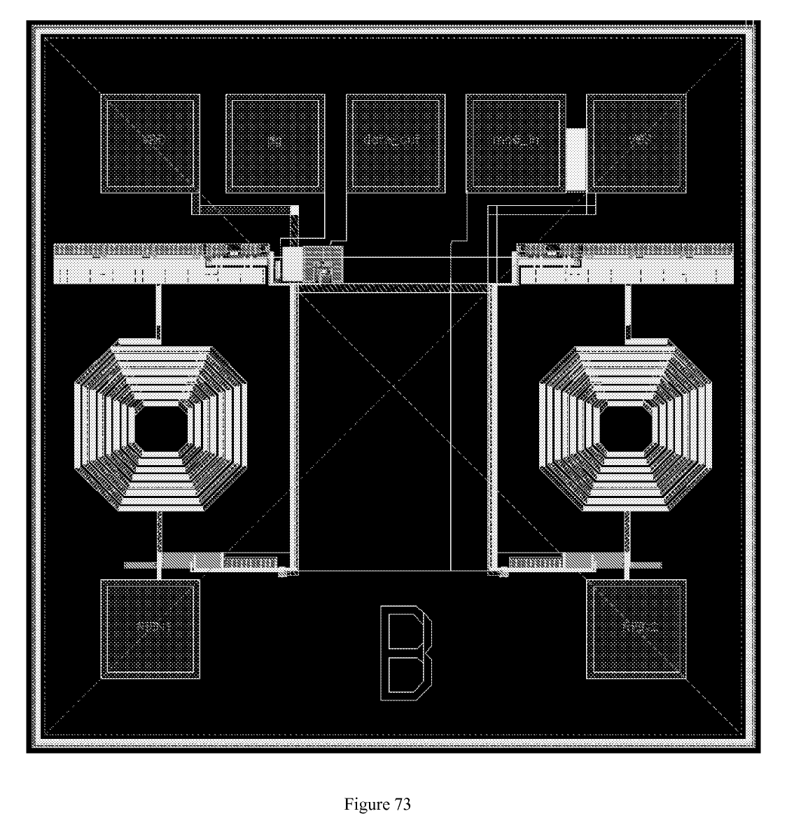

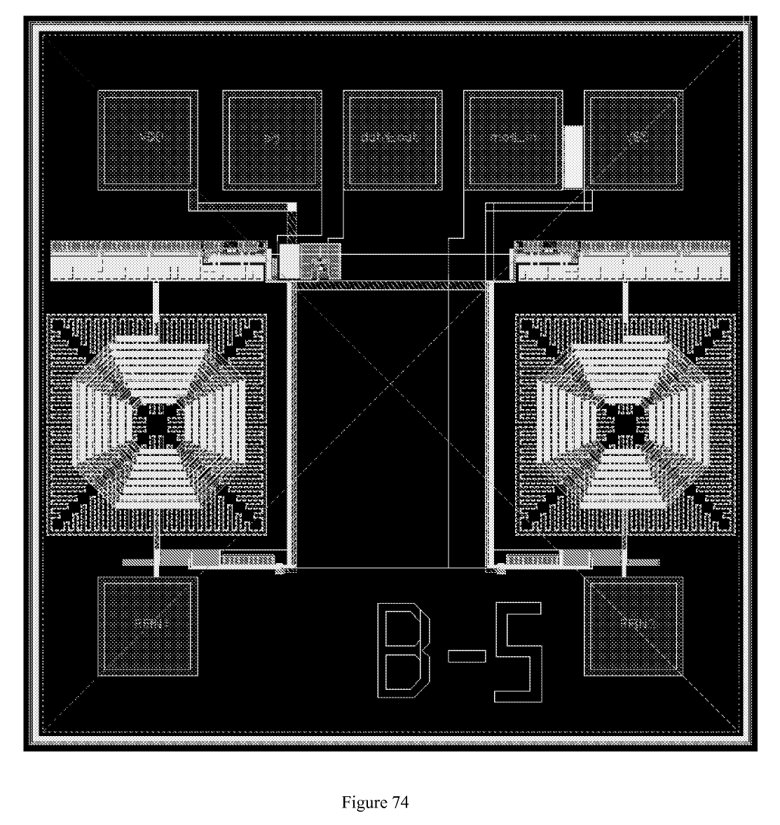

FIG. 73 illustrates Layout B of RFID tag dual charge-pump/resonator. In Layout B, the inductors are unshielded. FIG. 74 illustrates Layout B-s of RFID tag dual charge-pump/resonator. In Layout B-s, the inductors are shielded.

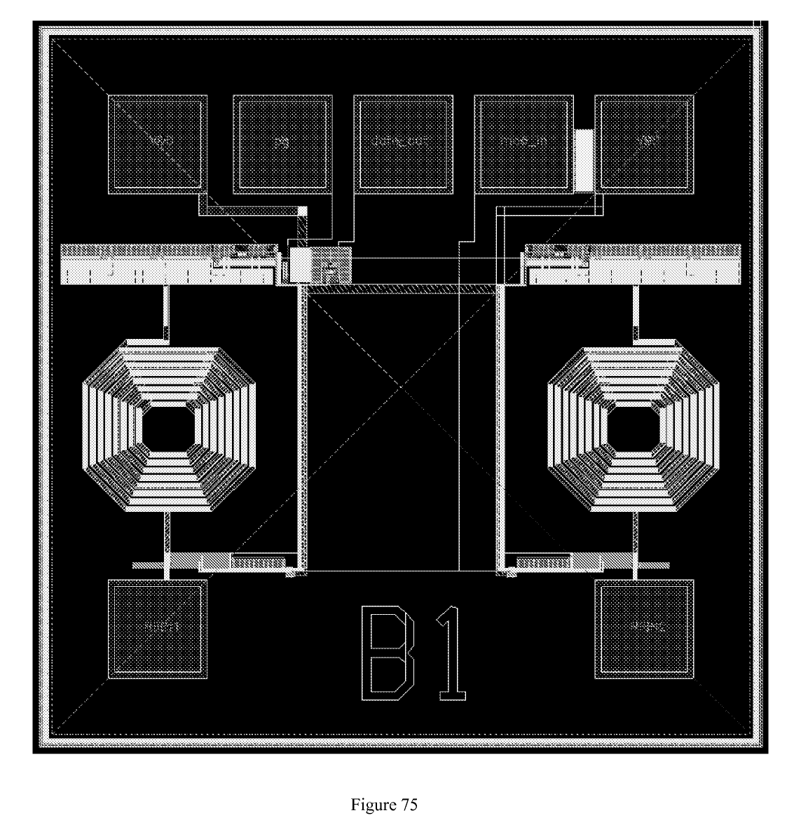

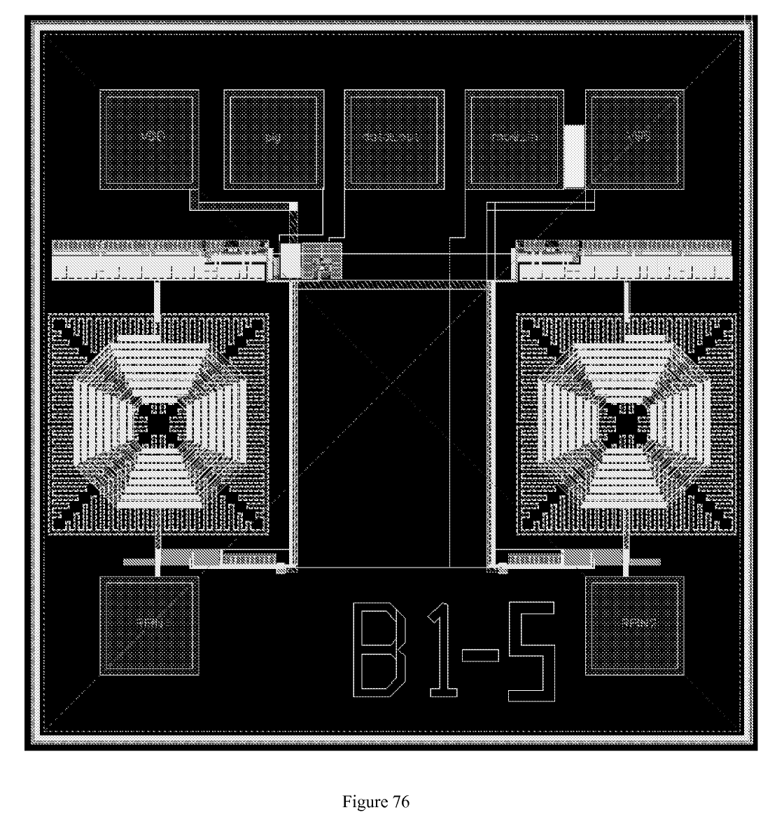

FIG. 75 illustrates Layout B1 of RFID tag dual charge-pump/resonator. In Layout B1, the inductors are unshielded. FIG. 76 illustrates Layout B1-s of RFID tag dual charge-pump/resonator. In Layout B1-s, the inductors are shielded.

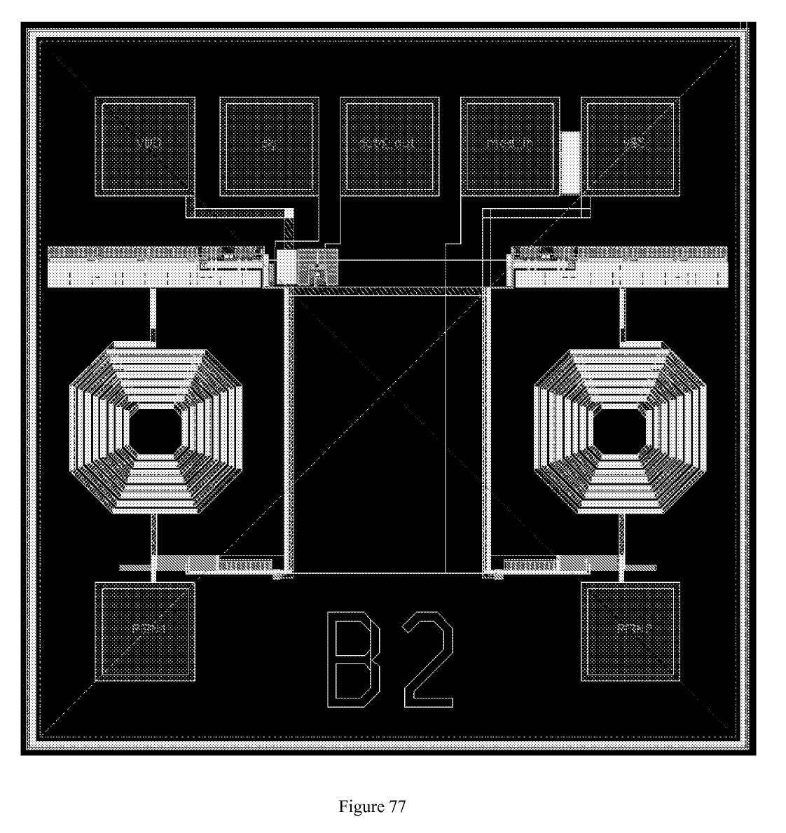

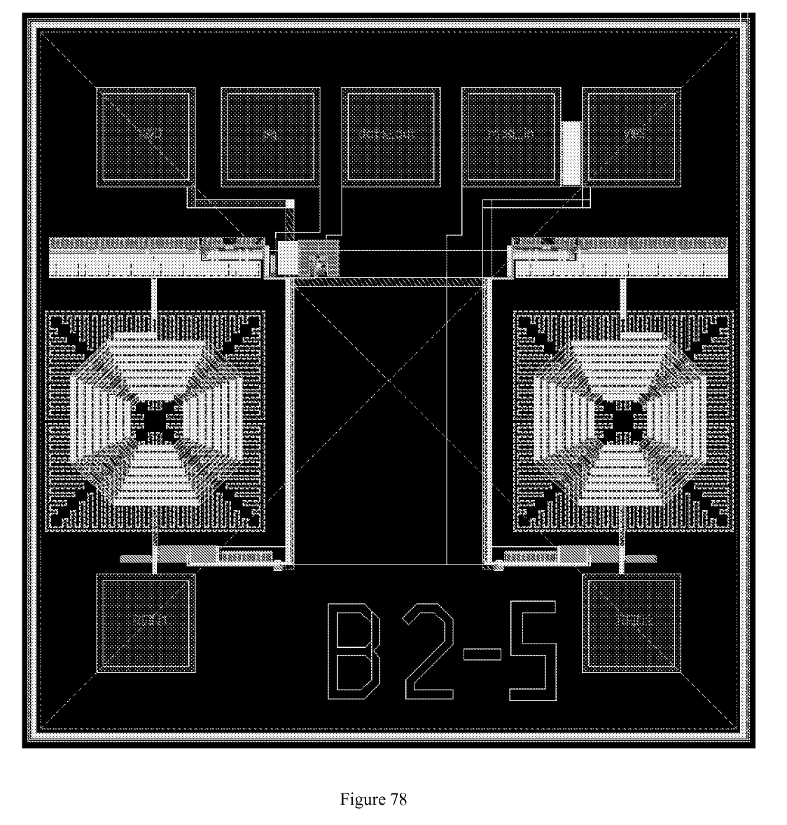

FIG. 77 illustrates Layout B2 of RFID tag dual charge-pump/resonator. In Layout B2, the inductors are unshielded. FIG. 78 illustrates Layout B2-s of RFID tag dual charge-pump/resonator. In Layout B2-s, the inductors are shielded.

P. Oscillator

The oscillator and the logic that it operates is constructed from similar transistor structures using proportionally related capacitive loads. The oscillator is a ring oscillator made up of a series of logic elements. This ring oscillator is powered from a current source instead of the normal voltage source. The amount of current to power the ring oscillator establishes its operating frequency. If manufacturing tolerances or the protocol requires oscillator calibration, this ring oscillator current is established by a Digital to Analog Converter (DAC) whose settings are selected during a power up sequence. The ring oscillator takes a fixed number of logic element delays to create the oscillator output period. The logic that the oscillator drives will have equivalent settling delays. With the same supply voltage powering both, these logic delays will have related strength times loading characteristics. This is a process and environmental parameter tracking system that auto-compensates. It eliminates wasted worst-case operating margins that waste power.

The prior art oscillators used for RFID tag integrated circuits are of the relaxation class. This disclosure employees a current-fed ring oscillator. In the relaxation oscillator, there is one capacitor fed by a current. The active plate of the capacitor is connected to one threshold detecting gain stage. A threshold detection is used to reset the capacitor to begin the next cycle. The threshold detection is placed near one of the power supply rails in order to maximize the voltage swing. If the charging current is a resistance, the voltage is an exponential. This has the problem of crossing the threshold very slowly. In the middle of the threshold detection, there is a pass through current since both the pull-up and pull-down transistors of the threshold detector are in their active state (ON). Any current limiting slows the transition down so that even though the peak current is reduced, this threshold detector current is on for a longer period of time. This results in about the same integrated charge being drained from the power supply. By using a current to charge the timing capacitor, the exponential voltage waveform into the threshold detector is replaced with a linear ramp. This ramp waveform has a higher slope at the time of threshold detection, which makes the threshold detector snap quicker. This reduces the pass-through current of the threshold detector. Note that the charge on the capacitor is dumped during the reset time of the oscillator. This wastes half the capacitor energy available that can be available for timing.

In the current-fed ring oscillator, the timing capacitance is broken up into multiple small capacitors, which are fed by the control current powering the ring oscillator. These capacitances are charged in sequence as each stage of the ring oscillator is active. The total capacitance and the constant current are similar to the relaxation oscillator. The total capacitance is independent of the number of stages, and thus the stage count is somewhat independent of frequency. More stages optimize for lower frequencies and less for higher frequencies, but the total current and capacitance are about the same for a given frequency. A nice high frequency oscillator can be made with this technique. Higher frequency ultra-low current oscillators are expedient when there is a calibration pulse-width sent within the command preamble to the RFID tag at the beginning of its command sequences. During the reader preamble sequence, a pulse width gates this high frequency oscillator into a counter. The counter starts counting at the start of the preamble pulse width, and this counter locks at the end of the pulse width. The counter contents is then used as a prescale to establish the master clock frequency. This prescale is used to determine when a dynamic counter reaches its prescale period count. The dynamic counter is then reset for the next master clock period measurement. Special Resettable dynamic counters are disclosed elsewhere in this document. A divide by three Resettable dynamic counter is also disclosed. This basically doubles the resolution to the prescale, or halves the required oscillator frequency.

C²L Logic in the form of ultra-low power dynamic dividers are used to calibrate the oscillator for any given command. When the logic timing is calibrated for each command, the oscillator only has to remain frequency stable within the specified tolerance for short-term of the command cycle. Long term stability is completely relaxed in this RFID application. Thus the extra circuitry and power for long-term stabilization is not required and this saves a precious quantity of on-chip power.

The threshold detection is taken at the sum of threshold voltages, which is about half the power supply voltage. Here there is a superior high slope on the timing capacitors, along with the threshold detector being biased at its highest gain operating point. An inverter operating at this point has the highest gain per stage of any amplifier configuration, thus the time spent with pass-through current is minimized. This minimizes the charge used by the oscillator throughout each cycle. The discharge part of the capacitor is used for the duty cycle which is half the oscillator's timing period and not just dumped for the next timing cycle as in the relaxation oscillator. The charge in the capacitors is used twice for timing—first for the charge time and then the bottom-plate is pulled to the other power rail so that the charge can be used for another timing period within the oscillator cycle. This is important because this charge is the drain current on the power supply—this charge gets used twice for timing on its way from the power supply through the oscillator.

One advantage is that the ring oscillator self-operates at the lowest voltage possible. This is a square function of voltage. It takes into account the process variations such as threshold voltages and motilities. Very low threshold voltages can be employed to further take advantage of the square law power advantage. This oscillator's operating voltage defines the operating speed of the RFID tag circuit's logic independent of the semiconductor process parameters. The delay of every logic element is related to the delay of an inverter in the current-fed ring oscillator. Thus, this voltage establishes the absolute minimum logic operating voltage and circuit environmental conditions, which are process independent. Ultra-low threshold voltages can be used to further enhance the voltage square law advantage. At low voltage, the leakage OFF transistor leakage current increases, but not as fast as the voltage square-law advantage.

This voltage reference derived from the current-fed ring oscillator is used to derive multiple power condition signals for different voltages. These are self-compensated for process variations due to the current-fed ring oscillator technique.

Q. Ultra Low-Power Trimmable RC Current-Fed Ring Oscillator for RFID Applications

1. Scope of the Current-Fed RC Ring Oscillator Disclosure

The current-fed-ring oscillator circuit blocks are specifically designed for electronic identification tags using RF wireless communication technology. The ability to operate tags remotely using a small transmitter to both power and communicate with remote RFID tag circuits is a key feature of the approach. Low-voltage and ultra low-power operation of the tag circuit is mandatory to passively power the tag to greater distances and/or higher read yield. Smaller tags, or tags within high attenuation locations are enabled. Tags placed close to metal surfaces are also enabled.

The transmission of a unique identification number relies on a dedicated protocol that requires a precise integrated time base. The proposed implementation of the latter is fully compatible with CMOS digital integrated circuit technology and has the definite advantage of requiring no external components, thus allowing the power consumption to be cut down to the microwatt level or even below.

Due to process and temperature variations, integrated RC time constants are usually not well controlled. This lack of initial precision is circumvented by making the oscillation frequency digitally programmable, so that timing can trimmed to the required accuracy following a calibration algorithm (e.g. a successive approximation algorithm), which should be included in the early handshaking of the transmission protocol of fixed at manufacturing for protocols that allow sufficiently loose tolerance.

The oscillation frequency is tuned by adjusting the supply voltage of a ring oscillator constructed with digital gates (e.g. inverters or NAND gates) which are devices identical to those of the integrated digital state machine handling the transmission protocol. This voltage is then buffered to supply the digital core of the RF ID tag circuit. This unique feature allows the digital circuitry to be supplied by the minimum achievable voltage that ensures proper operation at the rated clock speed (as the latter is defined by the oscillator itself). This minimizes the dynamic power consumption of the whole circuit, thus allowing greater sensitivity.

A dedicated auxiliary circuit monitors the circuit operating conditions and delivers a flag when the oscillator is ready.

2. Current-Fed RC Ring Oscillator Circuit Principle Block Diagram

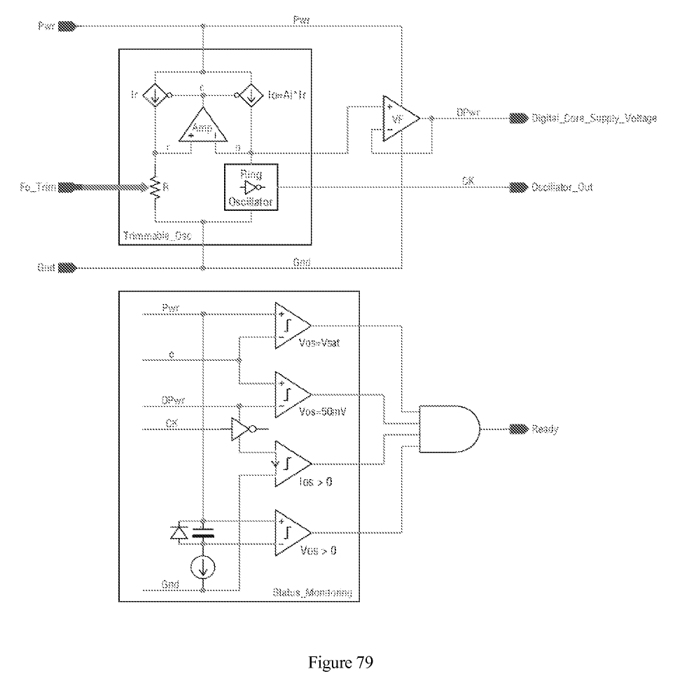

Referring to FIG. 79, the current-fed RC ring oscillator circuit includes the following blocks:
a. The trimmable oscillator, which is made of:
   One ring oscillator supplied at node (o) with one controlled current source (Io) sharing a common control node (c) and common power sink node (Pwr) with another controlled current source (Ir),
   One grounded resistor (R), which is connected at node (r) to the current source (Ir),
   One loop amplifier (Amp), which inverting (−) and non-inverting (+) inputs are connected to the supply node of the ring oscillator (o) and to the resistance terminal node (r), respectively, and which output is connected to the common control node (c) of current sources (Io) and (Ir),
   An auxiliary circuitry (not shown on FIG. 79) to digitally program the value of the grounded resistor (R) and possibly the value of the current gain Ai=Io/Ir.
b. One voltage follower/buffer (VF) which input is connected to the ring oscillator supply node (o) and which output is able to supply all subsequent digital circuitry.
c. One status monitoring block including but not limited to:
   One comparator checking that the voltage across controlled current source (Io) is larger than the saturation voltage Vsat (this comparator has a built-in input offset voltage set to Vos=Vsat),
One comparator controlling that the buffered supply voltage for the core digital is a close match of the ring oscillator voltage, i.e. that the voltage follower (VF) operates correctly, (this comparator has a slightly positive offset),
   A dynamic current sensing circuit checking that the oscillator is running,
   A power-on reset delay element.
   One common current reference (not shown on FIG. 79) providing the necessary biasing voltages & currents to the different blocks.

3. Current-Fed RC Ring Oscillator Circuit Principle

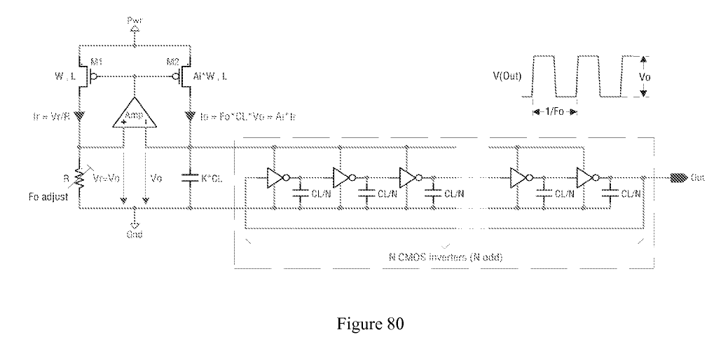

Referring to FIG. 80, the RC-oscillator is built around a ring-oscillator made of N identical CMOS inverters (N is odd). Each inverter is loaded with an equivalent capacitance (intrinsic+additional) of CL/N, so that the average dynamic current supplied to the inverter chain is:
Io=Fo·CL·Vo (1)

Where Fo is the oscillation frequency and Vo is the inverter chain supply voltage. The ripple on the latter voltage is filtered out by a bypass capacitor of value K·CL (K=1 to 10, typically). By feedback action of a differential amplifier and of PMOS devices M1 & M2, the voltage Vo is reproduced across a resistor of value RL, so that the current flowing through the latter is:

$$IR = \frac{V r}{R} = \frac{V o}{R} \qquad ( 2 )$$

As the width of device M2 is made A times larger than that of device M1, we have:
Io=Ai·Ir (3)

This yields:

$$Io = Ai \cdot \frac{V o}{R} = Fo \cdot CL \cdot V o \qquad ( 4 )$$

Thus, the oscillation frequency is given by:

$$Fo = \frac{Ai}{R \cdot CL} \qquad ( 5 )$$

The oscillation frequency can be tuned to the required degree of accuracy by adjusting the resistor value RL and/or the gain factor Ai. The noise performance is ultimately limited by the kT/CL noise, i.e. by the jitter noise of the inverter chain.

The frequency stability with temperature is limited by the resistor temperature coefficient, as Ai and CL can be considered as temperature-independent parameters.

Neglecting the biasing current of the amplifier, the supply current Idd of the cell is given by:

$$IDD = ( 1 + Ai ) = ( 1 + \frac{1}{Ai} ) \cdot Fo \cdot CL \cdot V o \qquad ( 6 )$$

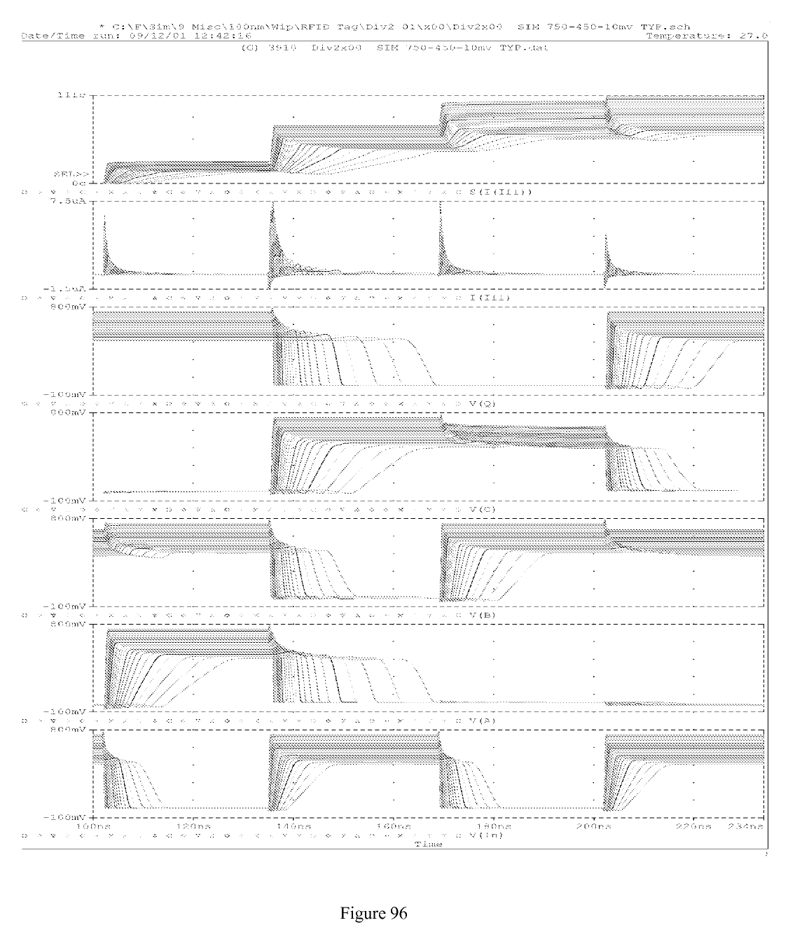

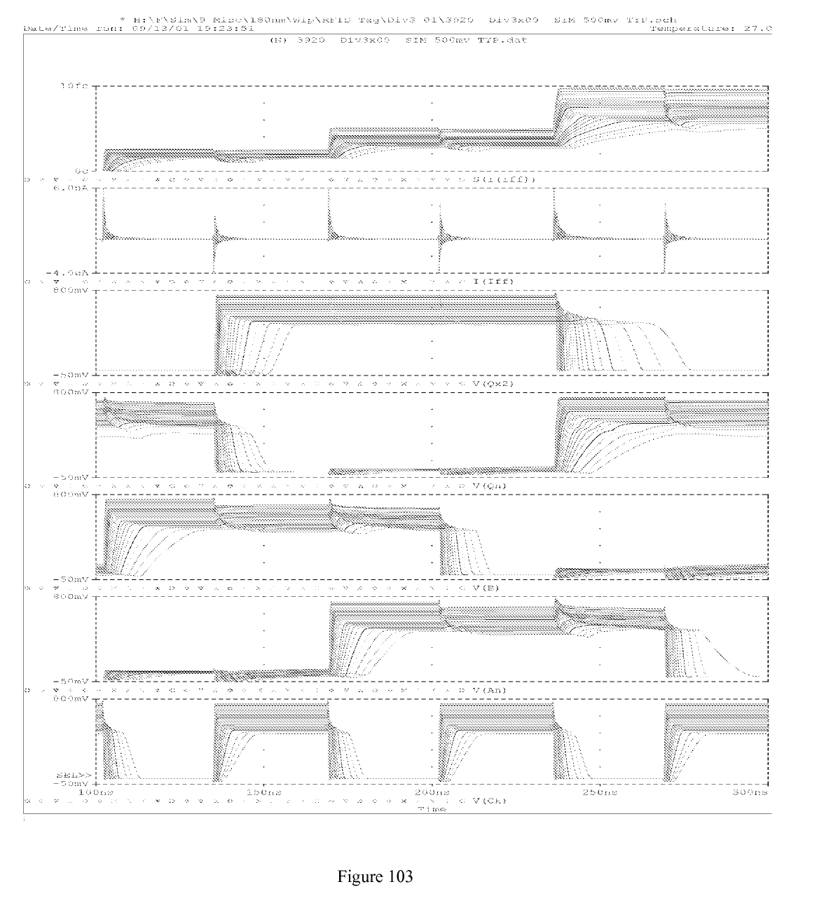

The value of Vo may be less than the sum of the NMOS and PMOS threshold voltages (e.g., 0.5 Volts using normal thresholds and typical conditions as shown in FIGS. 96 and 103). Some examples of the NMOS and PMOS threshold voltages are referenced in G. Machado, C. C. Enz, and M. Bucher, “Estimating Key Parameters in The EKV MOST Model for Analogue Design and Simulation”, IEEE ISCAS'95, Apr. 29-May 3, 1995, M. Bucher, C. Lallement, and C. C. Enz, “An Efficient Parameter Extraction Methodology for the EKV MOST Model”, IEEE Int. Conf. on Microelectronic Test Structures, Trento, Italy, Mar. 26-28, 1996, M. Bucher, C. Lallement, C. Enz, and F. Krummenacher, “Accurate MOS Modelling for Analog Circuit Simulation Using the EKV Model” IEEE ISCAS'96, pp. 703-6 vol. 4, 1996, which are incorporated by reference herein in their entirety.

R. Example of Detailed Current-Fed Ring RC-Oscillator Circuit Implementation

Detailed schematics of a possible implementation in a 0.18 um CMOS process are given as an example. The complete circuit, including biasing, monitoring, & buffering delivers a 50% duty cycle, 7.5 MHz clock from a trimmable 15 MHz oscillator and typically draws 1 uA from a 0.7V supply.

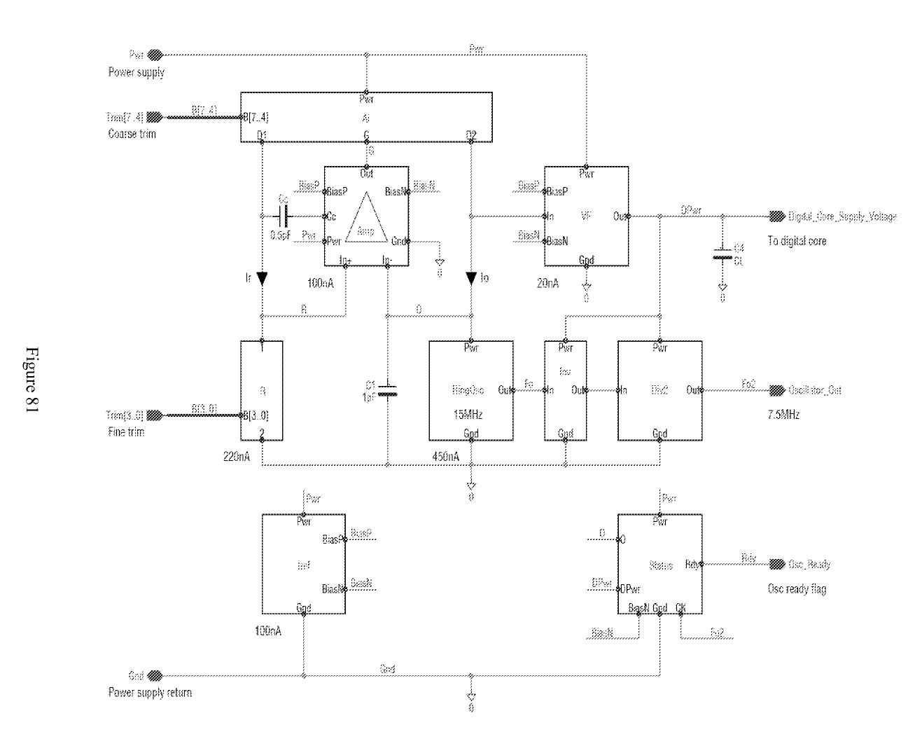

FIG. 81 is a Top Level Block Interconnect schematic of a trimmable RC Oscillator.

The Top Level Block Interconnect schematic of FIG. 81 includes:
One 9-stage, inverter-based ring oscillator running at 15 MHz (Ringosc),
One loop amplifier (Amp) controlling
2 current sources (Ai), the ratio of which is programmable for coarse trimming,
One programmable resistor (R) for fine trimming of the oscillation frequency,
One voltage follower (VF) to provide a low-impedance replica of the ring oscillator supply voltage to the core digital circuitry,
One buffer inverter (Inv) to drive
One dynamic frequency divider (Div2) providing a 50% duty cycle clock at 7.5 MHz
One current reference (Iref) for biasing purposes,
One status monitoring circuit (Status) delivering a flag when the oscillator is ready.

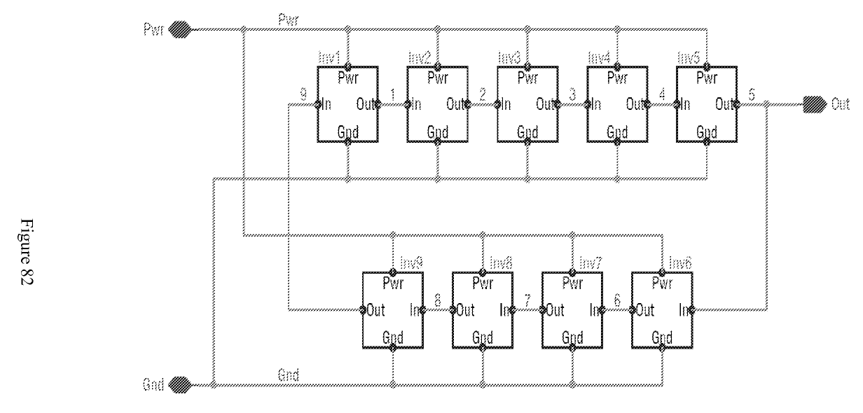

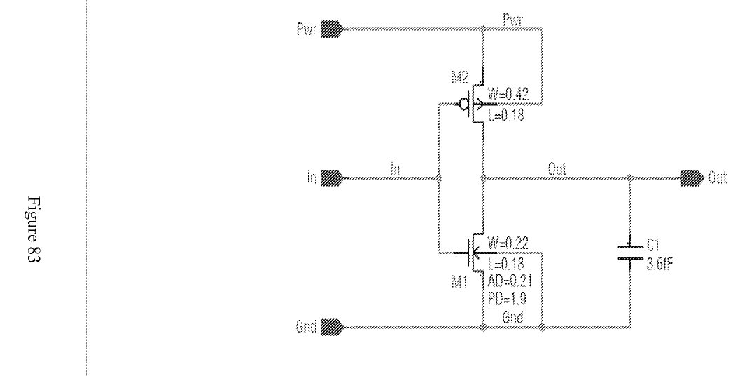

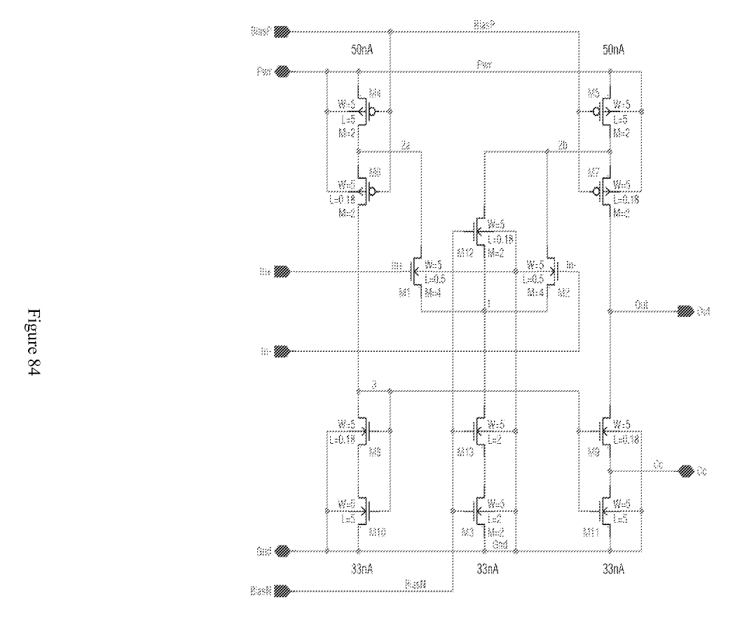

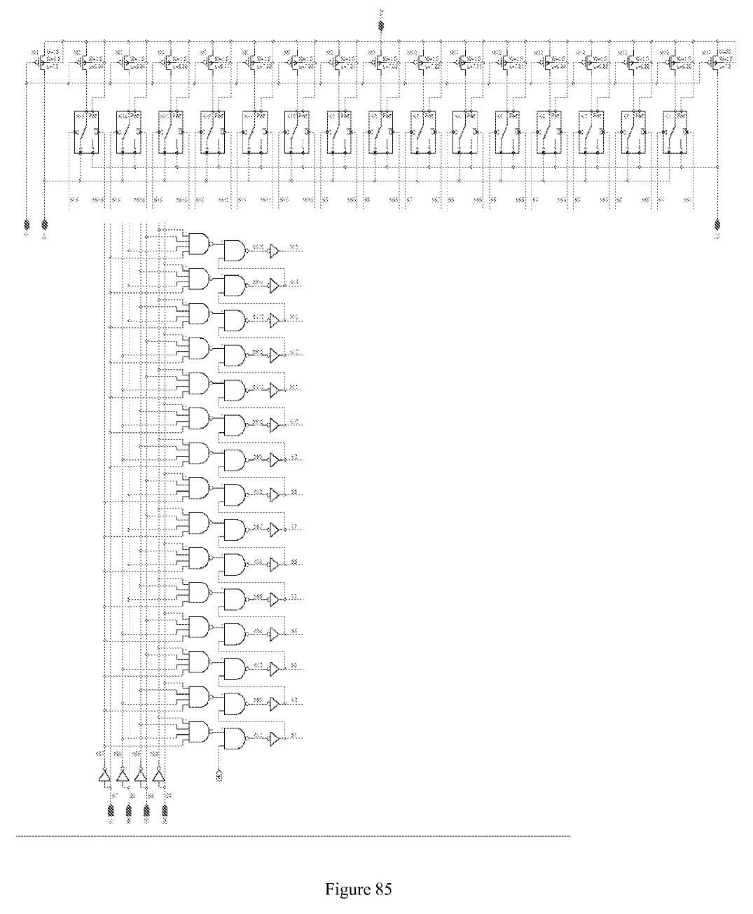

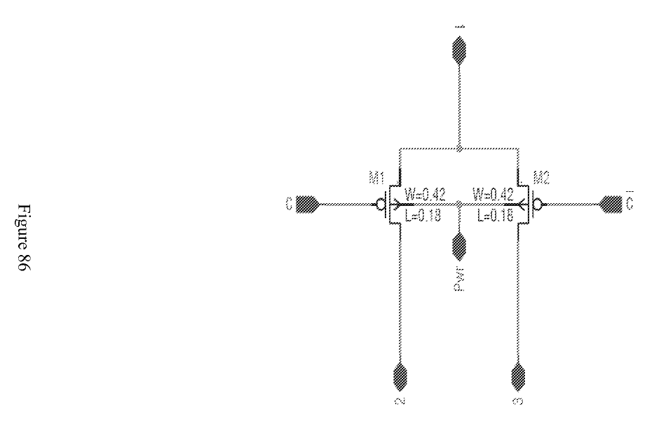

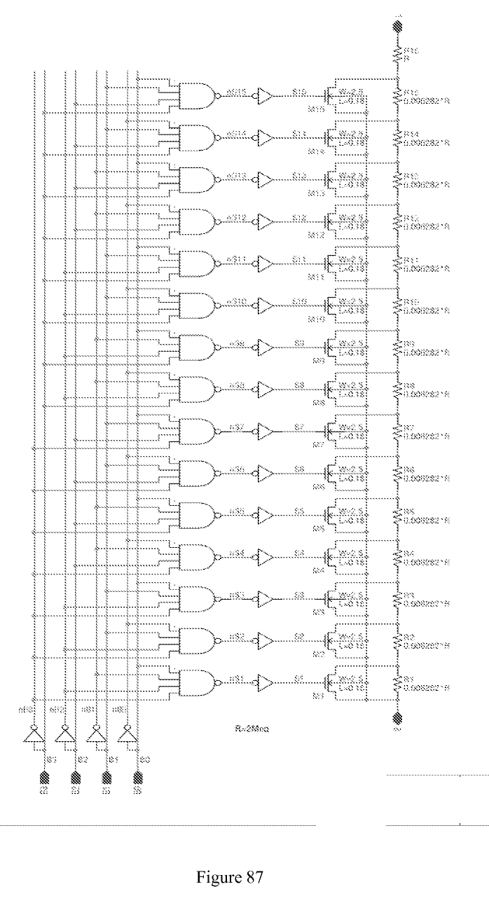

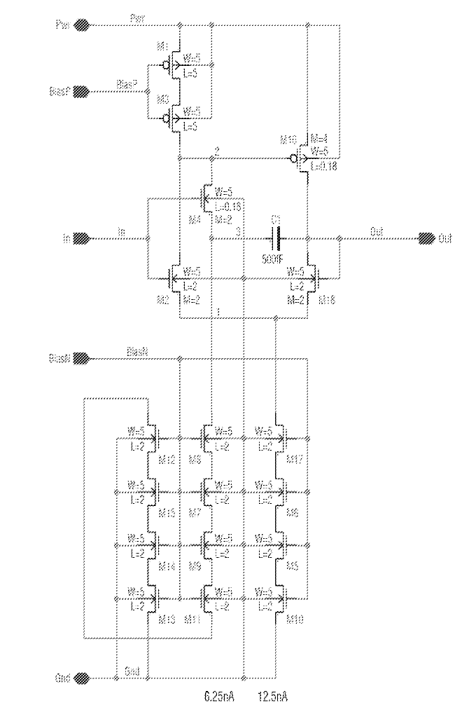

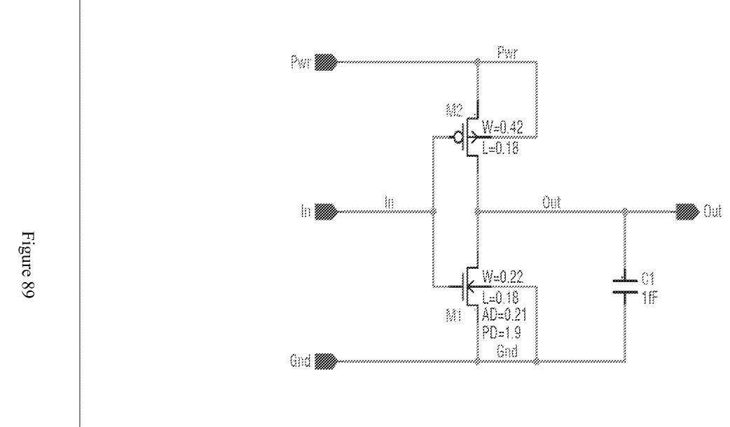

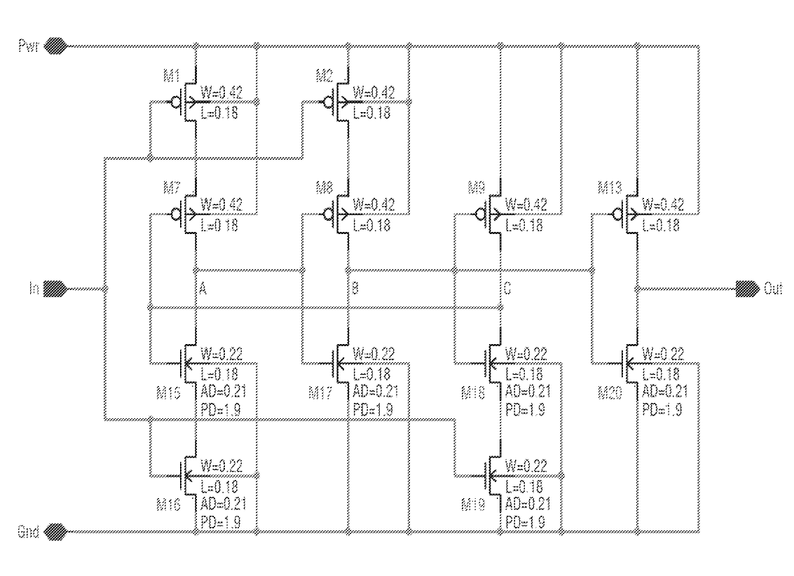

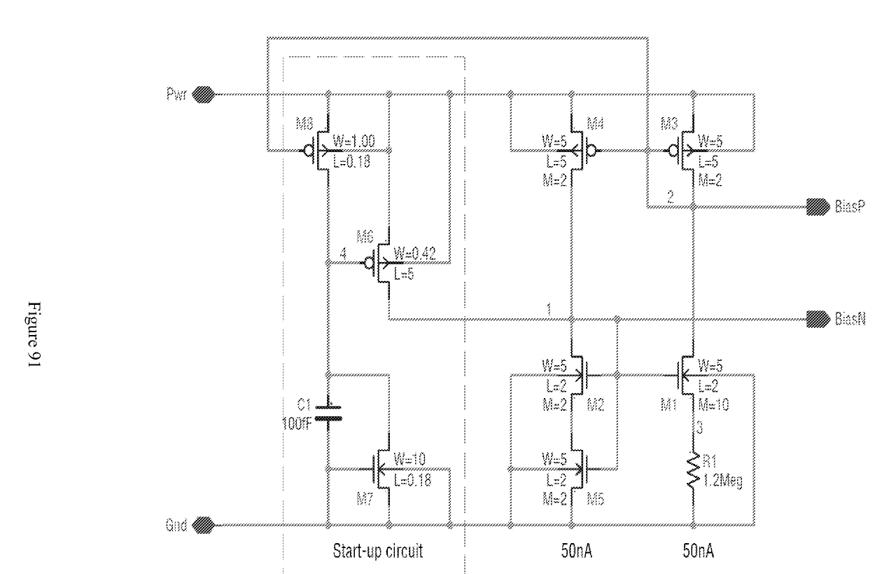

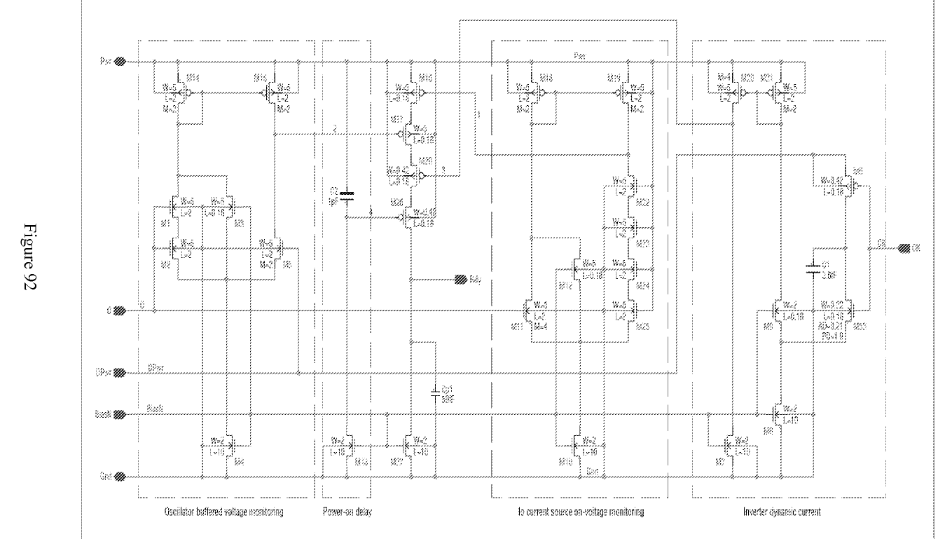

FIG. 82 is a Ring Oscillator Block Interconnect schematic of a Trimmable RC Oscillator. FIG. 83 is a Ring Oscillator Inverter schematic of a Trimmable RC Oscillator. FIG. 84 is an RC Oscillator Loop Amplifier schematic of a Trimmable RC Oscillator. FIG. 85 is a Programmable Current Mirror schematic of a Trimmable RC Oscillator. FIG. 86 is a Programmable Current Mirror Single-Pole-Double-Throw Switch schematic of a Trimmable RC Oscillator. FIG. 87 is a Trimmable Resistor schematic of a Trimmable RC Oscillator. FIG. 88 is a Digital Supply Buffer schematic of a Trimmable RC Oscillator. FIG. 89 is a Ring Oscillator Buffer Inverter schematic of a Trimmable RC Oscillator. FIG. 90 is a Dynamic Divide-By-2 schematic of a Trimmable RC Oscillator. FIG. 91 is a Current Reference schematic of a Trimmable RC Oscillator. FIG. 92 is an Oscillator Status Monitor schematic of a Trimmable RC Oscillator.

S. Memory

The fundamental task of an RFID tag is to rapidly identify tagged articles that are not necessarily in sight of the human operator. This is accomplished by the use of RF readout of the tag memory data, which as a minimum, contain a unique serial number. This unique serial number is used to singulate each individual tag from a sizable population of tags that are RF observable to the tag reader. This serial number may be used to identify individual items through an inventory database lookup. Individual serial numbers provide a mechanism of keeping historical data on every individual tagged item. The particular configuration and capacity of the tag memory is specified by mutually agreed upon standards. The number of memory bits is very precious since the integrated circuit power and tag chip area should be kept at the absolute minimum in order to maximize the tag sensitivity and optimize the disposable item cost. As a minimum, this small number of memory bits (from 40 bits=1 trillion individual serial numbers, to about 90 bits=10 e27) is required to program each individual RFID tag's serial number. The longer serial numbers of 90 bits allows for a less constrained serial number assignment. In addition to the serial number, the tag may be programmed, by the tag user, with more revealing product code data to aid in identification of the tagged article, independent of a central database lookup, in a manner similar to that used in the standard bar codes. Additional tag memory, over the serial number, can be used to identify user defined functions such as tracking data, product status—like sold and returned, control functions—such as checkpoints, etc.

In the most basic application, only the serial number portion of tag memory is programmed during the manufacturing process. When the serial number is initially programmed, each tag should be singulated from the rest of the tag population powered by the programmer RF field. It is impractical to assume that only one tag is powered during this initial programming. Singulation of the desired unprogrammed tag prevents other tags from inadvertently acting on the same program commands and data. This initial serial number setup should initially be executed on identical chips without the benefit of unique serial numbers to tell them apart. A tag may have adjacent powered tags on the wafer, tag manufacturing web (used during tag assembly and shipping), or some tags may just be in a RF hotspots. Initial programming singulation can use a random number generator on the tag to cause single tag selection with a sufficiently high probability, or a protocol that acts on the first tag to transmit can be employed. This provides singulation when the responding tags do not have a serial numbers pre-programmed. All tags within RF range can be initialized in this manner. The only limitation is not physically knowing which tag is singulated and has been initialized with which serial number. Theoretically, all tags will be eventually initialized with their respective serial numbers, even though which tags have what serial numbers will not be known.

To physically select which tag receives an initial serial number, when it is possible for more than one tag to be powered by the RF field, a scheme may be used where the lowest bits of the serial number are fabricated with these bits set at the integrated circuit mask level. This is performed by fixing sets of the lowest group of serial number ROM bits on the mask for integrated circuit fabrication. Here each group of cells in the stepper pattern are all made with their own lowest serial number bits fixed. There can be a number of patterns stepped onto the mask with each having different low bit serial number fields. The extent of this can satisfy the requirements of separating tags during manufacturing for the rest of the serial number initialization.

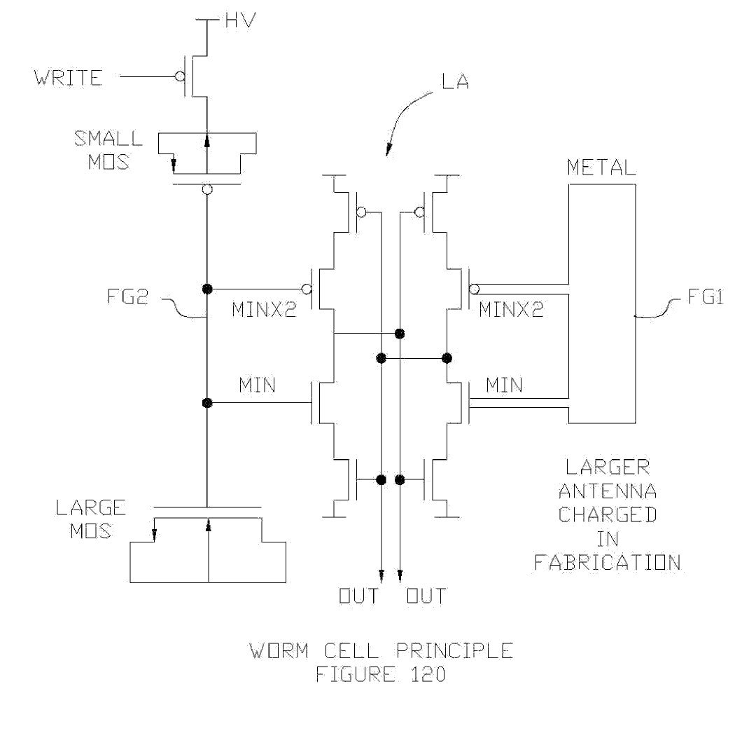

Single-Poly EEPROM or WORM (Write Once Read Many) memory is constructed in standard single-poly CMOS logic process using its one poly layer for construction the Floating Gate Device (FGD). The data is stored on the FGD as stored charge. This node becomes floating when there are no diffusions tied to it. This floating gate node has only a number of MOS device gates tied to it. Normally there are diffusions connected to every node to drive its voltage. This floating node includes the gates of the programming devices, the gates of a sensing circuit, and nothing else (i.e., includes only gates and no diffusion attached to it) as illustrated in FIG. 120. These FGD are assembled by joining only gates of several MOS transistors together for the floating node—no diffusions are connected to the floating node. In addition to the readout transistors, which use the floating poly only node as their gate, it uses one or more transistors to add or bleed charge from this poly only floating node. This programming is done by taking the source and drains of these programming transistors to a high enough voltage to produce tunneling to this poly only floating node. The MOS device's channel can be used for tunneling if both the source and drain are tied together on each programming transistor.

During integrated circuit manufacturing, there is a concern for floating gates obtaining sufficient charge to break down the gate oxide. Design rules have been established that limit the area of metal to gate area so that the accumulated charge will not generate enough voltage to breakdown the thin gate oxide. This aspect of integrated circuit manufacturing can be taken advantage of by using the accumulated charge as the initial set to zero state of the floating gate memory. With this, memory can be simplified to the WORM type. Only ones are written to their respective bit locations when they are programmed. The bulk of the RFID tag applications do not require re-writing data, or can use extended memory locations for additional programming. This enables simpler, more area efficient, and lower cost RFID tag memory for this majority of applications. The simpler the circuit generally results in lower overall power and thus higher sensitivity.

Referring to FIG. 120, floating gate charges (FG1 and FG2) are used to flip a symmetrical latch (LA) upon power up. The latch (LA) has to have sufficient gain and/or feedback to not hang in the middle during power up. The integrated circuit fabrication processing result in a charge built-up on both floating gate (FG1) and floating gate (FG2). Floating gate (FG1) is a larger antenna area, which accumulates more charge than during fabrication processing (manufacturing) than floating gate (FG2). This larger charge is used to define a zero in the Write Once Read Many (WORM) data bit (OUT). To write a ONE in the memory (WRITE), a voltage stress is applied to a small area MOS device (SMALL MOS) resulting in a tunneling current. All the applied high voltage is across the small area MOS device (SMALL MOS) because the capacitance of a large area MOS device (LARGE MOS) holds the floating gate voltage LOW. As such, the large area MOS device (LARGE MOS) is used here to provide capacitance to the floating gate node (FG2) and does not provide MOS functionality. Alternatively, other type of capacitors, such as Metal Insulator Metal (MIM) could be used.

Also, as shown in FIG. 120, at lower startup voltages, there needs to be less floating gate voltage applied and thus less charge is required. This makes writing easier since less charge should be tunneled. It takes more charge to operate at higher voltage since more trapped charge is needed to effect the threshold voltage to flip the memory to its readout state. This way, only a small amount of charge is needed to program the memory cell. To balance the circuit and cancel out process parameters, this power up latch cell is made differential or fully symmetric. The fundamental element for programming the FGD is constructed by joining the gate of the large area MOS device (LARGE MOS) to the gate of the small area MOS device (SMALL MOS) of the opposite CMOS polarity and no diffusions. Native or near zero threshold transistors may be used to start the memory latching process at near zero volts as the tag power supply comes up.

The application of higher tunneling voltage is used to write to memory cells. The longer this voltage is applied, the more the amount of charge that is transferred onto the floating nodes via tunneling. The relationship of voltage used to the time it is applied defines the operating point designed into this memory. There is a maximum write time limit specification agreed upon in the RFID standards made for inter-operatable compatibility. If writing should occur in 10 milliseconds for instance, the voltage required to transfer sufficient charge is defined. Since the RFID tag does not have to operate at high speed, this relaxes this high voltage requirement. The very thin gate oxides of the deep sub-micron processes bring the required voltage down to efficient voltages that can be easily generated and used during writing. The small cells also work to provide a compact low power RFID programmable memory.

Semiconductor processing leaves a charge on floating gates that is used to define an unprogrammed state which is defined as zero data. The “antenna” design rules are a reference to this accumulation of charge during processing. This is used to construct a program once RFID tag that is significantly less complex. This tag memory can be written in stages to provide the user with programmability. Since very few re-writes are required for tags, the memory can have extra bits or fields that supersede existing fields if programmed.

There are several PROM technologies that have been used in the past. UV erasable for example is one. This would be a useful type of memory for RFID since it can be fully testable. All ones are written, and bulk erasure will remove the all ONE state from testing for an initial serial number initialization. This erasure would have application where the tags are reused in such applications as shipping pallets and containers. Hot carrier injection programming methods are practical for RFID because of the ultra small dimensions of the deep sub-micron CMOS technologies even from the antenna power. With the new deep sub-micron integrated circuit technologies, the older PROM/EPROM memory technologies are reconsidered for RFID usage where there are greatly relaxed requirements. The RFID application is extremely slow and only has to be reprogrammed but a few times at most. For RFID, the extremely small deep submicron CMOS technology dimensions relax and change the rules of previous memory technology. Current densities do not consume much current due to the small dimensions. The gate oxide is already thinner than most previous EPROM technologies, in fact it is at the limit within the normal specified operating conditions.

T. Programming

When write once memory is used, the contents cannot be re-written, but if the memory initially set to, for instance, all ZEROs, the addition of ONEs is performed during writing. This data can be filled with ONEs at a later time if it is desired to erase it. The addition of increased memory address space would provide for alternate addresses that could be used for replacement data, thus making it possible to rewrite or modify data for a limited number of times. An all ONE programming of words would redirect the tag read to alternate locations. This has application in an RFID tag in that memory that does not have to be erased for rewriting is much simpler, requires less power and area to implement. This modified WORM technology will not cover all RFID tag applications, but is limited to the majority of RFID tags, where it will significantly reduce memory complexity, area, and power and thus contribute to the tag sensitivity through lower power as well as decrease overall tag cost.

Querying specific RFID tag memory bit locations is used to return digitized RFID tag integrated, or attached, sensor outputs. Examples of these sensors (though not limited to these) are temperature, pressure, humidity, etc. Mechanical change sensors can record over or under measurement limit conditions. This is helpful for keeping data on items such as food during shipping. Similar read-backs for acceleration, shock, and vibration. Many of these measurements can be made differentially. Mobile systems can collect and pass this RFID tag sensor information on to a central location. Active tags can also produce improved measurements and communicate through ad-hock networking of tags. The data is read out as specific memory locations.

Programming with a tag reader at close proximity, possibly inside a shielded area over the reader RF head. This lowers the probability of programming other tags in the vicinity and provides a condition of higher energy on the antenna for programming. This is especially useful for initial programming if a serial number identifier which is later used for singulation of a single tag out of a field of tags for programming. By hard coding several lower bits in the serial number field, it is helpful in singulation a tag in a small area for initial serial number programming. This can be done at the mask level by fabrication partitioned off into repeated arrays of RFID tag die with the lower bits fixed to different codes. These arrays are repeated across the wafer in the mask stepping processes.

U. Logic Design

Ultra-low-power C²L CMOS technology has been developed and patented previously. The use of EKV (Enz, Kirummenacher, Vittoz) SPICE compact simulation models enables a reliable look into the ultra-low level weak-inversion circuit operation for RFID designs. The patented C²L cell library technology reduces the circuit operating point to below 0.5 volts with normal thresholds, and reduces the power consumed by all the internal circuitry to around 1 microwatt. Included in this circuitry is an oscillator built form the same C²L logic from which an internal power supply regulator based on process parameters is derived as disclosed earlier in this document.

Logic design that employs techniques similar to Grey-code counters is used in the RFID tag. These techniques strive to minimize coincident timing transitions. The charge pump operates over 1000 times faster than the RFID tag electronic timing event rates. By not minimizing the number of coincident logic transitions on any of these lower rate-timing events, the peak energy drain is reduced, thus minimizing the power supply ripple. This enables more consistent logic timing. When the power supply voltage droops, the timing edges are stretched out in time.

Clockless, or self-timed logic, reduces the RFID tag operating voltage to a minimum and thus preserves energy on the tag (power being a squared function of voltage). Lower chip operating voltage means that the power recovery circuit may become more efficient in that it does not need as many stages, or may be in the extreme be just an active rectifier. Clockless logic, eliminates the need of clock distribution and the wasted energy of continual clocking of the state machine on the RFID tag. An oscillator and some sort of calibration method are needed to measure and communicate back to the reader, but this clock does not have be used otherwise.

Using all very low threshold voltage devices (Vth) throughout the logic enables operation at an ultra low power supply voltage of perhaps 200 mv. Here the increased transistor OFF leakage power is traded off against the decreased power supply voltage's CV2 power. An aggressive approach to approach this lowest supply voltage operation provides very significant rewards in that the power supply is simplified in both voltage and output current resulting in a higher efficiency power recovery. Lower input voltages may be rectified, not as many stages of charge pump are required, or it is possible to replace the charge pump power supply with an active rectifier at these voltages. The rectifier has much higher efficiency in that the multi-stage charge pump parasitic capacitances and its stack of turn-on voltages are almost entirely eliminated.

When using all very low threshold devices thorough ought the logic, energy reduction is aided by the reduced OFF current leakage resulting from reduced supply voltage. At any given threshold voltage, there is a minimum power supply voltage that is required to achieve circuit operation. The oscillator, along with its logic outputs indicate various safe operating supply voltage levels as listed above. The best combination of these circuit power supply/logic methodologies depend on the process used and the circuit requirements. The rate of logic transitions are a determining factor in determining the balance between dynamic power and static leakage power. The minimum power occurs when they are equal.

Use of all very low threshold voltage (Vth) MOS transistors makes an unusual tradeoff between static power and dynamic power. 1). The lower the threshold voltage selected for semiconductor processing, the lower the logic power supply voltage can be employed for a given chip speed. This provides lower dynamic power with a voltage squared advantage. 2). Lower threshold voltage means that the MOS transistors do not turn OFF, that is the ratio of ON to OFF current may be as low as 10 to 100 in this case. For each logic node, there is an ON transistor network pulling against an opposing OFF transistor network. Lower logic power supply voltage also reduces the leakage current.

V. RFID Tag Use of Complementary Complex Logic (C²L) Cells

Complimentary Complex Logic (C²L) consists of energy efficient logic cells. This technology also helps reduce the power consumption through reduction of logic cell area and parasitics. A large portion of the logic power is consumed by its interconnect. When the interconnect is reduced, the output drivers are reduced by the same amount to maintain the delay requirements. The cells are also internally faster due to reduced internal capacitances. This also lightens the output driver requirements. Lighter output drives define smaller transistors which reduce the OFF leakage current. This is especially important in the deep sub-micron geometries where leakage current is approaching the dynamic current or power drains. This is also equally applicable to the use of native or near zero threshold technology. The faster inherent logic core can have its power reduced as a tradeoff against this speed. The logic core area reduction is directly proportional to the interconnect power. Low power supply operation is aided by the use if C²L's true single phase clock flip-flops and coincident-clock circuit design considerations. C²L minimizes logic core area, thus minimizing interconnect, thus minimizing power for their specific operating delay requirement. 5 and 6 metal-2 pitch cells are used for this.

W. Complementary Complex Logic Cells for Low Voltage Operation

Low voltage power supply operation is aided by the use if C²L's true single phase clock flip-flops. The race-free logic timing within the flip-flops insure predictable timing behavior as voltage is lowered deep into the weak inversion mode of operation. This also cuts the internal and interconnect capacitance by more than 50% and increases the cell drive strength. This results in the ability to reliably operate at much lower voltage, which enjoys the advantage of the square law with voltage reduction of power.

X. Dual Rail Power Supply Cells in RFID Tag for Body Biasing

Dual rail power supplies are used to separate the CMOS sources from their wells and substrate connections. In this manner the CMOS device bodies are used to enhance the transistor's ability to turn ON and OFF better. This uses the body to provide additional channel control through “back gating.” To keep the cell layout compact, these two power rails are laid vertically on top of each other. The well/substrate power supply is routed in metal-1 through the top and bottom of the cell. The source or main power supplies are routed on top of the well/substrate power rails in metal-2. In this manner, all four of these power supply rails are at the extreme top and bottom of the logic cell. Here all power supplies are shared with adjacent cells on the top and bottom of the cell rows as is normal in integrated circuit layout. Since the metal-1 well/substrate rail does not carry any significant current, it is laid out with minimum metal width for long runs. This provides for the maximum use of metal-1 routing area within the cell for its construction. Sharing power rails with adjacent cells keeps the cell height to a minimum. An additional advantage in logic core area reduction is that the well/substrate ties are placed under the metal-1 rails only as they are needed to meet the design rule spacing and not in excess due to placing them in every cell. They are placed as needed after the core is routed as a final step in logic core layout. Here they are placed wherever there is design rule defined room. In this manner, these ties do not increase the area of the logic core.

Y. C²L Dynamic Logic Pre-Scalar Frequency Dividers

The logic operating around the oscillator and its frequency divide chain (prescalar) are the most significant power drain elements in the digital portion of the tag electronics. The interconnect wires that carry these higher frequency signals should be kept to a minimum. For this reason, very compact, power efficient cells are being disclosed which use Complex Complementary Logic structures (C²L). These power efficient cells, which are designed for ultra low power and size, are new, but they are based on C²L cell logic methodology, which is referenced to in the following U.S. patents: U.S. Pat. No. 6,198,324 Schober—Flip-Flops, U.S. Pat. No. 6,252,448 Schober—Coincident Complementary Clock generator for Logic Circuits, U.S. Pat. No. 6,297,668 Schober—Serial Device Compaction for Improving Integrated Circuit Layouts, and U.S. Pat. No. 6,333,656 Schober—Flip-Flops, which are incorporated by reference herein in their entirety. A switchable node in these cited patents is a logic function output to subsequent logic functions, inclusive of all the current path transistors that drive this output to either power or ground. The switchable node is a logic gate output inclusive of the entire transistor network, which switches it to either a logical ONE or ZERO. The switchable node's inputs are transistor gates and the switchable node's output is on at least one “strap” between the pull-up and pull-down active area regions. The switchable node includes the entire transistor source-drain connected network from the logic output connection “strap” back to the power supply and ground connections used in switching the logic output to either a power (logical ONE) or ground (logical ZERO) voltage. The functionality of a switchable node can normally be described by a Truth-Table, a Kamough-Map, or some similar logic means. A switchable node extent can be identified by following all of its output driving paths all the way from the switchable node output back to power and ground.

Note that these power efficient cells are true single phase clocked in that there in no inverted clock (no power consuming clock inverter) and all stages of the divider are controlled by the same clock input. In addition, the cells contain no more than two series devices, and most of the P-channel devices are single transistors. For these reasons, these power efficient (or logic) cells are very low power and well behaved at ultra-low voltages. Because they are very small, the interconnect does not have to go the long distances that would be incurred over normal larger cells.

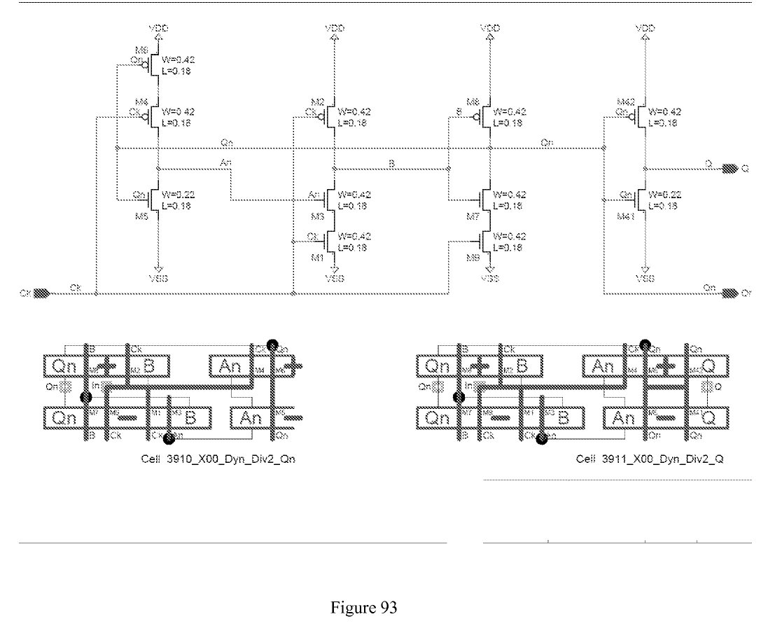

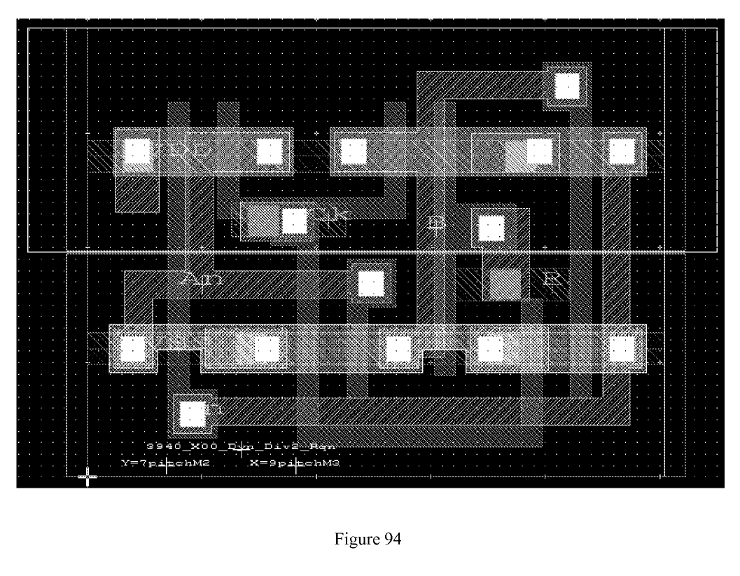

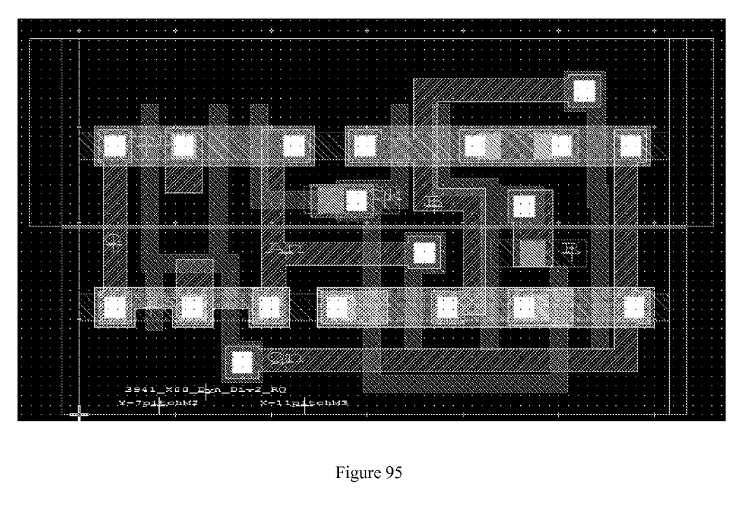

FIG. 93 illustrates schematics and stick diagrams of C²L Dynamic Divide by 2 (lower left stick), and an output buffer (lower right stick). FIG. 94 illustrates Layout of C²L Dynamic Divide by 2. FIG. 95 illustrates Layout of C²L Dynamic Divide by 2 including an output buffer.

FIG. 96 illustrates Voltage limiting performance, using normal threshold voltages, of C²L Dynamic Divide by 2 logic cell, such that a network of a circuit can operate at 800 mV or less and targeted at a 500 mV range with typical parameters and operating conditions. This operating voltage level is enabled by the parameter tracking current-fed ring oscillator circuit as discussed above. As parameters vary, the operating voltage of the current-fed ring oscillator compensates for the parameter variations since the logic voltage is derived from the operating voltage of the current-fed ring oscillator.

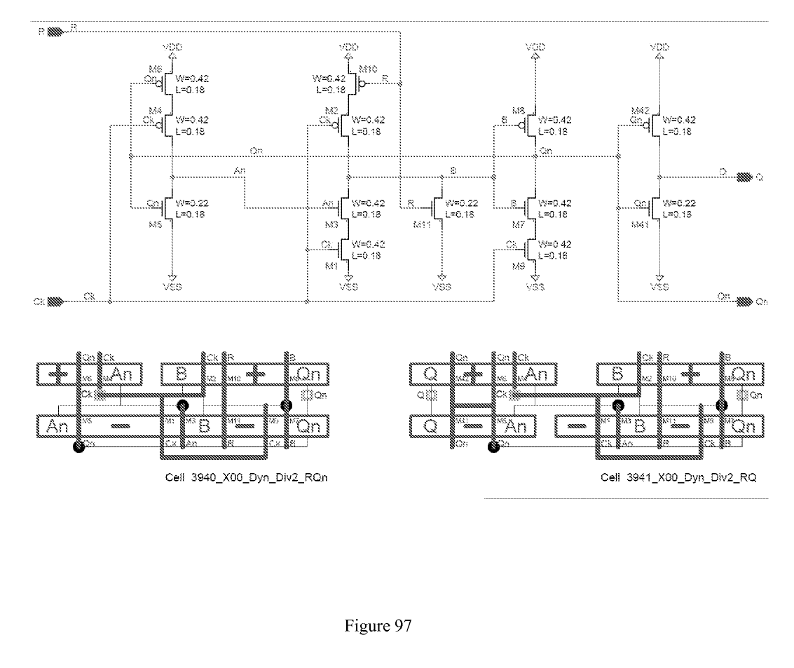

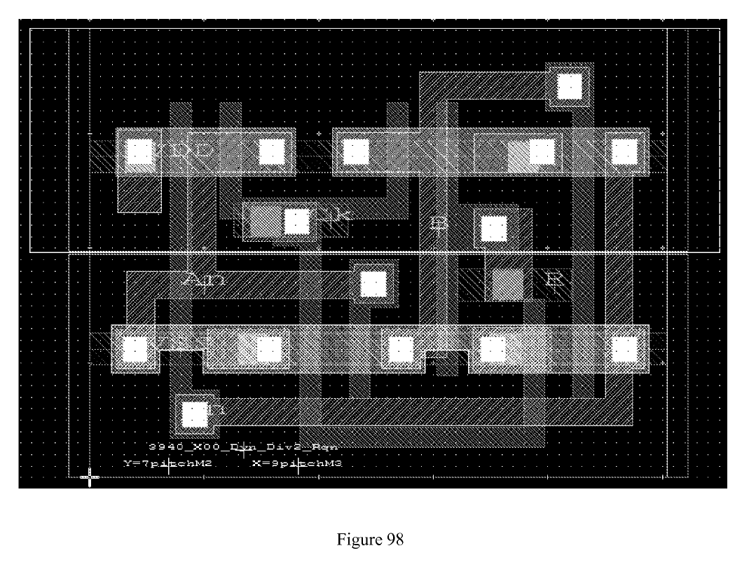

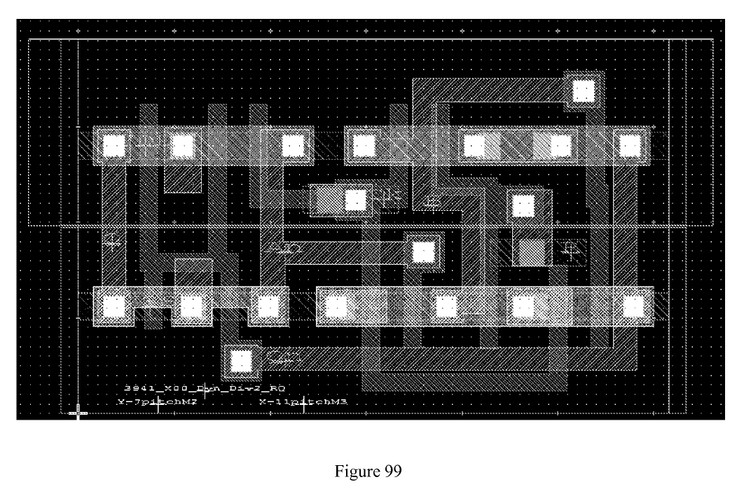

FIG. 97 is schematics and stick diagrams of C²L Dynamic Divide by 2 with static reset (lower left stick), and including an output buffer (lower right stick). FIG. 98 illustrates Layout of C²L Dynamic Divide by 2 with static reset. FIG. 99 illustrates Layout of C²L Dynamic Divide by 2 with static reset including an output buffer.

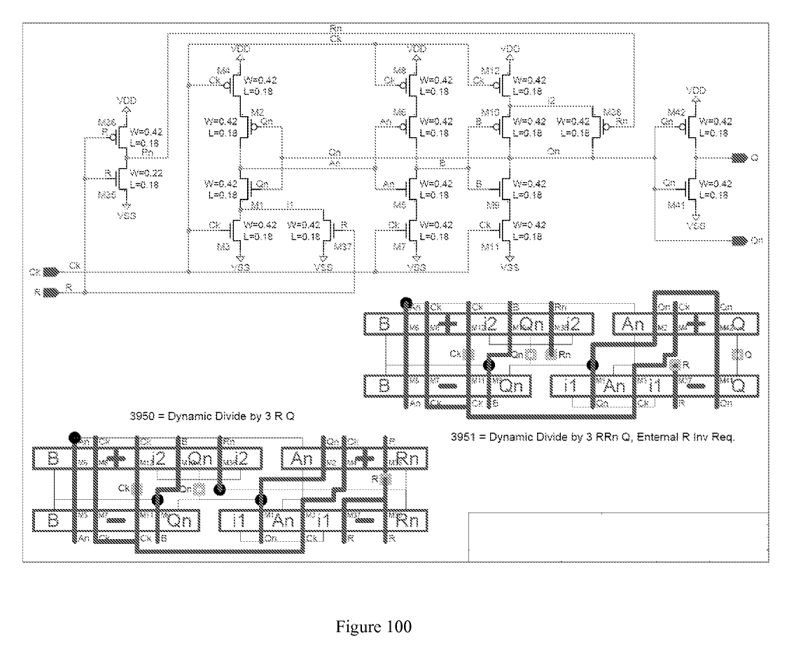

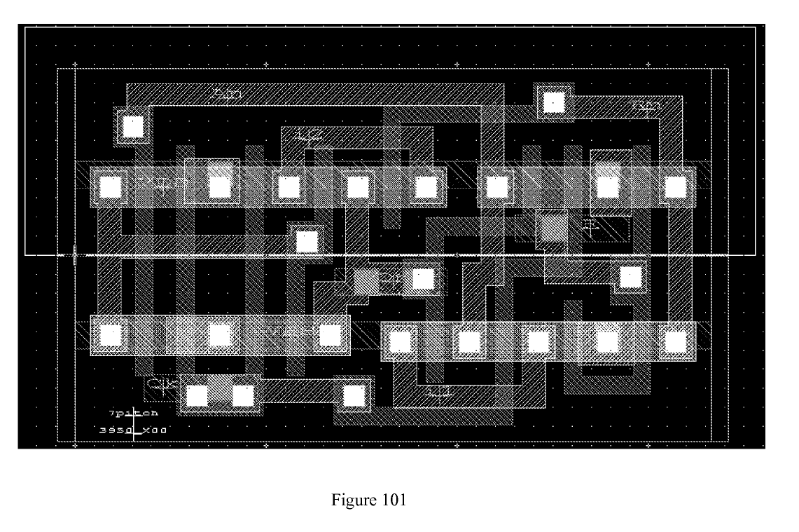

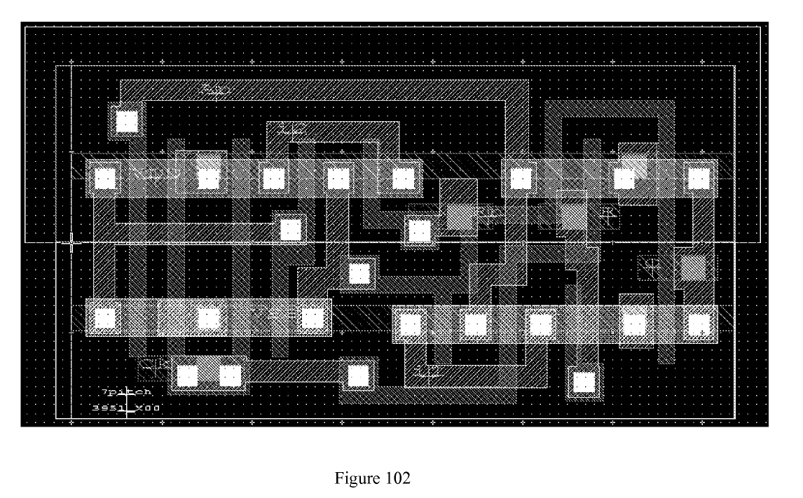

FIG. 100 is schematics and stick diagrams of C²L Dynamic Divide by 3 with static reset (lower left stick), and including an output buffer (center right stick). FIG. 101 illustrates Layout of C²L Dynamic Divide by 3 with static reset. FIG. 102 illustrates Layout of C²L Dynamic Divide by 3 with static reset including an output buffer.

FIG. 103 illustrates Voltage limiting performance, using normal threshold voltages, of C²L Dynamic Divide by 3 logic cell, such that a network of a circuit can operate at 800 mV or less and targeted at a 500 mV range with typical parameters and operating conditions. This operating voltage is enabled by the parameter tracking current-fed ring oscillator circuit as discussed above. As parameters vary, the operating voltage of the current-fed ring oscillator compensates for the parameter variations since the logic voltage is derived from the operating voltage of the current-fed ring oscillator.

Z. Logic Design Example

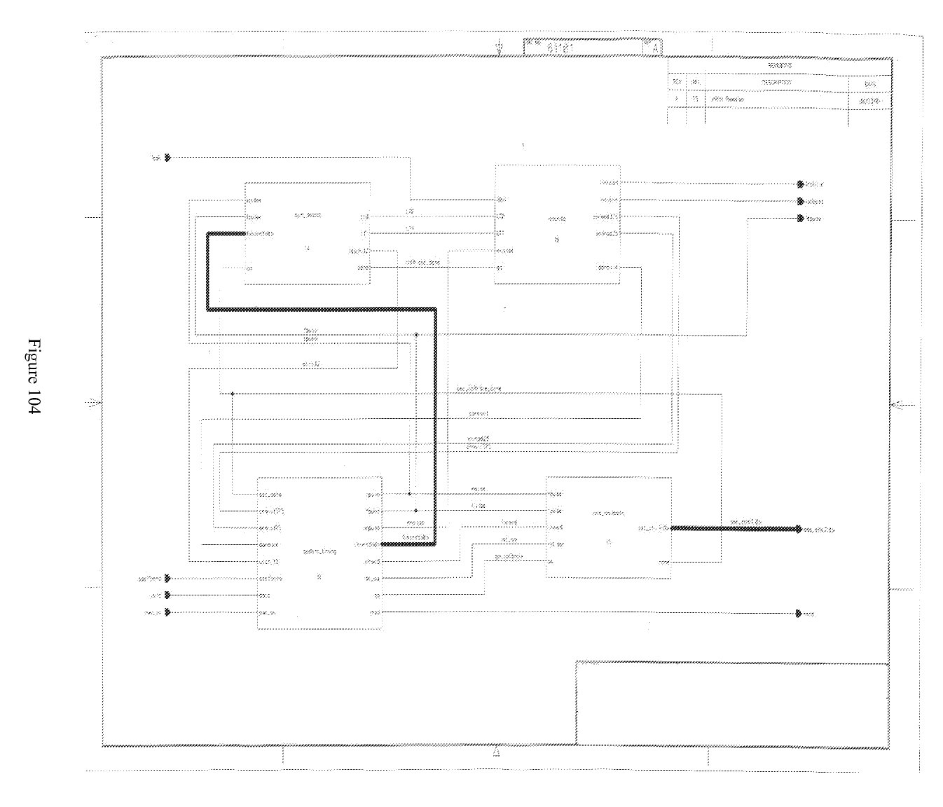

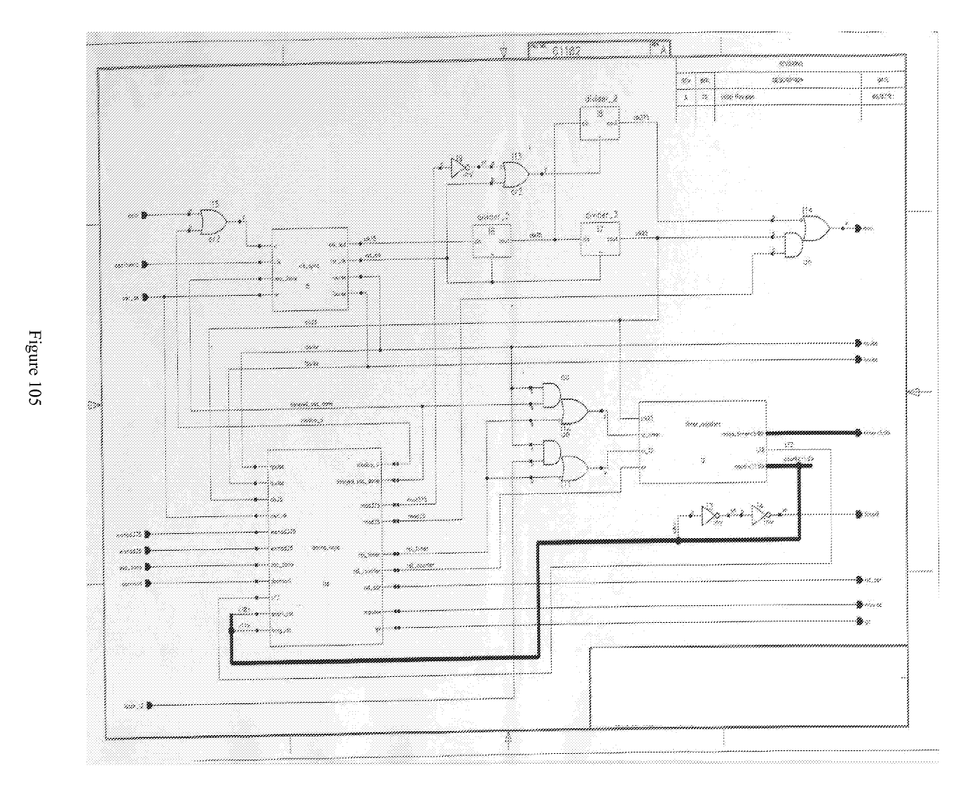

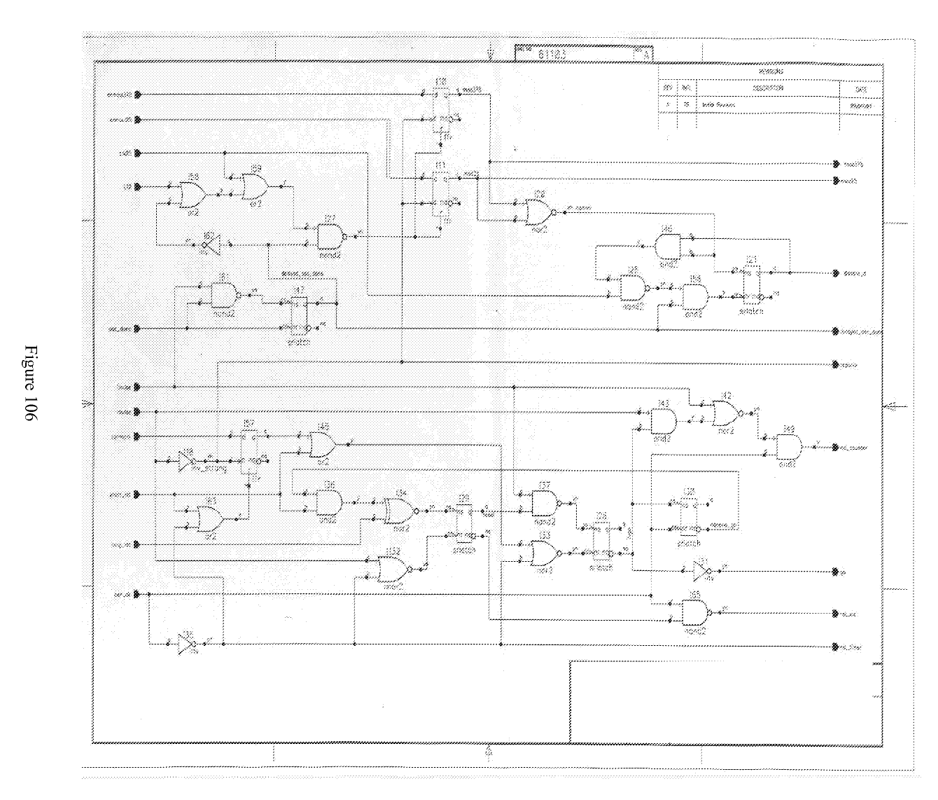

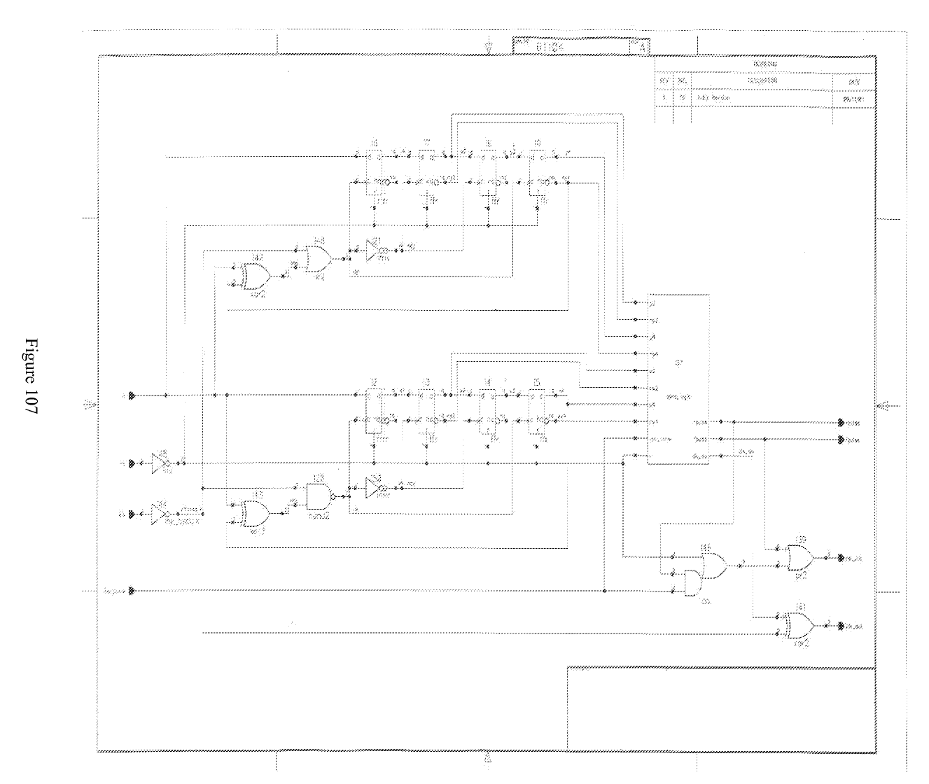

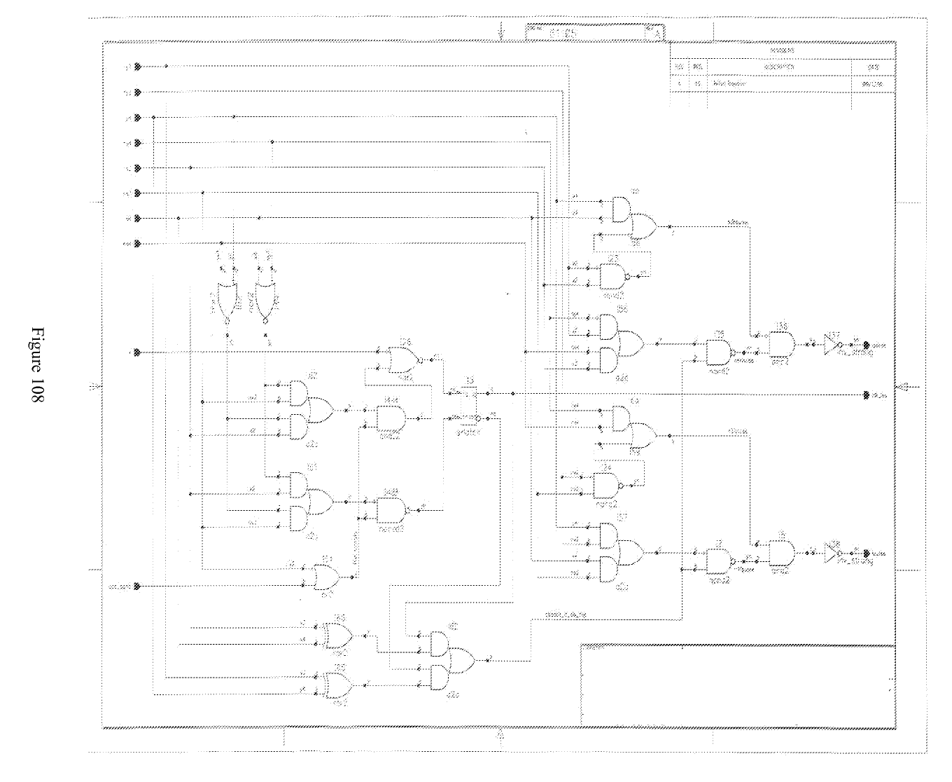

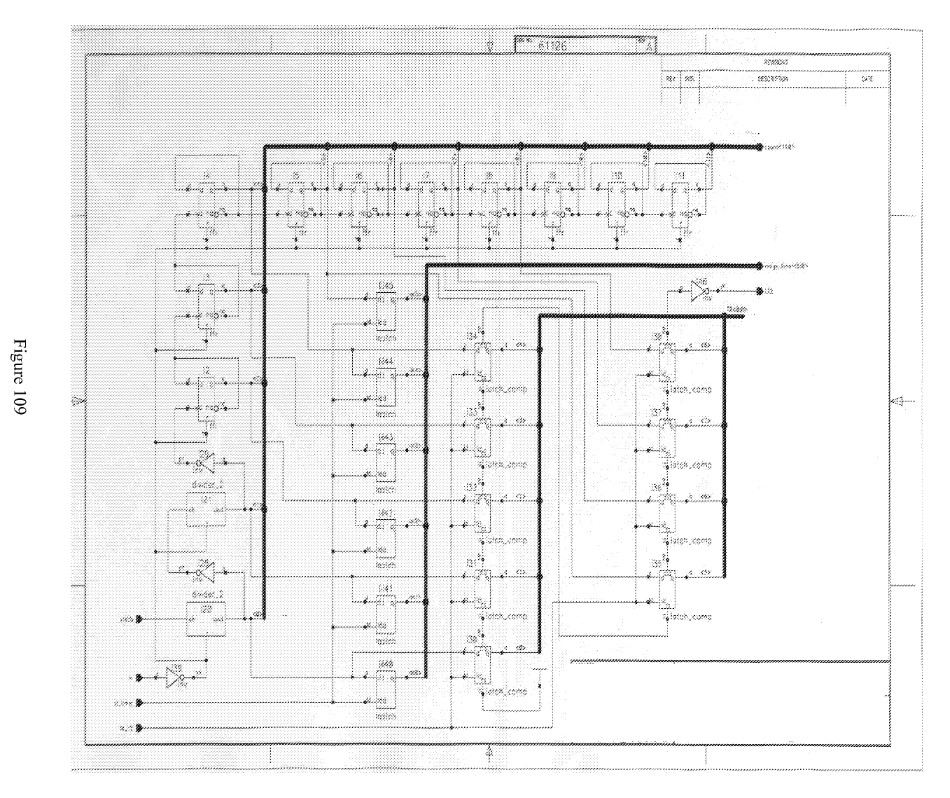

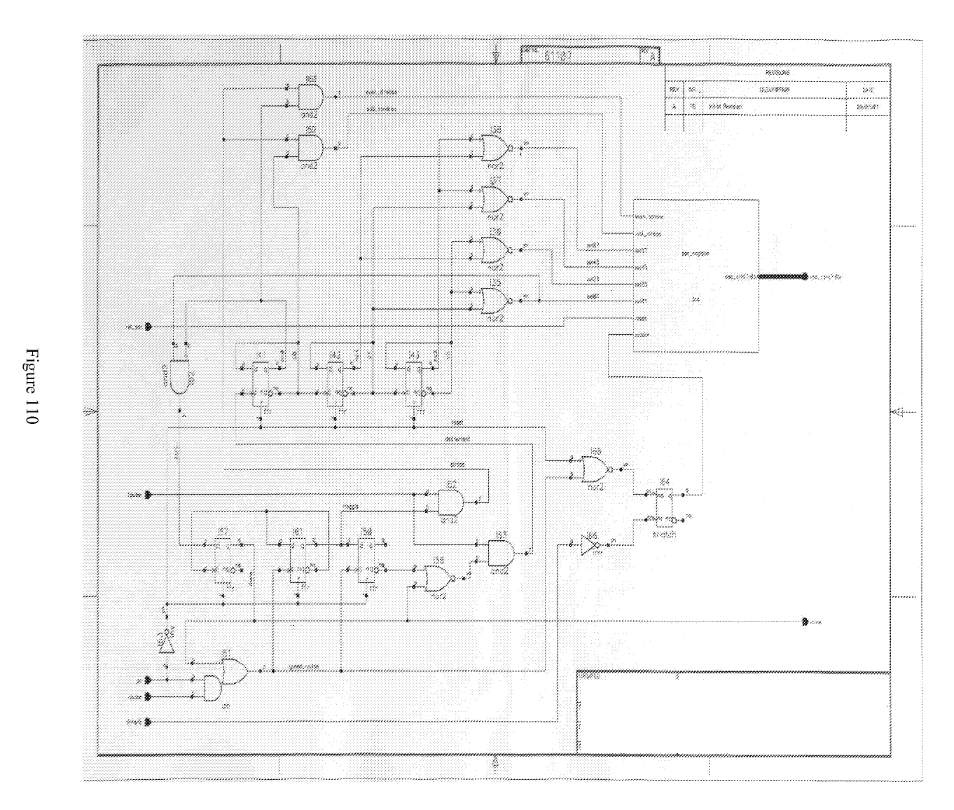

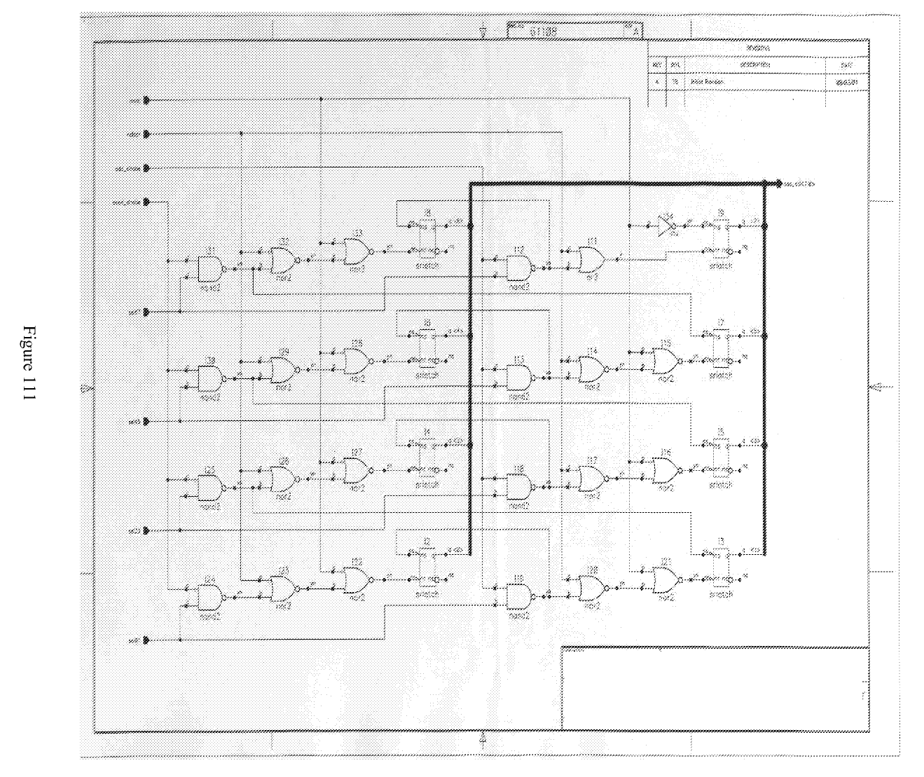

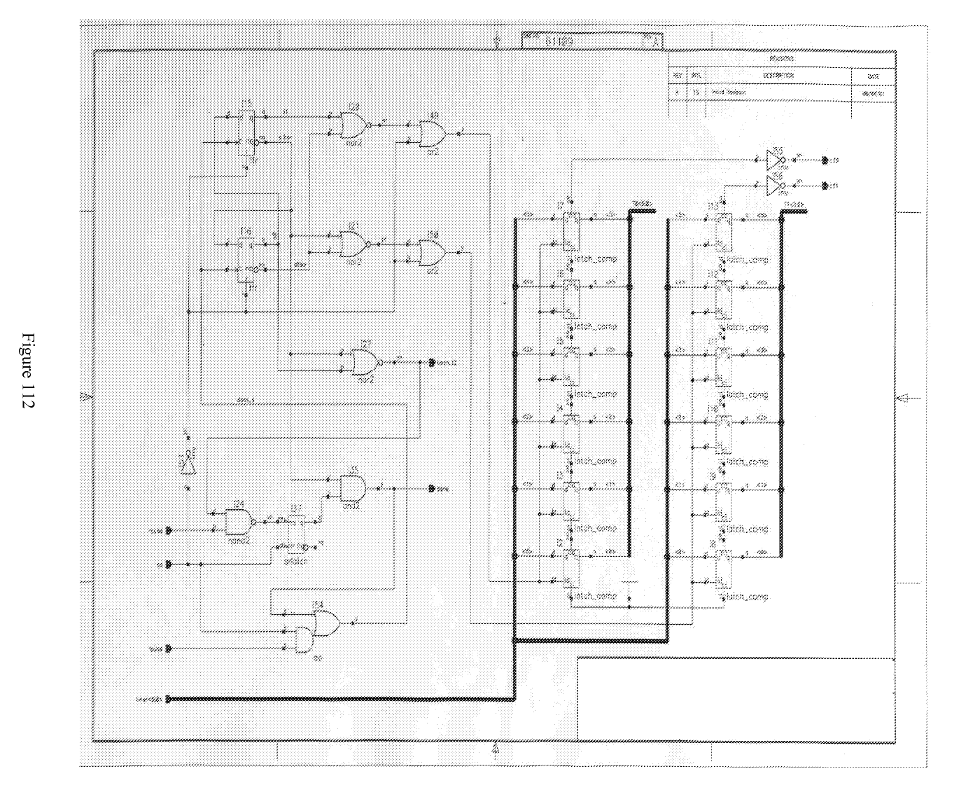

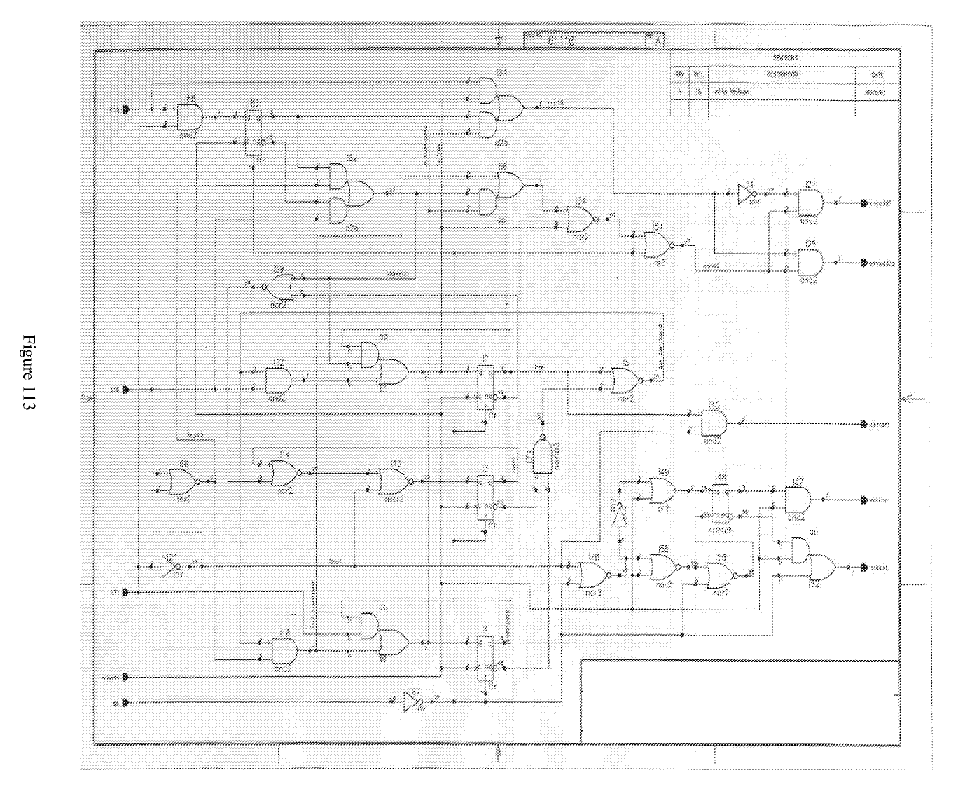

FIG. 104 is a Top Level block diagram of a RFID tag Digital Controller. FIG. 105 is a System Timing Control schematic of a RFID tag Digital Controller. FIG. 106 is a System Timing logic schematic of a RFID tag Digital Controller. FIG. 107 is a Clock to Data Synchronizer logic diagram of a RFID tag Digital Controller. FIG. 108 is a Clock Synchronizer logic diagram of a RFID tag Digital Controller. FIG. 109 is a Timer Counter Register logic diagram of a RFID tag Digital Controller. FIG. 110 is an Oscillator Calibration logic diagram of a RFID tag Digital Controller. FIG. 111 is an Oscillator Calibration Register logic diagram of a RFID tag Digital Controller. FIG. 112 is a DownLink Symbol Detector logic diagram of a RFID tag Digital Controller. FIG. 113 is a Command Operation logic diagram of a RFID tag Digital Controller.

AA. Minimizing Tag Cost

To keep the RFID tag cost at a minimum, there can be no external parts to the chip other than a conductive pattern printed on the mounting surface for the tag's antenna, possibly configured with an associated UHF network printed as part of the antenna design. In order to eliminate the normal external energy storage capacitor, all aspects of the circuit and system design are for ultra low power. Numerous creative approaches have been implemented to achieve the ultra low power operation. When this ultra low operating power design is combined with an innovative means of integrating sufficient capacitance on chip, not only is the battery eliminated, but the normal off-chip energy storage capacitor is also eliminated. This reduces the chip input/output pad requirements to include the antenna only. This facilitates the use of a unique pattern for the chip pads where only the antenna is present and the antenna pads are placed on diagonally opposing corners of the chip. If one antenna is used, it connects to divergent corners of the chip, and if the integrated circuit chip design utilizes two antennas for omni-directional operation, the second antenna is connected the other two divergent corner pads. This makes the RFID chip to have nothing more than one or two antennas attached to it, not even a power storage capacitor. There are no other connections. This enables a unique quality of being able to be mounted in any of its four rotational orientations and operate in an identical manner. This provision in the circuit design greatly simplifies the chip to antenna assembly procedure to help facilitate the lowest RFID tag cost.

BB. Orientation Independent Chip to Antenna Mounting

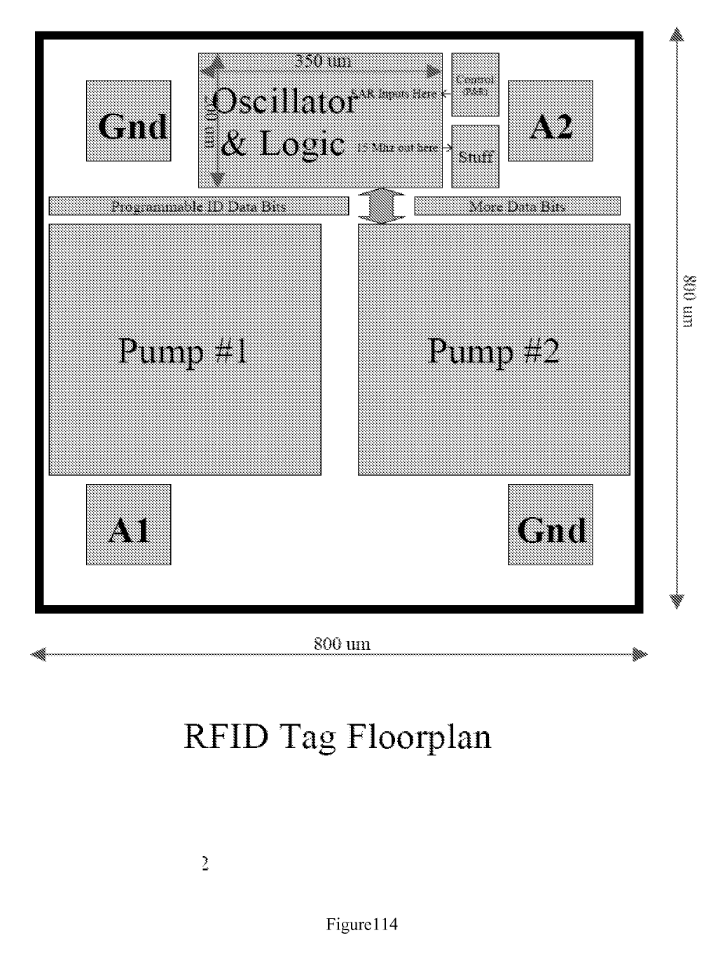

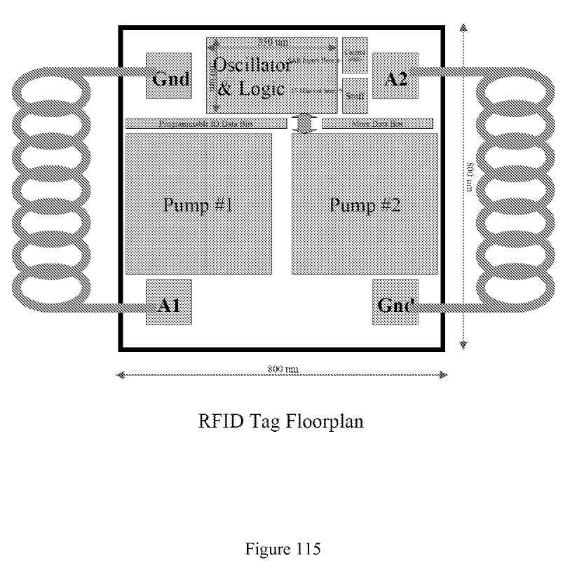

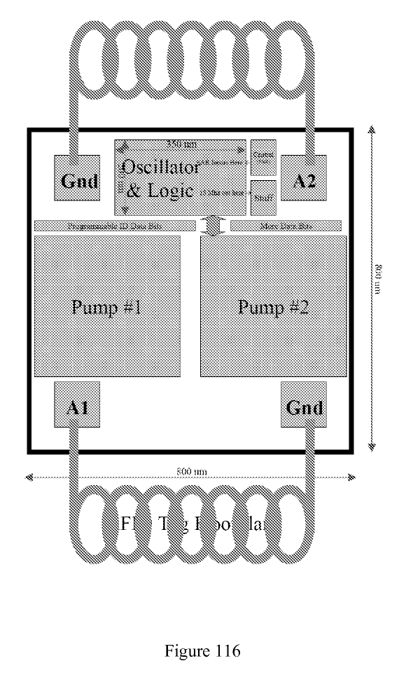

Referring to FIG. 114, special-purpose integrated electronic circuit techniques are disclosed and shown that enable low cost, very high sensitivity RFID Tag operation powered only by the RF field imposed on its antenna. Combinations of these design considerations enable high sensitivity, while at the same time minimizing cost by integration of all external parts including antenna matching, energy storage components such as external capacitors, printed batteries, and other components. The result is that only a tiny integrated circuit chip is required. This chip is inexpensively flip-chip mounted or capacitively coupled to a conductive printed pattern on Mylar, PET, paper, or another suitable smooth surface which does not absorb moisture. A conductive printed pattern on the RFID tag inlay serves as the antenna. Since only the antenna connections are used, the chip bonding pads are symmetrically positioned for mounting in any rotational orientation, thus facilitating low cost automated assembly where all of the possible rotational positions are functionally identical. In addition, with the ultra small square die dimensions, the RFID integrated circuit chip can be cut apart from the integrated circuit wafer by an etching process resulting in minimum loss of silicon wafer area. Since the integrated circuit die is small, while the “streets” between these die normally consume a significant portion of the wafer area that is wasted. For contact connection, the “flip-chip” connections align the die bonding pads to the bonding pattern on the inlay printed antenna-mounting pattern. For the capacitive coupling connection mounting configuration, the metalized areas on the chip are placed in close proximity to mating metallic areas of the antenna connecting points to capacitively couple energy through the capacitive divider formed by taking this capacitance into account in the RF antenna circuit. This enables the lowest cost fabrication at some cost in performance. The capacitive coupling method is intended for inclusion of the chip in credit cards and other similar relatively close proximity RFID tag reading applications. Since the antenna to integrated circuit bonding pads are located on diagonally opposing corners, any one of the possible chip orientations are equivalent. For a single antenna, there are two possible orientations, and for two antennas, there are four possible orientations. Four bonding pads may be used to achieve the all four possible orientation mounting. There are two options at making the coil hookup independent of chip placement orientation. In the example cases of FIGS. 115 and 116, the charge pumps are cross connected with the coils (not crossed over). The other case is to cross the antennas over each other and not the charge pumps. The better case is to not incur antenna crossover because this would cause a two layer antenna pattern. The integrated circuit already of multiple layer ready.

CC Single Antenna Floor Plan

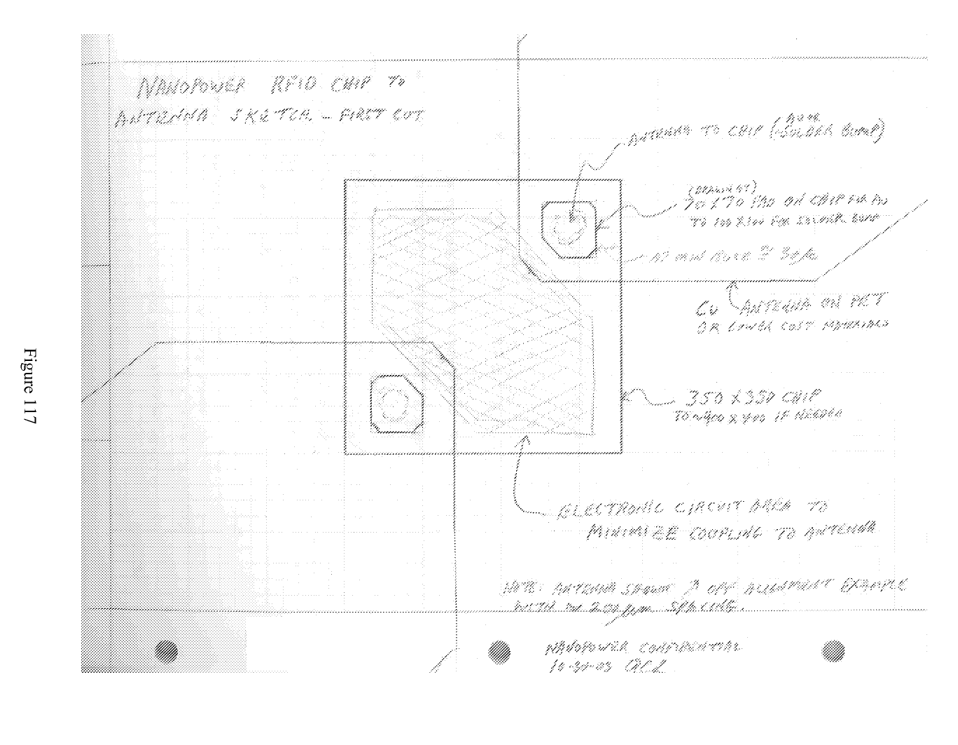

FIG. 117 illustrates Top level chip floorplan for single antenna minimal die size RFID chip.

DD. Single Antenna Pad to Inlay Interface

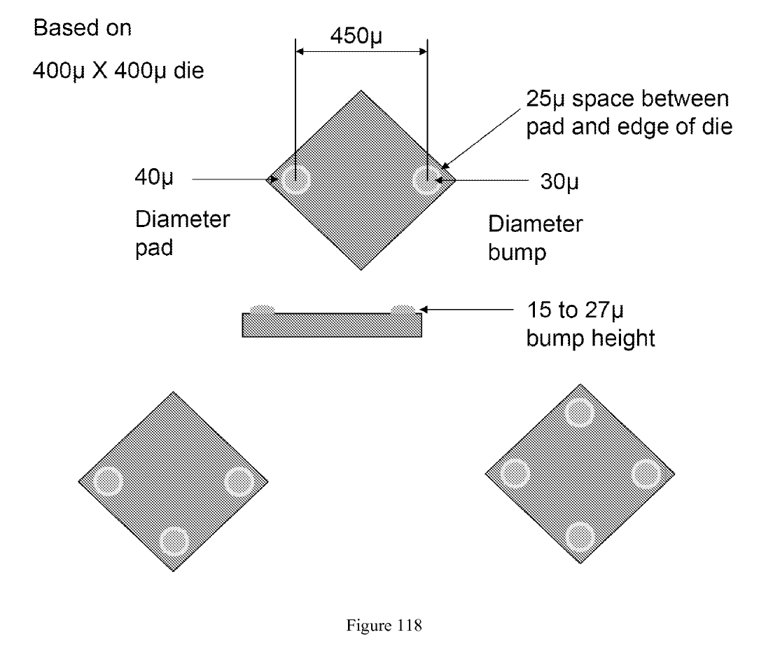

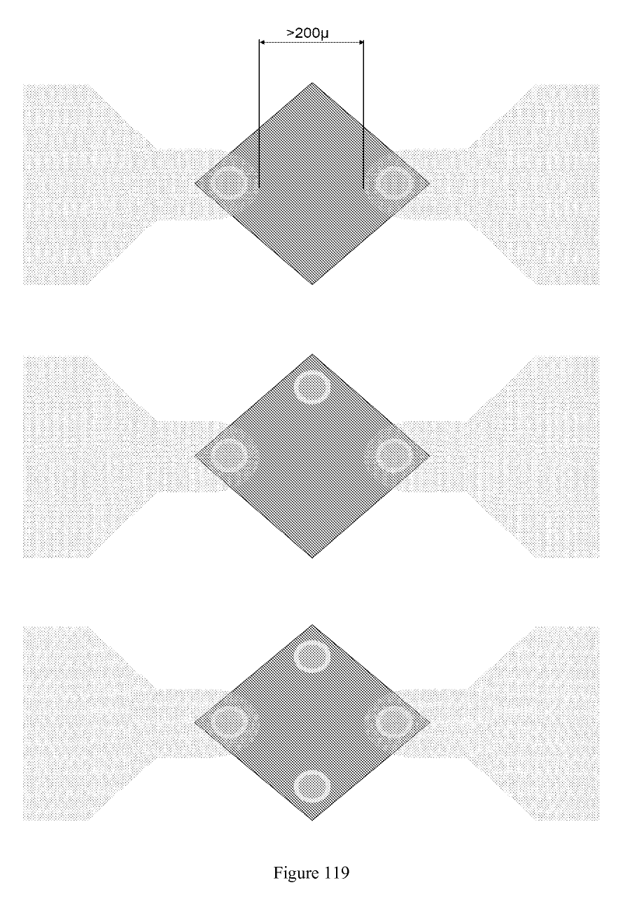

FIG. 118 is an Example drawing for small die size mounting configurations. In FIG. 118, these configurations have example dimensions relative to a minimal die size for 2, 3 and 4 pads. FIG. 119 is a single antenna chip mount to RFID tag inlay for 2, 3 and 4 pads. In FIG. 119, 2 pad inlay is most efficient on the chip, 3 pad inlay is for mechanical stability, and 4 pad inlay is strongest and orientation insensitive, but uses chip area.

EE. Battery Assisted RFID Tags

Battery Assisted RFID tags primarily get its energy form the Interrogator RF field in a similar manner to Passive RFID tag power extraction. The battery assisted RFID tag uses an ultra low capacity battery to assist RFID tag start the main tag power supply when the interrogator RF field is present. This mini-battery supplies bias voltage that is used to bias an active rectifier or charge pump, which in turn efficiently rectifies or multiplies the RF input voltage to power RFID tag integrated circuit operation. This mini-battery may also be used to retain memory data such as serial number. The key characteristic of the circuit is that it only draws leakage current to bias or keep-alive the circuit. The leakage current can be reduced by the use of bandgap self-cascode (BgSCFET) transistor structures disclosed above.

FF. Ad-Hock Connected Active RFID Tags

Active RFID tags are defined as battery powered tags as opposed to Battery Assisted RFID tags that primarily get their integrated circuit power form the Interrogator RF field by a means similar to Passive RFID tags. The Active RFID tags use a small battery to power the RFID tag integrated circuit. These active RFID tags use the battery to actively transmit back to the reader. Their applications, for example, would be for shipping containers and larger high value items.

The current active RFID tags only communicate with the reader, and not other tags. This disclosure extends the active tag communication to other tags as well as the reader. In communication with other tags, the range is amended through hopping in an ad-hock network of tags in a manner similar to the internet node hopping to achieve a communication route. Initially, this ad-hock tag system will respond with the information that the tagged item is within the communication area. The tag location for item can then be pinpointed by several methods which could include a beacon, a buzzer, a light, or identification through reporting the ad-hock path used. Known transmitter and item locations can be used by listing the path to them. The serial numbers of the near neighbors can be read back to define a known region. This can include a network of fixed nodes or identifiable pallets. Ultimately, the active tag should contain the flexibility to enable the inclusion of useful schemes. Encryption is an example of flexibility. The tag might include a rotting encryption key or some other means of protecting from intruders. At the least, there needs to be the ability to limit those that program or alter the tag memory contents.

The networked active tag can operate as a normal active tag communication in a standard active tag protocol in the 400 MHz band, an ad-hock network to communicate with other similar tags, or just modulate the antenna impedance to work with a passive RFID tag reader. For the networking, the tag has power conservation modes. It can be woken up by a passive tag interface.

GG. Sensor Inclusion in Active and Passive RFID Tags

Incorporating sensors into Passive RFID tags is not straightforward. The entire sensor circuit should operate on a very little amount of power. Its power absorption limit is about 1 microwatt at low voltage. The practical limit is about 10 microwatts at low voltage or in the order of 10 milliwatts for active tags. This should include the entire sensor circuit with the calibration, digitizer, readout, and power conditioning circuits. The ultimate tag readout is performed as a memory location read. In passive tags, the sensor is only active when the tag is powered through the interrogator RF field. In active tags, there is a lower power level for maintaining the tag measurement and memory status, as well as a higher power level for readout. Some of the passive sensors that can be included include temperature, pressure, light, humidity chemical, and radioactivity. Some of the additional sensors that can be included on active tags are acceleration including vibration, shock as derived from an accelerometer; and orientation as well as rotation or orientation as derived from a micro gyro. The measurements can be either single ended or differential, which is normally achieved with pairs of sensors. Consistent with low RFID tag costs, the sensors are moderate to low accuracy in most cases. In order to operate these sensors with ultra low power and voltage, and still have the capability of digitizing their output, differential sensors are employed. Here two nearly identical sensors are run in parallel. Their difference id designed in to be sensitive to the parameter being measured. These sensors are used to feed a current into identical oscillators. The oscillators run counters up. The first counter stops the count, and the difference is the digital word out. Calibration memory words are read from the tag and used to calculate out the errors. For higher accuracy measurements, temperature effects should be designed out with Proportional To Absolute Temperature (PTAT) circuits, or an additional temperature measurement may be made either on or off the tag.

Recap of Key Definitive Technologies for Improved RFID Tags

1. Ultra low power C2L RFID tag integrated circuit electronics using a total of 1 microwatt for the RFID tag. Typically circuits consume about 60 microwatts or more for RFID tag electronics. This is the power consumed by the RFID tag electronics only. This 60 to 1 advantage in the power needed to be extracted from the RF field flooding the RFID tag antenna and be pumped up to operating power supply voltage with a significant inefficiency. This reduces the RF field extracted power requirements for the RFID tag integrated circuit. The C2L logic cells are 5 or 6 metal-2 pitch high and use minimal area for ultra low parasitics. The C2L also uses true-single-phase and coincident clocking techniques described in reference patents on Flip-Flops. This enables well behaved low voltage operation.

2. RFID tag use of all ultra-low-threshold voltage devices for logic. This allows the logic to be operated at a few tenths of a volt thus gaining a voltage-squared advantage on power to more than overcome the OFF state leakage current with these transistors.

3. RFID tag use of near zero-threshold or native transistors that operate at near zero volts or in the couple of tens of millivolt range (about 22 millivolts for 50 microwatts on the antenna). These transistors are used in a charge pump circuit enabling it to operate at a much lower signal from the RFID tag antenna. Previous technology uses Schottky diodes to operate the charge pump at the tenths of a volt range. This is about an advantage of about 500 to one in RFID tag sensitivity, and I do not think any circuit can operate in the 8 meter distance range without it. Anybody claiming this 8 meter range will probably be violating the patents we have in process. This is the means of providing an extremely low startup voltage for the RFID tag integrated circuit electronics.

4. RFID tag use of an integrated Inductor for a resonant circuit into the charge pump. This precedes the first zero-threshold transistor by a linear circuit that provides a gain into the non-linear rectifying first zero-threshold transistor. This produces about an advantage of about 5 to one for a circuit Q of 5 which is included in the native threshold advantage above. This aids the extremely low RFID tag startup electronics.

5. Ultra-low-power oscillator, which is power supply independent and calibrated through the received RFID tag wake-up signals.

6. On board energy storage and management to enable the RFID tag to maintain its state during frequency hopping with long read range or low antenna energy levels. No additional components are used. This provides a totally symmetric bonding pattern where the RFID tag integrated circuit chip can be placed on any of its 4 possible rotational orientations and work identically. This, along with an ultra small die size due to C2L, makes it the lowest cost and highest manufacturability RFID tag.

7. Non-Volatile electronic RFID tag memory that uses single poly standard CMOS logic processes with no optional integrated circuit processing. This memory is programmed with a RFID tag reader/writer.

Several different memory technologies may be used with different advantages such as write once, write once with extensions for modified words, UV erasable, low voltage approaches, small size of entire memory block, large capacity (2 to 4 Kbits class), write a few times (perhaps like 7 to 20 times).

8. Memory Redundancy with error correction, differential cells,

9. RFID tag use of Grey-Code counter logic techniques for minimal power supply ripple.

Minimizing coincident logic transitions with Grey code type of counter and associated state logic design methodologies spreads out the peak current demand so that the power supply can best handle the logic current spike demands.

10. RFID tag use of Self-Timed or Clockless logic. This will allow for the lowest power supply voltage operation of the logic core thus reducing power and the requirements placed on the input charge pump circuit. This may be taken to the extreme where only a rectifier needs to be used at the antenna input to the RFID tag electronic chip.

11. RFID tag use of only an “ideal” rectifier at the input to derive chip power. This rectifier may be started with native ˜0 threshold MOS devices.

12. Turn OFF the input native devices when there is enough rectified voltage to do so thus increasing the charge pump efficiency after it is started.

13. RFID tag use of all very low threshold voltage MOS transistors for the entire RFID tag. This can provide minimal power because there is not any voltage to drive the leakage current.

14. Current mode logic may be used with ultra low or possibly zero threshold MOS transistors. This is to enable operation at the lowest voltage. The idea being that the currents are so low that they are lower than currents needed to drive voltage mode logic and its leakage at low power supply voltages.

There are numerous additional considerations that are in the patent process which define superior RFID tag electronics described in this disclosure, but these are some significant considerations.

The most major protocols at this time are the IOS16000-6 UHF RFID tag protocol, and EPCglobal gen2 specification (Chicago Standard). This disclosure considers implementation in these standards in particular as well as others.

List of Inventive Features

1. Low cost RFID Tag.

2. Ultra High sensitivity passive RFID tag.

3. Fast RFID tag reading protocol enhancements.

4. Ultra low power laser link read electronics.

5. Voltage multiplier means of powering RFID Tag from antenna.

6. Use of ultra low voltage RFID tag circuit operation to enable simple voltage multipliers or just a rectifier at the antenna input.

7. Use of an active rectifier at the antenna input to supply the RFID tag chip power.

8. Two stage power-up which uses an inefficient ultra low voltage multiplier to generate bias voltage supply for a more efficient main voltage multiplier or active rectifier.

9. Use of zero threshold transistors to operate voltage multiplier from ultra low input voltage levels.

10. Essentially Zero-Volt forward drop Active Rectifier.

11. Micro-volt level startup AC to DC Rectifier.

12. Use of an ultra small secondary voltage multiplier to provide bias and other startup aids in order to enhance minimum startup voltage sensitivity.

13. Graduated effective threshold voltage multiplier startup methodology.

14. Use of On-Chip coil resonant circuit to increase rectifier circuit voltage and reduce pad and modulator parasitics on RFID Tag.

15. Means of reflecting excess input energy back out antenna to protect against signal overloading.

16. Means of combining two antennas and charge pumps with minimum parasitics and circuit elements.

17. External parts-free RFID tag integrated circuit.

18. Symmetric bonding pads that enable any of the fro orientations to operate identically.

19. Patterned eddy minimizing patterns to increase coil Quality factor and provide for additional capacitive energy storage.

20. High Quality factor RFID coil design.

21. Use of MEMS for increasing RFID tag coil Quality factor.

22. Staged startup signals to enhance RFID tag sensitivity.

23. Current-fed ring oscillator for RFID tag.

24. Ring Oscillator made from circuit elements similar to logic circuitry for predicting the speed of the logic circuitry.

25. Derivation of regulated logic power supply from ring oscillator operating voltage.

26. Logic power up signal derived from slightly more voltage than ring oscillator's operating voltage.

27. Two stage calibration for RFID tag oscillator frequency with overlapping monotonic range in order to use low accuracy calibration elements.

28. Oscillator output phase selection and prescalar reset as a means of synchronizing multiple RFID tags.

29. Resettable ultra low power C2L divide by two and divide by three with symmetric output duty cycles.

30. Fully integrated RFID tag reader.

31. Variable output RFID tag reader control and a resulting means of triangulation and ranging for the localization and location of RFID tags.

32. Automated market research from RFID tagged item handling.

33. Fast read product code.

34. Follow-on data bits to indicate further information in RFID tag read-back information.

35. Partial set of bits set in the integrated circuit mask set top layers to reduce the number of bits that have to be programmed.

36. Combination of flash memory RFID tag information bits to allow flexibility.

37. Low power and voltage flash memory for RFID tags.

38. Flash EEPROM Memory for RFID tags using single-poly standard CMOS Logic process.

39. Write once EPROM that uses residual antenna rule voltage to provide the unprogrammed bit 0 state, thus only having to write ones.

40. Extendable EPROM memory to provide for a limited number of modified words.

41. Current mode operation of RFID memory cell, addressing, sensing, and/of control logic to allow for extremely low operating voltage.

42. Use of latched memory output storage to buffer memory read into the logic of RFID tags. This provides reliable low voltage operation.

43. Area efficient Flash EEPROM and EPROM cells and addressing for small memories.

44. Serial number and data encryption for RFID tags.

45. Frequency Shift Keying (FSK. methodology for long read range and fast tag communication in high RFID tag populations.

46. Minimum Power Mode during inter-frequency carrier-off time interval to minimize stored energy loss while Frequency Hopping—including RFID tag sensing and clock control.

47. Staged RFID tag wake-up during power up. Light rectifier/charge pump first which operates at the lowest input voltage swing to bias the more efficient main rectifier/charge pump.

48. Self timed logic—Clockless RFID tag state machine.

49. Ultra-low voltage logic circuit operation (around 200 millivolts for example. to take advantage of voltage squared advantage in power at the lesser expense of increased leakage current that is a result of ultra-low threshold voltages.

50. Gated oscillator—which is enabled only when there is detector logic activity at the decoder—to reduce load on the chip power supply so that more energy can be stored with a low RF level input.

51. Multiple threshold level condition logic signals from the power supply to signify—start, hold, transmit, power OK.

52. Ultra-low voltage memory retention latch—differential design carefully matched.

53. MOS Electrically Programmable Memory that is initially in the zero state (or unset state. due to the antenna rule charge absorption of semiconductor processing.

54. Ultra-low power RFID tag sensor readout techniques where the digitizing is accomplished by means of binary mismatch of multiple sensor elements.

55. Ultra-low power RFID tag sensors where the sensor signal is created by a calibrated mismatch between two nearly identical sensors.

56. Active rectifier antenna power conversion to DC supply.

57. Biasing startup circuit with voltage using a small battery to enable high efficiency low voltage startup.

58. Native transistors to sense memory cell's programmed state.

59. Staged memory where native devices initialize a latch and then the data powered to a higher voltage circuit and the native latch powered down.

60. Native or ultra-low threshold device latches that hold data down to near zero volts.

61. Use of an on-chip power supply voltage or current regulator for a RFID tag.

62. Rotating critical P-Channel devices by 45 degrees to take advantage of the different crystal structure orientation.

63. Use of write-once memory to construct RFID memory.

64. Writing all bits to erase write-once memory.

65. Referencing another pre-described location in RFID tag memory for erased locations.

66. Antenna on chip for close field coupled signal coupling to reader.

67. SOI implementation where the coil Q is high.

68. Thin flexible chip where the circuit has been thinned to the point of flexing on such processes as SOI with the silicon below the buried layer lapped away.

69. Special shaped die such as diamond shape or rounded corners as afforded by an etching processes to cut the die apart.

70. Rounded or full octangular bonding pads to lower the antenna connection parasitics.

71. Physically setting the low field of serial numbers at the mask or stepper level.

72. Use of true-single-phase clock flip-flops & latching cells enables low voltage operation.

73. Use of all very low threshold voltage (Vth. devices with leaky OFF state.

74. UV erasable EPROM for RFID tag memory.

75. RFID application of body or well-snatcher methods.

76. Passive RFID tag used as a wakeup circuit for turning on power to a larger circuit.

77. Combined active, ad-hock networked, and passive tag.

78. BgSCFET devices and their structures.

79. Use of BgSCFET devices to increase output resistance.

80. Use of BgSCFET devices to enhance gain.

81. Use of BgSCFET devices in weak inversion.

82. Use of BgSCFET devices to reduce OFF-state leakage current.

83. Use of BgSCFET devices to control and decrease ON-state resistance.

84. Use of BgSCFET devices series connection to generate a bandgap reference.

85. Use of native near-zero threshold voltage transistors in a BgSCFET.

In view of the foregoing, a method and apparatus for an ultra-high sensitivity, low cost, passive (no battery) low-power energy harvesting data transmitting circuit energy, such as a RFID (Radio Frequency IDentification) tag integrated circuit “chip,” is disclosed. By using combinations of special purpose design enhancements, the low-power energy harvesting passive data transmitting circuit, such as the RFID tag chip, operates in the sub-microwatt power range. The chip power should be derived from a low-microwatt per square centimeter RF field radiated to the RFID tag antenna from the tag reader (interrogator) or derived from any other suitable low-level signal source, such as a sonic transducer (e.g., a piezoelectric transducer or a low level DC source, such as a bimetallic or chemical source, e.g., a living organic low level energy source). This enables the circuit or tag's operation at a long distance from the RFID tag reader or the signal source under ideal line of sight conditions. For example, ultra high RFID tag sensitivity translates to the ability of reading tags reliably in real-world conditions, where the RF field varies over a wide range and is often absorbed by the environment to near-zero levels. Consistently reliable tag interrogation is the primary qualifier of acceptable RFID tags. Not missing tagged items in the field of the reader, but out of visual sight, is the primary enticement of RFID. The present invention cover a set of related complimentary embodiments that enable ultra-high sensitive RFID tag fabrication.

While the invention has been described in connection with certain exemplary embodiments, it is to be understood by those skilled in the art that the invention is not limited to the disclosed embodiments, but, on the contrary, is intended to cover various modifications included within the spirit and scope of the appended claims and equivalents thereof.

What is claimed is:

1. A charge pump circuit comprising:
a first diode-connected transistor having a first electrode connected with a first power source and a second electrode connected with a first node;
a first capacitor connected between the first node and a second power source;
a second diode-connected transistor having a first electrode connected with the first node and a second electrode connected with a second node; and
a second capacitor connected between the second node and the first power source,
wherein at least one of the first and second diode-connected transistors has a substantially zero threshold voltage.

2. The charge pump circuit of claim 1, further comprising:
a third diode-connected transistor having a first electrode connected with the second node and a second electrode connected with a third node;
a third capacitor connected between the third node and the second power source;
a fourth diode-connected transistor having a first electrode connected with the third node and a second electrode connected with a fourth node; and
a fourth capacitor connected between the fourth node and the first power source.

3. The charge pump circuit of claim 2, wherein the first, second, third, and fourth diode-connected transistors have respective channel lengths adjusted according to their respective maximum hold off voltages.

4. The charge pump circuit of claim 1, wherein at least one of the first and second diode-connected transistors has a body electrode electrically coupled to the first power source or the second node.

5. The charge pump circuit of claim 4, wherein the body electrode is electrically coupled to the first power source when the first power source has a voltage level higher than the second node, and wherein the body electrode is electrically coupled to the second node when the second node has a voltage level higher than the first power source.

6. The charge pump circuit of claim 1, wherein the first power source is a reference node and the second power source is an alternating input node.

7. The charge pump circuit of claim 1, further comprising a plurality of terminals adapted to receive an alternative voltage signal, wherein the first power source is electrically coupled to one of the plurality of terminals, and wherein the second power source is electrically coupled to another one of the plurality of terminals.

8. The charge pump circuit of claim 7, wherein the second node is adapted to provide a substantially constant voltage.

9. The charge pump circuit of claim 1, wherein the charge pump circuit is incorporated within a Radio Frequency IDentification (RFID) tag having a modulator electrically coupled between the first and second power sources, the modulator being adapted to modify an impedance between the first and second power sources.

10. The charge pump circuit of claim 1, wherein each of the first and second diode-connected transistors is a native MOS transistor.

11. The charge pump circuit of claim 1, wherein each of the first and second diode-connected transistors has a substantially zero threshold voltage.

12. The charge pump circuit of claim 1, wherein the charge pump circuit is incorporated within a Radio Frequency IDentification (RFID) tag, and wherein the RFID tag comprises another charge pump circuit electrically coupled to the first power source and a third power source to increase a differential charge pump output voltage level.

13. The charge pump circuit of claim 1, wherein the charge pump circuit is incorporated within a Radio Frequency IDentification (RFID) tag and has a first storage capacitance, wherein the RFID tag comprises another charge pump electrically coupled to the first and second power sources, and wherein the another charge pump has a second storage capacitance lower than the first storage capacitance to detect data from signals provided to the first and second power sources.

14. The charge pump circuit of claim 13, wherein the RFID tag further comprises a current comparator electrically coupled to the charge pump circuit and another current comparator electrically coupled to the another charge pump circuit to detect the data from the signals provided to the first and second power sources.

15. The charge pump circuit of claim 1, wherein each of the first and second diode-connected transistors has a body electrode electrically coupled to the first power source or the second node.

16. A low-power energy harvesting passive data transmitting circuit comprising:
a primary inductor;
a charge pump having an input capacitance and an alternating input terminal, the input terminal being connected between the primary inductor and the input capacitance; and
a modulator electrically coupled to the charge pump through the primary inductor to back scatter an energy,
wherein the energy is supplied to the primary inductor, and
wherein the primary inductor has an inductance selected to resonate with the input capacitance at a frequency of a signal applied to the alternative input terminal to boost a voltage supplied to the alternating input terminal of the charge pump.

17. The low-power energy harvesting passive data transmitting circuit of claim 16, wherein the primary inductor includes a part of an antenna of a Radio Frequency IDentification (RFID) tag.

18. The low-power energy harvesting passive data transmitting circuit of claim 16, wherein the primary inductor includes a part of an antenna of a Radio Frequency (RF) device.

19. The low-power energy harvesting passive data transmitting circuit of claim 16, wherein a part of the primary inductor is incorporated within a chip of a Radio Frequency IDentification (RFID) tag.

20. The low-power energy harvesting passive data transmitting circuit of claim 16, wherein a part of the primary inductor is incorporated within a chip of a Radio Frequency (RF) device.

21. A low-power energy harvesting passive data transmitting circuit comprising:
a first controlled current source connected with a second controlled current source via a common control node and a common power sink node; and
a ring oscillator adapted to be supplied with a current from the first controlled current source via a supplied node connected between the first controlled current source and the ring oscillator.

22. The low-power energy harvesting passive data transmitting circuit of claim 21, further comprising:
a grounded current adjuster connected with the second controlled current source via a resistance terminal node connected between the second controlled current source and the grounded resistor; and
an amplifier having an inverting input, a non-inverting input, and an output,
wherein the inverting input node is connected with the supply node, the non-inverting input is connected with the resistance terminal node, and the output is connected with the common control node.

23. The low-power energy harvesting passive data transmitting circuit of claim 22, further comprising:
an auxiliary circuitry connected with the grounded resistor to digitally program a resistance value of the grounded current adjuster to tune an oscillation frequency of the ring oscillator.

24. The low-power energy harvesting passive data transmitting circuit of claim 22, further comprising:
a voltage follower having an input connected with the supply node and an output adapted to supply a subsequent digital circuitry.

25. The low-power energy harvesting passive data transmitting circuit of claim 21, further comprising:
an auxiliary circuitry connected with the first controlled current source to digitally program a current gain value of the first controlled current source to tune an oscillation frequency of the ring oscillator.

26. The low-power energy harvesting passive data transmitting circuit of claim 21, wherein the ring oscillator comprises N number of inverters, and wherein N is an odd number.

27. The low-power energy harvesting passive data transmitting circuit of claim 26, wherein each of the N number of inverters is loaded with an equivalent capacitance CL/N so that the average dynamic current supplied to the N number of inverters is Io=Fo·CL·Vo, and wherein Fo is an oscillation frequency of the N number of inverters and Vo is a voltage of the N number of inverters.

28. The low-power energy harvesting passive data transmitting circuit of claim 27, wherein the voltage Vo is less than a sum of a NMOS threshold voltage and a PMOS threshold voltage.

29. The low-power energy harvesting passive data transmitting circuit of claim 27, further comprising a bypass capacitor connected between the supplied node and a ground to filter out a voltage ripple.

30. A method of designing a low-transient power energy harvesting passive data transmitting circuit, the method comprising:
generating a plurality of logic and memory functions to represent a network of the low-transient power energy harvesting passive data transmitting circuit;
minimizing coincident logic transitions including data handling transitions and memory transitions to spread the plurality of logic, data handling, and memory functions with a grey code type logic to reduce peak energy drain; and
designing the low-transient power energy harvesting passive data transmitting circuit to include the network in accordance with the logic, data handling, and memory functions with the minimized coincident logic, data handling, and memory transitions to minimize a power supply ripple of the low-transient power energy harvesting passive data transmitting circuit.

31. A method of designing a low-transient power energy harvesting passive data transmitting circuit, the method comprising:
generating a plurality of self-timed logic functions to represent a network of the low-transient power energy harvesting passive data transmitting circuit; and
designing the low-transient power energy harvesting passive data transmitting circuit to include the network in accordance with the self-timed logic functions to eliminate a clock distribution and reduce an operating voltage of the low-transient power energy harvesting passive data transmitting circuit.

32. A method of designing a low-transient power energy harvesting passive data transmitting circuit, the method comprising:
generating a plurality of low-voltage logic functions to represent a network of the low-transient power energy harvesting passive data transmitting circuit; and
designing the low-transient power energy harvesting passive data transmitting circuit to include the network in accordance with the low-voltage logic functions to reduce an operating voltage of the low-transient power energy harvesting passive data transmitting circuit,
wherein the operating voltage is not greater 800 mV and targeted at 500 mV for typical parameters and operating conditions.

33. The method of claim 32, wherein the operating voltage is regulated by a current-fed ring oscillator circuit.

34. The method of claim 33, wherein the current-fed ring oscillator compensates for parameter variations.

35. The method of claim 33, wherein the designing of the low-transient power energy harvesting passive data transmitting circuit comprises using transistors having threshold voltages to enable to the current-fed ring oscillator to set the operating voltage to below 500 mV and above 200 mV

36. A charge pump circuit comprising:
a first diode-connected transistor having a first electrode connected with a first power source and a second electrode connected with a first node;
a first capacitor connected between the first node and a second power source;
a second diode-connected transistor having a first electrode connected with the first node and a second electrode connected with a second node; and
a second capacitor connected between the second node and the first power source,
wherein at least one of the first and second capacitors is formed using a transistor having a substantially zero threshold voltage.

37. The charge pump circuit of claim 36, wherein the transistor is a native MOS transistor.

38. The charge pump circuit of claim 36, wherein the second capacitor is formed using the transistor, and wherein the first capacitor is not formed using the transistor.

39. The charge pump circuit of claim 36, wherein at least one of the first and second diode-connected transistors has a substantially zero threshold voltage.
